(19) United States
(12) Patent Application Publication
(10) Pub. No.: US 2022/0244629 A1
(43) Pub. Date: Aug. 4, 2022

(54) METHOD FOR PRODUCING RADIATION-SENSITIVE RESIN COMPOSITION, PATTERN FORMING METHOD, AND METHOD FOR MANUFACTURING ELECTRONIC DEVICE

(71) Applicant: FUJIFILM Corporation, Tokyo (JP)

(72) Inventors: Takumi TANAKA, Haibara-gun (JP); Takashi BANNAI, Haibara-gun (JP); Hiroyuki EZOE, Haibara-gun (JP); Shoichiro IWAGAYA, Haibara-gun (JP); Hiroki MOTOYAMA, Haibara-gun (JP); Kenichi HARADA, Haibara-gun (JP)

(73) Assignee: FUJIFILM Corporation, Tokyo (JP)

(21) Appl. No.: 17/714,366

(22) Filed: Apr. 6, 2022

Related U.S. Application Data
(63) Continuation of application No. PCT/JP2020/035161, filed on Sep. 17, 2020.

(30) Foreign Application Priority Data
Oct. 9, 2019 (JP) 2019-186185
Sep. 7, 2020 (JP) 2020-149893

(51) Int. Cl. G03C 1/73

(52) U.S. Cl. CPC G03C 1/733; G03C 2001/7429

(57) ABSTRACT

The present invention provides a method for producing a radiation-sensitive resin composition, in which an inter-lot variation in performance of radiation-sensitive resin compositions that have been filtered is suppressed, a pattern forming method, and a method for producing an electronic device. The method for producing a radiation-sensitive resin composition of an embodiment of the present invention has a step 1 of bringing a first solution including a first organic solvent into contact with a first filter to clean the first filter, and a step 2 of filtering a radiation-sensitive resin composition using the first filter cleaned in the step 1.

### CROSS-REFERENCE TO RELATED APPLICATIONS

This application is a Continuation of PCT International Application No. PCT/JP2020/035161 filed on Sep. 17, 2020, which claims priority under 35 U.S.C. § 119(a) to Japanese Patent Application No. 2019-186185 filed on Oct. 9, 2019 and Japanese Patent Application No. 2020-149893 filed on Sep. 7, 2020. Each of the above applications is hereby expressly incorporated by reference, in its entirety, into the present application.

### BACKGROUND OF THE INVENTION

### 1. Field of the Invention

The present invention relates to a method for producing a radiation-sensitive resin composition, a pattern forming method, and a method for manufacturing an electronic device.

### 2. Description of the Related Art

In processes for manufacturing semiconductor devices such as an integrated circuit (IC) and a large scale integrated circuit (LSI) in the related art, microfabrication by lithography using a radiation-sensitive resin composition has been performed.

Examples of the lithographic method include a method in which a resist film is formed with a radiation-sensitive resin composition, and then the obtained film is exposed and then developed.

In addition, JP2014-178566A discloses a method of carrying out a filtration treatment using a filter in a case of the production of a radiation-sensitive resin composition.

### SUMMARY OF THE INVENTION

Generally, radiation-sensitive resin compositions that have passed through filters are subdivided into containers in the order of passage, recovered, and shipped. At that time, the subdivided radiation-sensitive resin compositions are required to exhibit the same performance.

The present inventors filtered radiation-sensitive resin compositions with a filter according to the method described in JP2014-178566A, and used each of the radiation-sensitive resin compositions subdivided in the order of filtration to form a pattern, from which it was thus found that there occurs a variation in a pattern shape (for example, a space line width or a hole size). Hereinafter, occurrence of a variation in the pattern shape among the radiation-sensitive resin compositions that have been subjected to filtration through a filter and subdivided in the order of recovery as described above is expressed as follows: “there occurs an inter-lot variation in the performance of the radiation-sensitive resin compositions that have been filtered through a filter”.

It is an object of the present invention to provide a method for producing a radiation-sensitive resin composition, in which an inter-lot variation in the performance of the radiation-sensitive resin compositions that have been filtered through a filter is suppressed.

In addition, another object of the present invention is to provide a pattern forming method and a method for manufacturing an electronic device.

The present inventors have found that the objects can be accomplished by the following configurations.

(1) A method for producing a radiation-sensitive resin composition, comprising:

a step 1 of bringing a first solution including a first organic solvent into contact with a first filter to clean the first filter; and

a step 2 of filtering a radiation-sensitive resin composition using the first filter cleaned in the step 1.

(2) The method for producing a radiation-sensitive resin composition as described in (1),

in which the radiation-sensitive resin composition includes a resin having a polarity that increases by an action of an acid, a photoacid generator, and an organic solvent, and

the radiation-sensitive resin composition is used as the first solution.

(3) The method for producing a radiation-sensitive resin composition as described in (1) or (2),

in which a contact time between the first filter and the first solution in the step 1 is 1 hour or more.

(4) The method for producing a radiation-sensitive resin composition as described in any one of (1) to (3),

in which an SP value of the first organic solvent is 17.0 MPa^{1/2} or more and less than 25.0 MPa^{1/2}.

(5) The method for producing a radiation-sensitive resin composition as described in any one of (1) to (4),

in which the contact between the first filter and the first solution in the step 1 is performed under a pressure of 50 kPa or more.

(6) The method for producing a radiation-sensitive resin composition as described in any one of (1) to (5),

in which the first filter is arranged so that a liquid passing direction is from a lower side to an upper side in a vertical direction.

(7) The method for producing a radiation-sensitive resin composition as described in any one of (1) to (6),

in which at least one first filter is a polyamide-based filter.

(8) The method for producing a radiation-sensitive resin composition as described in any one of (1) to (7),

in which a linear velocity in a case where the first solution including the first organic solvent passes through the first filter is 40 L/(hr·m²) or less.

(9) The method for producing a radiation-sensitive resin composition as described in any one of (1) to (8),

in which the step 2 is a step of circulating and filtering the radiation-sensitive resin composition using the first filter.

(10) The method for producing a radiation-sensitive resin composition as described in any one of (1) to (9), further comprising:

a step 3 of bringing a second solution including a second organic solvent into contact with a second filter to clean the second filter before the step 2;

a step 4 of filtering at least one compound of constituents included in the radiation-sensitive resin composition using the second filter cleaned in the step 3; and

a step 5 of preparing the radiation-sensitive resin composition using the compound obtained in the step 4.

(11) The method for producing a radiation-sensitive resin composition as described in (10),

in which a contact time between the second filter and the second solution in the step 3 is 1 hour or more.

(12) The method for producing a radiation-sensitive resin composition as described in (10) or (11),

in which an SP value of the second organic solvent is 17.0 MPa^{1/2} or more and less than 25.0 MPa^{1/2}.

(13) The method for producing a radiation-sensitive resin composition as described in any one of (10) to (12),

in which the contact between the second filter and the second solution in the step 3 is performed under a pressure of 50 kPa or more.

(14) The method for producing a radiation-sensitive resin composition as described in any one of (10) to (13),

in which the second filter is arranged so that a liquid passing direction is from a lower side to an upper side in a vertical direction.

(15) The method for producing a radiation-sensitive resin composition as described in any one of (10) to (14),

in which at least one second filter is a polyamide-based filter.

(16) The method for producing a radiation-sensitive resin composition as described in any one of (10) to (15),

in which a linear velocity in a case where the second solution including the second organic solvent passes through the second filter is 40 L/(hr·m²) or less.

(17) The method for producing a radiation-sensitive resin composition as described in any one of (10) to (16),

in which the step 4 is a step of circulating and filtering at least one compound of constituents included in the radiation-sensitive resin composition using the second filter.

(18) The method for producing a radiation-sensitive resin composition as described in any one of (1) to (17),

in which a concentration of solid contents of the radiation-sensitive resin composition is 10% by mass or more.

(19) A pattern forming method comprising:

a step of forming a resist film on a substrate using a radiation-sensitive resin composition produced by the production method as described in any one of (1) to (18);

a step of exposing the resist film; and

a step of developing the exposed resist film using a developer to form a pattern.

(20) A method for manufacturing an electronic device, comprising the pattern forming method as described in (19).

According to the present invention, it is possible to provide a method for producing a radiation-sensitive resin composition, in which an inter-lot variation in the performance of the radiation-sensitive resin compositions that have been filtered through a filter is suppressed.

In addition, according to the present invention, it is possible to provide a pattern forming method and a method for manufacturing an electronic device.

### BRIEF DESCRIPTION OF THE DRAWINGS

FIG. 1 shows a schematic view of an embodiment of a production device used in a method for producing a radiation-sensitive resin composition of the embodiment of the present invention.

### DESCRIPTION OF THE PREFERRED EMBODIMENTS

Hereinafter, an example of forms for carrying out the present invention will be described.

In the present specification, a numerical value range expressed using “to” means a range that includes the preceding and succeeding numerical values of “to” as a lower limit value and an upper limit value, respectively.

In notations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

The bonding direction of divalent groups cited in the present specification is not limited unless otherwise specified. For example, in a compound represented by General Formula “LMN”, M may be either *1-OCO—C(CN)═CH-*2 or *1-CH═C(CN)—COO-*2, assuming that in a case where M is —OCO—C(CN)═CH—, a position bonded to the L side is defined as *1 and a position bonded to the N side is defined as *2.

“(Meth)acryl” in the present specification is a generic term encompassing acryl and methacryl, and means “at least one of acryl or methacryl”. Similarly, “(meth)acrylic acid” is a generic term encompassing acrylic acid and methacrylic acid, and means “at least one of acrylic acid or methacrylic acid”.

In the present specification, a weight-average molecular weight (Mw), a number-average molecular weight (Mn), and a dispersity (also described as a molecular weight distribution) (Mw/Mn) of a resin are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

“Radiation” in the present specification means, for example, a bright line spectrum of a mercury lamp, far ultraviolet rays typified by an excimer laser, extreme ultraviolet rays (EUV), X-rays, electron beams (EB), or the like. “Light” in the present specification means radiation.

In the present specification, an acid dissociation constant (pKa) represents a pKa in an aqueous solution, and is specifically a value determined by computation from a value based on a Hammett's substituent constant and database of publicly known literature values, using the following software package 1. Any of the pKa values described in the present specification indicates values determined by computation using the software package.

Software Package 1: Advanced Chemistry Development (ACD/Labs) Software V 8.14 for Solaris (1994-2007 ACD/Labs).

On the other hand, the pKa can also be determined by a molecular orbital computation method. Examples of a specific method therefore include a method for performing calculation by computing H⁺ dissociation free energy in an aqueous solution based on a thermodynamic cycle. With regard to a computation method for H⁺ dissociation free energy, the H⁺ dissociation free energy can be computed by, for example, density functional theory (DFT), but various other methods have been reported in literature and the like, and are not limited thereto. Furthermore, there are a plurality of software applications capable of performing DFT, and examples thereof include Gaussian 16.

As described above, the pKa in the present specification refers to a value determined by computation from a value based on a Hammett's substituent constant and database of publicly known literature values, using the software package 1, but in a case where the pKa cannot be calculated by the method, a value obtained by Gaussian 16 based on density functional theory (DFT) shall be adopted.

In addition, the pKa in the present specification refers to a “pKa in an aqueous solution” as described above, but in a case where the pKa in an aqueous solution cannot be calculated, a “pKa in a dimethyl sulfoxide (DMSO) solution” shall be adopted.

One of features of the method for producing a radiation-sensitive resin composition of an embodiment of the present invention (hereinafter also simply referred to as “the composition of an embodiment of the present invention” or “the composition”) may be that the composition is brought into contact with an organic solvent for cleaning before using a filter.

According to the investigations conducted by the present inventors, a reason of the occurrence of an inter-lot variation in the performance of radiation-sensitive resin compositions filtered by a filter in the related art is that a radiation-sensitive resin composition having a large amount of impurities can be obtained in an initial stage of filtration through a filter due to impurities included in a filter, whereas a radiation-sensitive resin composition having a decreased amount of impurities can be obtained in a later stage of filtration through the filter due to a decrease in the amount of the impurities in the filter over time. Accordingly, it is presumed that the amount of the impurities differs among the radiation-sensitive resin compositions subdivided in the order of filtration through the filter, and as a result, a difference in the performance of pattern formation occurs. In contrast, it was found that the impurities in the filter can be efficiently removed by carrying out a cleaning treatment of bringing the filter into contact with an organic solvent, and as a result, a desired effect can be obtained.

### First Embodiment

A first embodiment of the production method of the embodiment of the present invention has the following steps 1 and 2 in this order.

Step 1: A step of bringing a first solution including a first organic solvent into contact with a first filter to clean the first filter

Step 2: A step of filtering a radiation-sensitive resin composition using the first filter cleaned in the step 1

Hereinafter, a procedure of each step will be described in detail.

Furthermore, the production method of the embodiment of the present invention is preferably carried out in a clean room. The degree of cleanliness is preferably Class 6 or less in International Organization for Standardization ISO 14644-1.

Moreover, in a case where the concentration of solid contents of the radiation-sensitive resin composition used in the step 2 is 10% by mass or more, the effect of the present invention is remarkably exhibited.

(Step 1)

The step 1 is a step of bringing a first solution including a first organic solvent into contact with a first filter to clean the first filter.

Hereinbelow, first, the materials and members to be used will be described in detail, and then the procedure of the steps will be described in detail.

[First Solution]

The first solution includes a first organic solvent.

The type of the first organic solvent is not particularly limited, and examples thereof include an amide-based solvent, an alcohol-based solvent, an ester-based solvent, a glycol ether-based solvent (including a glycol ether-based solvent having a substituent), a ketone-based solvent, an alicyclic ether-based solvent, an aliphatic hydrocarbon-based solvent, an aromatic ether-based solvent, and an aromatic hydrocarbon-based solvent.

Among those, an organic solvent having an SP value (solubility parameter) of 17.0 MPa^{1/2} or more and less than 25.0 MPa^{1/2} is preferable in that an inter-lot variation in the performance of the radiation-sensitive resin compositions that have been filtered through a filter is further suppressed (hereinafter also simply referred to as “the viewpoint that the effect of the present invention is more excellent”).

The SP value of the present invention was calculated using the Fedor's method described in “Properties of Polymers, 2^{nd} Ed, 1976 Publishing”. A calculation equation used and the parameters of each substituent are shown in Table 1 below.

SP value (Fedor's method)=[(Sum of cohesive energy of each substituent)/(Sum of volume of each substituent)]^{0.5}

TABLE 1

| | Cohesive | Volume | | Cohesive | Volume |
|---|---|---|---|---|---|
| | energy | (cm³/ | | energy | (cm³/ |
| Substituent | (J/mol) | mol) | Substituent | (J/mol) | mol) |
| CH₃ | 4,710 | 33.5 | CN | 25,530 | 24 |
| CH₂ | 4,940 | 16.1 | OH | 29,800 | 10 |
| CH | 3,430 | −1 | CHO | 21,350 | 22.3 |
| C | 1,470 | −19.2 | COOH | 27,630 | 28.5 |
| CH2═ | 4,310 | 28.5 | -O- | 3,350 | 3.8 |
| ═CH− | 4,310 | 13.5 | CO | 17,370 | 10.8 |
| ═C< | 4,310 | −5.5 | COO | 18,000 | 18 |
| | | | 5− or | | |
| Ph | 31,940 | 71.4 | higher- | 1,050 | 16 |
| | | | member ring | | |
| NH₂ | 12,560 | 19.2 | | | |
| NH | 8,370 | 4.5 | | | |
| N< | 4,190 | −9 | | | |

Fedors method substituent constants extracted (Properties of Polymers 2^{nd} Edition, pp. 138 to 140)

Hereinafter, specific examples of the organic solvent having an SP value of 17.0 MPa^{1/2} or more and less than 25.0 MPa^{1/2} are shown in Tables 2 to 6.

TABLE 2

| Classification | Name of solvent | MPa^{1/2} |
|---|---|---|
| Ketone-based solvent | 3,3-Dimethyl-2-butanone | 17.3 |
| Ester-based solvent | Isobutyl acetate | 17.4 |
| Ester-based solvent | Isopropyl acetate | 17.4 |
| Ester-based solvent | Isoamyl acetate (isopentyl | 17.4 |
| | acetate, 3-methylbutyl acetate) | |
| Ester-based solvent | 2-Methylbutyl acetate | 17.4 |
| Ester-based solvent | 1-Methylbutyl acetate | 17.4 |
| Ester-based solvent | Isopropyl propionate | 17.4 |
| Ester-based solvent | Isopropyl butanoate | 17.4 |
| Ester-based solvent | Isobutyl butanoate | 17.4 |
| Ester-based solvent | Isopropyl pentanoate | 17.4 |
| Ketone-based solvent | Diisobutyl ketone | 17.4 |
| Ketone-based solvent | Diisopentyl ketone | 17.4 |
| Ketone-based solvent | Diisohexyl ketone | 17.4 |
| Ketone-based solvent | Diisoheptyl ketone | 17.4 |
| Ester-based solvent | 3-Methyl-3-methoxybutyl acetate | 17.5 |
| Ester-based solvent | Isobutyl hexanoate, | 17.5 |
| Ester-based solvent | 2-Ethylhexyl acetate | 17.5 |
| Ketone-based solvent | Methyl isoamyl ketone | 17.5 |
| Aliphatic hydrocarbon- | Cyclohexane | 17.5 |
| based solvent | | |
| Aliphatic hydrocarbon- | Cycloheptane | 17.5 |
| based solvent | | |
| Aliphatic hydrocarbon- | Cyclooctane | 17.5 |
| based solvent | | |
| Ketone-based solvent | Isophorone | 17.6 |
| Ester-based solvent | Heptyl acetate | 17.7 |
| Ester-based solvent | Octyl acetate | 17.7 |
| Ester-based solvent | Hexyl propionate | 17.7 |
| Ester-based solvent | Heptyl propionate, | 17.7 |
| Ester-based solvent | Pentyl butanoate | 17.7 |
| Ester-based solvent | Hexyl butanoate | 17.7 |
| Ester-based solvent | Butyl pentanoate | 17.7 |
| Ester-based solvent | Pentyl pentanoate | 17.7 |
| Ester-based solvent | Propyl hexanoate | 17.7 |
| Ester-based solvent | Butyl hexanoate, | 17.7 |
| Ester-based solvent | Ethyl heptanoate, | 17.7 |
| Ester-based solvent | Propyl heptanoate | 17.7 |
| Ketone-based solvent | Ethyl isobutyl ketone | 17.7 |
| Ketone-based solvent | Methyl isopentyl ketone | 17.7 |
| Ketone-based solvent | Ethyl isopentyl ketone | 17.7 |
| Ketone-based solvent | Propyl isopentyl ketone | 17.7 |
| Ketone-based solvent | Propyl isobutyl ketone | 17.7 |
| Aliphatic hydrocarbon- | Ethylcyclohexane | 17.8 |
| based solvent | | |
| Aliphatic hydrocarbon- | Methylcyclohexane | 17.8 |
| based solvent | | |

TABLE 3

| Classification | Name of solvent | MPa^{1/2} |
|---|---|---|
| Ester-based solvent | Butyl acetate | 17.8 |
| Ester-based solvent | Amyl acetate (pentyl acetate) | 17.8 |
| Ester-based solvent | Propyl acetate | 17.8 |
| Ester-based solvent | Hexyl acetate | 17.8 |
| Ester-based solvent | 2-Methoxybutyl acetate | 17.8 |
| Ester-based solvent | 3-Methoxybutyl acetate | 17.8 |
| Ester-based solvent | Propylene glycol monoethyl | 17.8 |
| | ether acetate | |
| Ester-based solvent | Propylene glycol monopropyl | 17.8 |
| | ether acetate | |
| Ester-based solvent | 2-Ethoxybutyl acetate | 17.8 |
| Ester-based solvent | 2-Methoxypentyl acetate | 17.8 |
| Ester-based solvent | 3-Methoxypentyl acetate | 17.8 |
| Ester-based solvent | 4-Methoxypentyl acetate | 17.8 |
| Ester-based solvent | Ethyl propionate | 17.8 |
| Ester-based solvent | Propyl propionate | 17.8 |
| Ester-based solvent | Butyl propionate | 17.8 |
| Ester-based solvent | Pentyl propionate | 17.8 |
| Ester-based solvent | Butyl butyrate | 17.8 |
| Ester-based solvent | Propyl pentanoate | 17.8 |
| Ester-based solvent | Ethyl hexanoate | 17.8 |
| Ester-based solvent | Methyl heptanoate | 17.8 |
| Ketone-based solvent | 3-Methyl-2-butanone | 17.8 |
| Ketone-based solvent | Methyl isobutyl ketone | 17.8 |
| Ester-based solvent | Ethyl acetate | 17.9 |
| Ester-based solvent | Propylene glycol monomethyl | 17.9 |
| | ether acetate (PGMEA) | |
| Ester-based solvent | Methyl propionate | 17.9 |
| Ester-based solvent | Methyl acetate | 18.0 |
| Ketone-based solvent | 2-Octanone | 18.0 |
| Ketone-based solvent | 3-Octanone | 18.0 |
| Ketone-based solvent | 4-Octanone | 18.0 |
| Ketone-based solvent | 2-Nonanone | 18.0 |
| Ketone-based solvent | 3-Nananone | 18.0 |
| Ketone-based solvent | 4-Nonanone | 18.0 |
| Ketone-based solvent | 5-Nonanone | 18.0 |
| Ester-based solvent | Ethylene glycol monobutyl ether acetate | 18.1 |
| Ester-based solvent | 3-Ethyl-3-methoxybutyl acetate | 18.1 |
| Ester-based solvent | 4-Ethoxybutyl acetate | 18.1 |
| Ester-based solvent | 4-Propoxybutyl acetate | 18.1 |
| Ketone-based solvent | 2-Heptanone | 18.1 |
| Ketone-based solvent | 3-Heptanone | 18.1 |
| Ketone-based solvent | 4-Heptanone | 18.1 |
| Ester-based solvent | Ethyl ethoxylate | 18.2 |

TABLE 4

| Classification | Name of solvent | MPa^{1/2} |
|---|---|---|
| Ester-based solvent | Ethylene glycol monoethyl | 18.2 |
| | ether acetate | |
| Ester-based solvent | Ethylene glycol monopropyl | 18.2 |
| | ether acetate | |
| Ester-based solvent | 4-Methoxybutyl acetate | 18.2 |
| Ester-based solvent | Methylbutyl carbonate | 18.2 |
| Ketone-based solvent | 2-Hexanone | 18.2 |
| Ketone-based solvent | 3-Hexanone | 18.2 |
| Alicyclic ether-based solvent | Tetrahydrofuran | 18.2 |
| Ester-based solvent | Ethyl methoxyacetate | 18.3 |
| Ester-based solvent | Diethylene glycol monobutyl | 18.3 |
| | ether acetate | |
| Ester-based solvent | Methylpropyl carbonate | 18.3 |
| Ester-based solvent | Ethylene glycol monophenyl | 18.4 |
| | ether acetate | |
| Ester-based solvent | Diethylene glycol monopropyl | 18.4 |
| | ether acetate | |
| Ester-based solvent | Diethylene glycol monoethyl | 18.4 |
| | ether acetate | |
| Ketone-based solvent | Methyl ethyl ketone | 18.4 |
| Alicyclic ether-based solvent | Tetrahydrofuran | 18.4 |
| Aromatic hydrocarbon- | Propylbenzene | 18.4 |
| based solvent | | |
| Aromatic hydrocarbon- | 1-Methyl-4-propylbenzene | 18.4 |
| based solvent | | |
| Aromatic hydrocarbon- | Diethylbenzene | 18.4 |
| based solvent | | |
| Amide-based solvent | N,N-Dimethylpropioamide | 18.5 |
| Ester-based solvent | Diethylene glycol | 18.5 |
| | monomethyl ether acetate | |
| Ester-based solvent | Ethylmethyl carbonate | 18.5 |
| Aromatic hydrocarbon- | Ethylbenzene | 18.5 |
| based solvent | | |
| Ketone-based solvent | Acetone | 18.6 |
| Aromatic hydrocarbon- | Xylene | 18.6 |
| based solvent | | |
| Amide-based solvent | N,N-dimethylacetamide | 18.7 |
| Aromatic hydrocarbon- | Toluene | 18.7 |
| based solvent | | |
| Aromatic ether-based solvent | Phenethol | 19.0 |
| Aromatic ether-based solvent | Anisole | 19.2 |
| Ester-based solvent | Butyl formate | 19.4 |
| Ketone-based solvent | 3-Methylcyclohexanone | 19.4 |
| Ketone-based solvent | 4-Methylcyclohexanone | 19.4 |
| Ester-based solvent | Cycloheptyl acetate | 19.5 |
| Ester-based solvent | Propylene glycol diacetate | 19.6 |
| Ester-based solvent | Propyl formate | 19.7 |
| Ester-based solvent | Cyclohexyl acetate | 19.7 |
| Alcohol-based solvent | 9-Methyl-2-decanol | 19.8 |
| Alcohol-based solvent | 8-Methyl-2-nonanol | 20.0 |
| Ketone-based solvent | Cyclohexanone | 20.0 |
| Alcohol-based solvent | 2-Methyl-3-pentanol | 20.1 |
| Alcohol-based solvent | 3-Methyl-2-pentanol | 20.1 |
| Alcohol-based solvent | 4,5-Dimethyl-2-hexanol | 20.2 |

TABLE 5

| Classification | Name of solvent | MPa^{1/2} |
|---|---|---|
| Alcohol-based solvent | 7-Methyl-2-octanol | 20.2 |
| Ester-based solvent | Ethyl formate | 20.2 |
| Ester-based solvent | Butyl pyruvate | 20.3 |
| Ester-based solvent | Diethylene glycol monophenyl | 20.4 |
| | ether acetate | |
| Alcohol-based solvent | 1-Decanol | 20.5 |
| Alcohol-based solvent | 6-Methyl-2-heptanol | 20.5 |
| Ketone-based solvent | Cyclopentanone | 20.5 |
| Alicyclic ether-based solvent | 1,4-Dioxane | 20.5 |
| Alcohol-based solvent | 2-Octanol | 20.7 |
| Alcohol-based solvent | 3-Octanol | 20.7 |
| Alcohol-based solvent | 4-Octanol | 20.7 |
| Ester-based solvent | Propyl pyruvate | 20.7 |
| Ester-based solvent | Ethyl acetate | 20.7 |
| Alcohol-based solvent | 2,3-Dimethyl-2-butanol | 20.8 |
| Alcohol-based solvent | 3,3-Dimethyl-2-butanol | 20.8 |
| Alcohol-based solvent | 5-Methyl-2-hexanol | 20.8 |
| Alcohol-based solvent | 4-Methyl-2-hexanol | 20.8 |
| Alcohol-based solvent | 1-Octanol | 21.0 |
| Ester-based solvent | Methyl formate | 21.0 |
| Alcohol-based solvent | 2-Heptanol | 21.1 |
| Alcohol-based solvent | 3-Heptanol | 21.1 |
| Ester-based solvent | Ethyl pyruvate | 21.1 |
| Ester-based solvent | Methyl acetoacetate | 21.1 |
| Amide-based solvent | N, N-dimethylformamide | 21.2 |
| Alcohol-based solvent | 3-Methyl-3-pentanol | 21.2 |
| Alcohol-based solvent | 2-Methyl-2-pentanol | 21.2 |
| Alcohol-based solvent | 3-Methyl-3-pentanol | 21.2 |
| Alcohol-based solvent | 4-Methyl-2-pentanol | 21.2 |
| Ketone-based solvent | Phenylacetone | 21.2 |
| Ketone-based solvent | Acetonyl acetone | 21.2 |
| Alcohol-based solvent | 1-Heptanol | 21.4 |
| Glycol ether-based solvent | Propylene glycol monobutyl ether | 21.4 |
| Alcohol-based solvent | 2-Hexanol | 21.5 |
| Alcohol-based solvent | 3-Hexanol | 21.5 |
| Glycol ether-based solvent | 3-Methoxy-3-methylbutanol | 21.5 |
| Ester-based solvent | Methyl pyruvate | 21.6 |
| Ketone-based solvent | Acetophenone | 21.6 |
| Glycol ether-based solvent | Triethylene glycol monoethyl ether | 21.7 |
| Ketone-based solvent | Acetylacetone | 21.7 |
| Glycol ether-based solvent | Propylene glycol monopropyl ether | 21.8 |

TABLE 6

| Classification | Name of solvent | MPa^{1/2} |
|---|---|---|
| Alcohol-based solvent | 1-Hexanol | 21.9 |
| Alcohol-based solvent | 3-Methyl-1-butanol | 22.0 |
| Alcohol-based solvent | 2-Pentanol | 22.0 |
| Glycol ether-based solvent | Ethylene glycol monobutyl ether | 22.1 |
| Amide-based solvent | N-Methyl-2-pyrrolidone | 22.2 |
| Alcohol-based solvent | tert-Butyl alcohol | 22.3 |
| Alcohol-based solvent | 3-Methoxy-1-butanol | 22.3 |
| Glycol ether-based solvent | Propylene glycol monoethyl ether | 22.3 |
| Alcohol-based solvent | 1-Pentanol | 22.4 |
| Alcohol-based solvent | 2-Butanol | 22.7 |
| Glycol ether-based solvent | Ethylene glycol monopropyl ether | 22.7 |
| Ester-based solvent | Butyl lactate | 23.0 |
| Glycol ether-based solvent | Propylene glycol monomethyl | 23.0 |
| | ether (PGME) | |
| Glycol ether-based solvent | Diethylene glycol monomethyl ether | 23.0 |
| Alcohol-based solvent | 1-Butanol | 23.2 |
| Glycol ether-based solvent | Ethylene glycol monoethyl ether | 23.5 |
| Alcohol-based solvent | Cyclohexanol | 23.6 |
| Ester-based solvent | Propyl lactate | 23.6 |
| Ketone-based solvent | Propylene carbonate. | 23.6 |
| Alcohol-based solvent | Isopropanol | 23.7 |
| Ketone-based solvent | γ-Butyrolactone | 23.8 |
| Ketone-based solvent | Diacetonyl alcohol | 23.9 |
| Alcohol-based solvent | 1-Propanol | 24.2 |
| Glycol ether-based solvent | Propylene glycol monophenyl ether | 24.2 |
| Ester-based solvent | Ethyl lactate | 24.4 |
| Alcohol-based solvent | Cyclopentanol | 24.5 |
| Glycol ether-based solvent | Ethylene glycol monomethyl ether | 24.5 |

A content of the first organic solvent in the first solution is not particularly limited, but from the viewpoint that an inter-lot variation in the performance of the radiation-sensitive resin compositions that have been filtered through a filter is further suppressed (hereinafter simply referred to as “the viewpoint that the effect of the present invention is more excellent”), the content is preferably 50% by mass or more, more preferably 70% by mass or more, and still more preferably 90% by mass or more with respect to a total mass of the first solution. The upper limit may be 100% by mass.

The first solution may include only one kind of first organic solvent or may include two or more kinds of first organic solvents.

Furthermore, the first organic solvent used preferably does not include impurities such as metal impurities. Therefore, it is preferable that the first organic solvent is filtered with a filter to remove impurities before use.

The type of filter used is not particularly limited, and examples thereof include filters exemplified in the first filter which will be described later.

A content of the metal impurities included in the first organic solvent is preferably 1 ppm by mass or less, more preferably 10 ppb by mass or less, still more preferably 100 ppt by mass or less, particularly preferably 10 ppt by mass or less, and most preferably 1 ppt by mass or less. Here, examples of the metal impurities include Na, K, Ca, Fe, Cu, Mn, Mg, Al, Li, Cr, Ni, Sn, Ag, As, Au, Ba, Cd, Co, Mo, Zr, Pb, Ti, V, W, and Zn.

Furthermore, it is preferable to use the organic solvent included in the radiation-sensitive resin composition used in the step 2 which will be described later as the first organic solvent.

In a case where the first solution is brought into contact with the first filter for cleaning, the first solution remains in the first filter after the contact in some cases. Therefore, for example, in a case where the first solution consists only of an organic solvent not included in the radiation-sensitive resin composition used in the step 2 and the radiation-sensitive resin composition is filtered using the first filter brought in contact with the first solution, there is a possibility that the first solution remaining in the first filter is partially incorporated into the radiation-sensitive resin composition that has passed through the first filter and the organic solvent that is not supposed to be used is incorporated into the radiation-sensitive resin composition.

In contrast, in a case where the organic solvent included in the radiation-sensitive resin composition used in the step 2 which will be described later is used as the first organic solvent, there is a possibility that even in a case where the first solution remains in the first filter, the radiation-sensitive resin composition only includes the organic solvent which is supposed to be used and gives no influence on the composition of the components, which is thus preferable.

In addition, the first solution may include components other than the first organic solvent.

For example, as the first solution, the radiation-sensitive resin composition used in the step 2 which will be described later may be used. More specifically, the radiation-sensitive resin composition preferably includes a resin having a polarity that increases by the action of an acid, a photoacid generator, and an organic solvent, and a radiation-sensitive resin composition including an organic solvent can be used as the first solution.

In a case where the first solution is brought into contact with the first filter for cleaning, the first solution remains in the first filter after the contact in some cases. Therefore, for example, in a case where the first solution consists only of the first organic solvent and the radiation-sensitive resin composition is filtered using the first filter in contact with the first solution, the first solution remaining in the first filter is partially incorporated into the radiation-sensitive resin composition that has passed through the first filter and the concentration of solid contents thus changes in some cases.

In contrast, in a case where the radiation-sensitive resin composition is used as the first solution in the step 2, there is no influence on the composition of the components of the radiation-sensitive resin composition even in a case where the radiation-sensitive resin composition remains in the first filter, which is thus preferable.

Therefore, the composition of the first solution is preferably the same as the composition of the radiation-sensitive resin composition used in the step 2.

The resin having a polarity that increases by the action of an acid, the photoacid generator, the organic solvent, and the like which are the constituents of the radiation-sensitive resin composition will be described in detail later.

[First Filter]

The type of the first filter used is not particularly limited, and a known filter is used.

A pore diameter (pore size) of the first filter is preferably 0.50 μm or less, and more preferably 0.30 μm or less. The lower limit is not particularly limited, but is often 0.001 μm or more.

As a material of the first filter, for example, fluororesins such as polytetrafluoroethylene, perfluoroalkoxyalkane, a perfluoroethylenepropene copolymer, polyvinylidenefluoride, and an ethylenetetrafluoroethylene copolymer, polyolefin resins such as polypropylene and polyethylene, polyamide resins such as nylon 6 and nylon 66, and polyimide resins (examples of the polyimide filter include the polyimide filters described in JP2017-064711A and JP2017-064712A) are preferable.

Among those, as the first filter, polyamide-based filters (a filter composed of a polyamide resin) are preferable.

[Procedure of Step 1]

A contact time between the first filter and the first solution is not particularly limited, but is preferably 1 hour or more, and more preferably 2 hours or more from the viewpoint that the effect of the present invention is more excellent. The upper limit is not particularly limited, but in a case where the present step is performed in equipment for producing a photosensitive resin composition, the upper limit is preferably 15 hours or less in consideration of an occupation time of the equipment.

A method of bringing the first solution into contact with the first filter may be either a method of immersing the first filter in the first solution or a method of bringing the first solution into contact with the first filter while passing the first solution through the first filter. In a case of the method of immersing the first filter in the first solution, the above-mentioned contact time corresponds to the immersion time, and in a case of the method of passing the first solution through the first filter, the above-mentioned contact time corresponds to the liquid passing time.

Furthermore, from the viewpoint that the effect of the present invention is more excellent, a treatment of immersing the filter in the first solution to clean the first filter is preferable.

The first filter is preferably arranged so that the liquid passing direction is from a lower side to an upper side in the vertical direction. That is, in a case where the first solution is to be passed through the first filter, it is preferable to arrange the first filter so that the first solution passes from the lower side to the upper side in the vertical direction. With the arrangement, air bubbles included in the first filter can be efficiently removed.

The contact between the first solution and the first filter may be carried out under normal pressure or may be carried out under pressurization.

As the condition for pressurization, the pressure is preferably 50 kPa or more, more preferably 100 kPa or more, and still more preferably 200 kPa. The upper limit is not particularly limited, but it depends on a maximum permissible differential pressure of a filter used.

Furthermore, examples of a method of performing the contact under pressurization include a method in which a first filter is arranged in a production device for a radiation-sensitive resin composition, a valve on a secondary side that is the downstream side of the first filter is closed, and pressurization is performed from the primary side that is the upstream side of the first filter, as described later.

Incidentally, the upstream side of the first filter means a side on which an object to be purified is supplied to the first filter and the downstream side of the first filter means a side on which the object to be purified has passed through the first filter.

As described above, in the present specification, the upstream side means an inflow portion side, and the downstream side means the opposite side.

In addition, a predetermined amount of the first solution may be passed through the first filter, as necessary, after the contact treatment. A passage volume of the first solution is preferably 5 kg or more, more preferably 10 kg or more, and still more preferably 15 kg or more per first filter. The upper limit is not particularly limited, but is preferably 100 kg or less from the viewpoint of productivity.

A linear velocity (linear velocity of the first solution) in a case where the first solution is passed through the first filter is not particularly limited, but is preferably 40 L/(hr·m²) or less, more preferably 25 L/(hr·m²) or less, and still more preferably 10 L/(hr·m²) or less.

The linear velocity is obtained by measuring a flow amount in a case where the first solution passes through with a commercially available flow meter and dividing the obtained flow rate by a film area of the first filter.

The above-mentioned step 1 may be carried out in a production device for a radiation-sensitive resin composition or may be carried out in another equipment for contact.

Hereinafter, a mode using the production device for a radiation-sensitive resin composition will be described in detail.

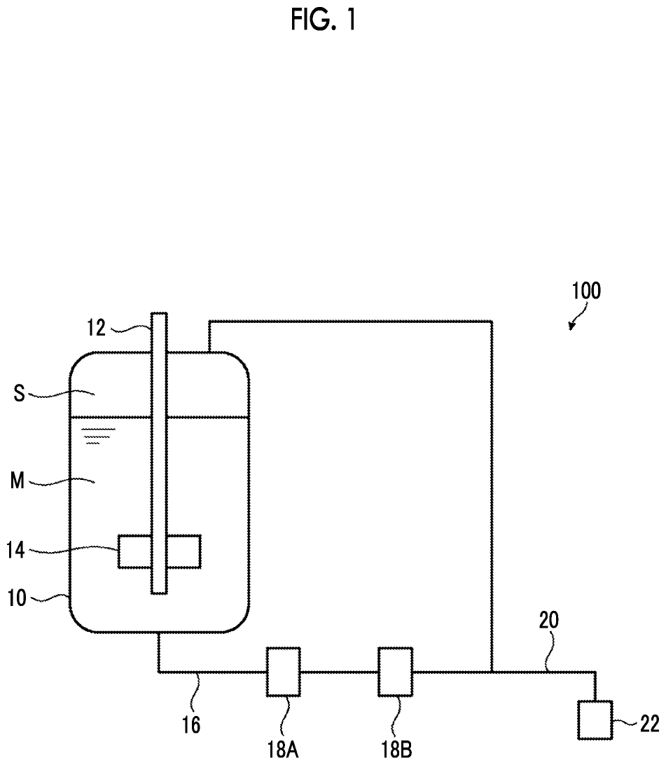

FIG. 1 shows a schematic view of an embodiment of an production device for a radiation-sensitive resin composition.

A production device 100 has a stirring tank 10, a stirring shaft 12 rotatably mounted in the stirring tank 10, a stirring blade 14 attached to the stirring shaft 12, a circulation pipe 16 having one end connected to a bottom part of the stirring tank 10 and the other end connected to an upper part of the stirring tank 10, a first filter 18A and a first filter 18B arranged in the middle of the circulation pipe 16, a discharge pipe 20 connected to the circulation pipe 16, and a discharge nozzle 22 arranged on an end part of the discharge pipe 20.

Furthermore, although not shown in FIG. 1, a valve for controlling the flow of a solution in the pipe and a discharge port capable of discharging the solution in the pipe is provided between the first filter 18A and the first filter 18B and on the downstream side of the first filter 18B.

In addition, a valve (not shown) is arranged between the stirring tank 10 and the first filter 18A.

Furthermore, a valve (not shown) is arranged on the discharge pipe 20.

In addition, the production device 100 has, apart from the circulation pipe 16, a circulation pipe capable of returning the solution that has passed through the first filter 18A to a position between the stirring tank 10 and the first filter 18A. Incidentally, in the production device 100, apart from the circulation pipe 16, a circulation pipe (hereinafter also referred to as a “circulation pipe X”) capable of returning the solution that has passed through the first filter 18B to a position between the stirring tank 10 and the first filter 18A or to a position between the first filter 18A and the first filter 18B.

Moreover, although the production device 100 has the circulation pipe X, the production device is not limited to the aspect and may not have the circulation pipe X.

The stirring tank 10 is not particularly limited as long as it can accommodate a resin having a polarity that increases by the action of an acid, a photoacid generator, and a solvent, each included in the radiation-sensitive resin composition, and examples thereof include known stirring tanks.

A shape of the bottom part of the stirring tank 10 is not particularly limited, examples thereof include a dish-like end plate shape, a semi-elliptical end plate shape, a flat end plate shape, and a conical end plate shape, and the dish-like end plate shape and the semi-elliptical end plate shape are preferable.

Baffle plates may be installed in the stirring tank 10 in order to improve the stirring efficiency.

The number of the baffle plates is not particularly limited, and is preferably 2 to 8.

A width of the baffle plate is not particularly limited, and is preferably ⅛ to ½ of the diameter of the stirring tank.

A length of the baffle plate in the height direction of the stirring tank is not particularly limited, but is preferably ½ or more, more preferably ⅔ or more, and still more preferably ¾ or more of the height from the bottom part of the stirring tank to the liquid level of the component to be put.

It is preferable that a drive source (for example, a motor) (not shown) is attached to the stirring shaft 12. In a case where the stirring shaft 12 is rotated by the drive source, the stirring blade 14 is rotated and each component put into the stirring tank 10 is stirred.

The shape of the stirring blade 14 is not particularly limited, and examples thereof include a paddle blade, a propeller blade, and a turbine blade.

Furthermore, the stirring tank 10 may have a material charging port for putting various materials into the stirring tank.

Two first filters, a first filter 18A and a first filter 18B, are arranged in the production device 100.

Examples of the method for cleaning the first filter 18A and the first filter 18B in the production device 100 include the following methods. First, the valve on the downstream side of the first filter 18B is closed, and the first solution is supplied from the stirring tank 10 side so that the first filter 18A and the first filter 18B are immersed in the first solution. Thereafter, the filters are immersed for a predetermined time, the valve is opened, and the first solution is discharged from a discharge port not shown in the figure arranged on the downstream side of the first filter 18B.

The mode in which both the first filter 18A and the first filter 18B are immersed in the first solution is described above, but the present invention is not limited to this mode and an immersion treatment may be performed for each filter. For example, the valve between the first filter 18A and the first filter 18B is closed, the first solution is supplied from the stirring tank side, and the first filter 18A is immersed in the first solution. After the immersion treatment, the valve is opened and the first solution after the immersion treatment is discharged from a discharge port (not shown) arranged between the first filter 18A and the first filter 18B. Next, the valve on the downstream side of the first filter 18B is closed and the first solution is supplied from the stirring tank side so that the first filter 18B is immersed in the first solution. After the immersion treatment, the valve is opened and the first solution after the immersion treatment is discharged from a discharge port (not shown) arranged on the downstream side of the first filter 18B.

In addition, in a case where a radiation-sensitive resin composition is used as the first solution, after the radiation-sensitive resin composition is produced in the stirring tank 10, the valve on the downstream side of the first filter 18B is closed, a valve (not shown) arranged between the stirring tank 10 and the first filter 18A is opened, and a part of the radiation-sensitive resin composition in the stirring tank 10 is supplied to the first filter 18A side so that the first filter 18A can be immersed in the radiation-sensitive resin composition. The radiation-sensitive resin composition after the immersion treatment is discharged from the production device 100, and then the radiation-sensitive resin composition remaining in the stirring tank 10 is supplied to the first filter 18A side, whereby a step 2 which will be described later can be carried out.

As described above, the first solution is discarded after the immersion treatment and is not used in the step 2 which will be described later. For example, in a case where a radiation-sensitive resin composition is used as the first solution, the radiation-sensitive resin composition used in the step 1 is not used in the step 2.

Moreover, the mode in which the two first filters are used is described in FIG. 1, but the number of the first filters is not limited to two and may be one or three or more.

In a case where three or more first filters are used, it is preferable that the valve and the discharge port are arranged on the downstream side of each first filter in the production device.

In addition, even in a case where three or more first filters are used as described above, an immersion treatment of the first filters may be performed for each first filter or may be performed collectively.

The mode in which all the first filters used in the step 2 which will be described later are cleaned is described above, but the step 1 may be carried out for at least one first filter used in the step 2.

In addition, the case where the immersion treatment of the first filters is carried out using the production device is described above, but the present invention is not limited to this mode, and the contact between the first solution and the first filter may be carried out while passing the first solution through the first filter.

Furthermore, in a case where the first solution is brought into contact with the first filter, the contact treatment between the first solution and the first filter may be carried out while circulating the first solution. That is, the first solution that has passed through the first filter may be returned to the upstream side of the first filter and a circulation treatment in which the first solution is passed through the first filter may be carried out again.

In addition, the first filter that has been brought into contact with the first solution and cleaned in the step 1 may be temporarily stored inside a container or the like. In addition, in a case where the step 1 is carried out using the production device for a radiation-sensitive resin composition as shown in FIG. 1, the step 2 which will be described later may be carried out with the first filter as it is arranged.

(Step 2)

The step 2 is a step of filtering the radiation-sensitive resin composition using the first filter cleaned in the step 1. By carrying out the present step, impurities in the radiation-sensitive resin composition can be removed.

The constituents included in the radiation-sensitive resin composition used in the step 2 will be described in detail later, but it is typically preferable that the radiation-sensitive resin composition includes a resin having a polarity that increases by the action of an acid, a photoacid generator, and an organic solvent.

The method of filtration is not particularly limited, and examples thereof include a method in which the radiation-sensitive resin composition produced in the stirring tank 10 is fed to the circulation pipe 16 and filtered through the first filter 18A and the first filter 18B in the production device 100 shown in FIG. 1. Furthermore, in a case where the radiation-sensitive resin composition is fed from the stirring tank 10 to the circulation pipe 16, it is preferable to open a valve (not shown) to feed the radiation-sensitive resin composition to the circulation pipe 16.

A method for feeding the radiation-sensitive resin composition from the stirring tank 10 to the circulation pipe 16 is not particularly limited, and examples thereof include a method of feeding a liquid using gravity, a method of applying a pressure from a liquid level side of the radiation-sensitive resin composition, a method of setting a pressure on the circulation pipe 16 side to a negative pressure, and a method obtained by combination of two or more of these methods.

In a case of the method of applying a pressure from the liquid level side of the radiation-sensitive resin composition, examples of the method include a method of utilizing a flow pressure generated by feeding a liquid and a method of pressurizing a gas.

The flow pressure is preferably generated by, for example, a pump (a liquid feeding pump, a circulation pump, and the like), or the like. Examples of the pump include a rotary pump, a diaphragm pump, a metering pump, a chemical pump, a plunger pump, a bellows pump, a gear pump, a vacuum pump, an air pump, and a liquid pump, as well as commercially available pumps as appropriate. A position where the pump is arranged is not particularly limited.

The gas used for pressurization is preferably a gas which is inert or non-reactive with respect to the radiation-sensitive resin composition, and specific examples thereof include nitrogen and noble gases such as helium and argon. Incidentally, it is preferable that the circulation pipe 16 side is not decompressed but has an atmospheric pressure.

As a method of making the circulation pipe 16 side have a negative pressure, decompression by a pump is preferable, and decompression to vacuum is more preferable.

A differential pressure (a pressure difference between the upstream side and the downstream side) applied to the first filter is preferably 200 kPa or less, and more preferably 100 kPa or less.

In addition, during the filtration with the first filter, it is preferable that a change in the differential pressure during the filtration is small. A differential pressure before and after the filtration for a period from a point in time that 90% by mass of the solution to be filtered is finished to a point in time that the passage of the liquid through the first filter is initiated is maintained to be preferably within ±50 kPa, and more preferably within ±20 kPa of the differential pressure before and after the filtration at the point in time that the passage of the liquid is initiated.

During the filtration with the first filter, a linear velocity is preferably 3 to 150 L/(hr·m²), more preferably 5 to 120 L/(hr·m²), and still more preferably 10 to 100 L/(hr·m²).

During the filtration of the radiation-sensitive resin composition with the first filter, circulation filtration may be performed. That is, the radiation-sensitive resin composition that has passed through the first filter may be returned to the upstream side of the first filter and passed through the first filter again.

In addition, the first filter may be passed through the liquid only once without performing the circulation filtration.

in the step 2, only one first filter may be used or two or more first filters may be used, as described above.

### Second Embodiment

Examples of the second embodiment of the method for producing a radiation-sensitive resin composition of the embodiment of the present invention include the following steps 3 to 5 and steps 1 and 2.

Step 3: A step of bringing a second solution including a second organic solvent into contact with a second filter to clean the second filter before the step 2

Step 4: A step of filtering at least one compound of the constituents included in the radiation-sensitive resin composition using the second filter cleaned in the step 3

Step 5: A step of preparing the radiation-sensitive resin composition using the compound obtained in the step 4

Step 1: A step of bringing a first solution including a first organic solvent into contact with a first filter to clean the first filter

Step 2: A step of filtering a radiation-sensitive resin composition using the first filter cleaned in the step 1

The procedures of the steps 1 and 2 are as described above, and a description thereof will be omitted.

It is preferable that the steps 3 to 5 are usually carried out before the steps 1 and 2. The steps 3 to 5 are carried out in this order.

In the mode, a raw material of the radiation-sensitive resin composition is filtered with the second filter to remove impurities in the raw material before preparing the radiation-sensitive resin composition. In particular, in the mode, the second filter used in the filtration of the raw material is cleaned by bringing the second filter into contact with a solution including an organic solvent in the same manner as in the above-mentioned first embodiment, thereby further reducing the impurities included in the radiation-sensitive resin composition.

Hereinafter, the steps 3 to 5 will be described in detail.

(Step 3)

The step 3 is a step of bringing a second solution including a second organic solvent into contact with a second filter to clean the second filter before the step 2. The present step may be carried out before the step 2 or may be carried out before or after the step 1.

A suitable mode of the second organic solvent used in the step 3 is the same as the suitable mode of the first organic solvent used in the step 1. That is, as the second organic solvent, an organic solvent having an SP value of 17.0 MPa^{1/2} or more and less than 25.0 MPa^{1/2} is preferable.

A content of the second organic solvent in the second solution is not particularly limited, but from the viewpoint that the effect of the present invention is more excellent, the content is preferably 50% by mass or more, more preferably 70% by mass or more, and still more preferably 90% by mass or more with respect to the total mass of the second solution. The upper limit may be 100% by mass.

The second solution may include only one kind of second organic solvent or may include two or more kinds of second organic solvents.

Furthermore, it is preferable to use the organic solvent included in the radiation-sensitive resin composition prepared in the step 4 which will be described later as the second organic solvent.

In a case where the second solution and the second filter are brought into contact with each other for cleaning, the second solution may remain in the second filter after the cleaning. Therefore, for example, in a case where the second solution consists only of an organic solvent not included in the radiation-sensitive resin composition prepared in the step 4 and at least one compound of the constituents included in the radiation-sensitive resin composition is filtered using the second filter brought in contact with the second solution, there is a possibility that the second solution remaining in the second filter is partially incorporated into at least one compound of the constituents included in the radiation-sensitive resin composition that has passed through the second filter and the organic solvent that is not supposed to be used is incorporated into the radiation-sensitive resin composition.

In contrast, in a case where the organic solvent included in the radiation-sensitive resin composition prepared in the step 4 which will be described later is used as the second organic solvent, there is a possibility that even in a case where the second solution remains in the second filter, the radiation-sensitive resin composition only includes the organic solvent which is supposed to be used, which is preferable due to no influence on the composition of the components.

The second solution may include components other than the second organic solvent.

The definition and a suitable mode of the second filter are the same as the definition and the suitable mode of the first filter.

[Procedure of Step 3]

A contact time between the second filter and the second solution is not particularly limited, but is preferably 1 hour or more, and more preferably 2 hours or more from the viewpoint that the effect of the present invention is more excellent. The upper limit is not particularly limited, but is preferably 15 hours or less from the viewpoint of productivity.

A method of bringing the second solution into contact with the second filter may be either a method of immersing the second filter in the second solution or a method of bringing the second solution into contact with the second filter while passing the second solution through the second filter. In a case of the method of immersing the second filter in the second solution, the above-mentioned contact time corresponds to the immersion time, and in a case of the method of passing the second solution through the second filter, the above-mentioned contact time corresponds to the liquid passing time.

Furthermore, from the viewpoint that the effect of the present invention is more excellent, a treatment of immersing the filter in the second solution to clean the second filter is preferable.

The second filter is preferably arranged so that the liquid passing direction is from the lower side to the upper side in the vertical direction. That is, in a case where the second solution is passed through the second filter, it is preferable to arrange the second filter so that the second solution passes from the lower side to the upper side in the vertical direction. With the arrangement, air bubbles included in the second filter can be efficiently removed.

The contact between the second solution and the second filter may be carried out under normal pressure or may be carried out under pressurization.

As the condition for pressurization, the pressure is preferably 50 kPa or more, more preferably 100 kPa or more, and still more preferably 200 kPa. The upper limit is not particularly limited, but it depends on a maximum permissible differential pressure of a filter used.

Furthermore, in a case where the second solution and the second filter are brought into contact with each other, the contact treatment between the second solution and the second filter may be carried out while circulating the second solution. That is, the second solution that has passed through the second filter may be returned to the upstream side of the second filter, and a circulation treatment in which the second solution is passed through the second filter may be carried out again.

In addition, after the contact treatment, a predetermined amount of the second solution may pass through the second filter, as necessary. A passage volume of the second solution is preferably 5 kg or more, more preferably 10 kg or more, and still more preferably 15 kg or more per first filter. The upper limit is not particularly limited, but is preferably 100 kg or less from the viewpoint of productivity.

A linear velocity (linear velocity of the second solution) in a case where the second solution is passed through the second filter is not particularly limited, but is preferably 40 L/(hr·m²) or less, more preferably 25 L/(hr·m²) or less, and still more preferably 10 L/(hr·m²) or less.

The linear velocity is obtained by measuring a flow amount in a case where the second solution passes through with a commercially available flow meter and dividing the obtained flow rate by a film area of the second filter.

(Step 4)

The step 4 is a step of filtering at least one compound of the constituents included in the radiation-sensitive resin composition using the second filter cleaned in the step 3.

The constituents included in the radiation-sensitive resin composition used in the step 4 will be described in detail later, but examples thereof include a resin having a polarity that increases by the action of an acid, a photoacid generator, and an organic solvent.

In a case where an object to be filtered is a solid content, the object and the organic solvent may be mixed to form a solution, which is subjected to the filtration treatment, as necessary.

The type of the organic solvent used is not particularly limited, but an organic solvent included in the radiation-sensitive resin composition prepared in the step 5 which will be described later is preferable.

The filtration method is not particularly limited, and examples thereof include known methods.

A differential pressure (a pressure difference between the upstream side and the downstream side) applied to the second filter is preferably 200 kPa or less, and more preferably 100 kPa or less.

In addition, in a case of performing the filtration with the second filter, it is preferable that a change in the differential pressure during the filtration is small. The differential pressure before and after the filtration for a period from a point in time that 90% by mass of the solution to be filtered is finished to a point in time that the passage of the liquid through the second filter is initiated is maintained to be preferably within ±50 kPa, and more preferably within ±20 kPa of the differential pressure before and after the filtration at the point in time that the passage of the liquid is initiated.

In a case of performing the filtration with the second filter, a linear velocity is preferably 3 to 150 L/(hr·m²), more preferably 5 to 120 L/(hr·m²), and still more preferably 10 to 100 L/(hr·m²).

During the filtration of the compound with the second filter, circulatory filtration may be carried out. That is, the compound that has passed through the second filter may be returned to the upstream side of the second filter and passed through the second filter again.

In the step 4, only one second filter may be used or two or more second filters may be used.

The step 4 may be carried out for at least one compound of the constituents included in the radiation-sensitive resin composition, and may also be carried out for all the constituents included in the radiation-sensitive resin composition.

(Step 5)

The step 5 is a step of preparing the radiation-sensitive resin composition using the compound obtained in the step 4.

The method for preparing the radiation-sensitive resin composition using the compound filtered in the step 4 is not particularly limited, and examples thereof include a known method. For example, a method for preparing a radiation-sensitive resin composition by mixing the compound obtained in the step 4 and other necessary components can be mentioned.

<Pattern Forming Method>

The radiation-sensitive resin composition produced by the above-mentioned production method is used for pattern formation.

More specifically, the procedure of the pattern forming method using the composition of the present invention is not particularly limited, but preferably has the following steps.

Step A: A step of forming a resist film on a substrate using the composition of the present invention

Step B: A step of exposing the resist film

Step C: A step of developing the exposed resist film, using a developer to form a pattern

Hereinafter, the procedure of each of the steps will be described in detail.

(Step A: Resist Film Forming Step)

The step A is a step of forming a resist film on a substrate using the composition of the present invention.

The composition of the present invention is as described above.

Examples of the method of forming a resist film on a substrate using the composition include a method of applying the composition onto a substrate.

The composition can be applied onto a substrate (for example, silicon and silicon dioxide coating) as used in the manufacture of integrated circuit elements by a suitable application method such as ones using a spinner or a coater. As the application method, spin application using a spinner is preferable.

After applying the composition, the substrate may be dried to form a resist film. In addition, various underlying films (an inorganic film, an organic film, or an antireflection film) may be formed on the underlayer of the resist film.

Examples of the drying method include a heating method (pre-baking: PB). The heating may be performed using a unit included in an ordinary exposure machine and/or an ordinary development machine, and may also be performed using a hot plate or the like.

The heating temperature is preferably 80° C. to 150° C., and more preferably 80° C. to 140° C.

The heating time is preferably 30 to 1,000 seconds, and more preferably 40 to 800 seconds.

A film thickness of the resist film is not particularly limited, but in a case of a resist film for KrF exposure, the film thickness is preferably 0.2 to 15 μm, and more preferably 0.3 to 5 μm.

In addition, in a case of a resist film for ArF exposure or EUV exposure, the film thickness is preferably 30 to 700 nm, and more preferably 40 to 400 nm.

Moreover, a topcoat may be formed on the upper layer of the resist film, using the topcoat composition.

It is preferable that the topcoat composition is not mixed with the resist film and can be uniformly applied onto the upper layer of the resist film.

The film thickness of the topcoat is preferably 10 to 200 nm, and more preferably 20 to 100 nm.

The topcoat is not particularly limited, a topcoat known in the related art can be formed by a method known in the related art, and for example, the topcoat can be formed in accordance with the description in paragraphs 0072 to 0082 of JP2014-059543A.

(Step B: Exposing Step)

The step B is a step of exposing the resist film.

Examples of the exposing method include a method of irradiating a resist film thus formed with radiation through a predetermined mask.

Examples of the radiation include infrared light, visible light, ultraviolet light, far ultraviolet light, extreme ultraviolet light, X-rays, and electron beams (EB), preferably a far ultraviolet light having a wavelength of 250 nm or less, more preferably a far ultraviolet light having a wavelength of 220 nm or less, and still more preferably a far ultraviolet light having a wavelength of 1 to 200 nm, specifically, KrF excimer laser (248 nm), ArF excimer laser (193 nm), F₂ excimer laser (157 nm), EUV (13 nm), X-rays, and EB.

It is preferable to bake (post-exposure bake: PEB) after exposure and before developing.

The heating temperature is preferably 80° C. to 150° C., and more preferably 80° C. to 140° C.

The heating time is preferably 10 to 1,000 seconds, and more preferably 10 to 180 seconds.

The heating may be performed using a unit included in an ordinary exposure machine and/or an ordinary development machine, and may also be performed using a hot plate or the like.

This step is also described as a post-exposure baking.

(Step C: Developing Step)

The step C is a step of developing the exposed resist film using a developer to form a pattern.

Examples of the developing method include a method in which a substrate is immersed in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously jetted onto a substrate rotating at a constant rate while scanning a developer jetting nozzle at a constant rate (a dynamic dispense method).

Furthermore, after the step of performing development, a step of stopping the development may be carried out while substituting the solvent with another solvent.

A developing time is not particularly limited as long as it is a period of time where the unexposed area of a resin is sufficiently dissolved, and is preferably 10 to 300 seconds, and more preferably 20 to 120 seconds.

The temperature of the developer is preferably 0° C. to 50° C., and more preferably 15° C. to 35° C.

Examples of the developer include an alkali developer and an organic solvent developer.

As the alkali developer, it is preferable to use an aqueous alkaline solution including an alkali. Among those, the aqueous solutions of the quaternary ammonium salts typified by tetramethylammonium hydroxide (TMAH) are preferable as the alkali developer. An appropriate amount of an alcohol, a surfactant, or the like may be added to the alkali developer. The alkali concentration of the alkali developer is usually 0.1% to 20% by mass. Furthermore, the pH of the alkali developer is usually 10.0 to 15.0.

The organic solvent developer is a developer including an organic solvent.

Examples of the organic solvent used in the organic solvent developer include known organic solvents, and include an ester-based solvent, a ketone-based solvent, an alcohol-based solvent, an amide-based solvent, an ether-based solvent, and a hydrocarbon-based solvent.

(Other Steps)

It is preferable that the pattern forming method includes a step of performing cleaning using a rinsing liquid after the step C.

Examples of the rinsing liquid used in the rinsing step after the step of performing development using the developer include pure water. Furthermore, an appropriate amount of a surfactant may be added to pure water.

An appropriate amount of a surfactant may be added to the rinsing liquid.

In addition, an etching treatment on the substrate may be carried out using a pattern formed as a mask. That is, the substrate (or the underlayer film and the substrate) may be processed using the pattern thus formed in the step C as a mask to form a pattern on the substrate.

A method for processing the substrate (or the underlayer film and the substrate) is not particularly limited, but a method in which a pattern is formed on a substrate by subjecting the substrate (or the underlayer film and the substrate) to dry etching using the pattern thus formed in the step C as a mask is preferable.

The dry etching may be one-stage etching or multi-stage etching. In a case where the etching is etching including a plurality of stages, the etchings at the respective stages may be the same treatment or different treatments.

For etching, any of known methods can be used, and various conditions and the like are appropriately determined according to the type of a substrate, usage, and the like. Etching can be carried out, for example, in accordance with Journal of The International Society for Optical Engineering (Proc. of SPIE), Vol. 6924, 692420 (2008), JP2009-267112A, and the like. In addition, the etching can also be carried out in accordance with “Chapter 4 Etching” in “Semiconductor Process Text Book, 4^{th} Ed., published in 2007, publisher: SEMI Japan”.

Among those, oxygen plasma etching is preferable as the dry etching.

<Radiation-Sensitive Resin Composition>

The constituents included in the radiation-sensitive resin composition are not particularly limited, and examples thereof include a resin having a polarity that increases by the action of an acid, a photoacid generator, and a solvent.

Hereinafter, the components included in the radiation-sensitive resin composition will be described in detail.

<Resin Having Polarity That Increases by Action of Acid>

The radiation-sensitive resin composition preferably includes a resin having a polarity that increases by the action of an acid (hereinafter also simply referred to as a “resin (A)”).

The resin (A) preferably has a repeating unit (A-a) having an acid-decomposable group (hereinafter also simply referred to as a “repeating unit (A-a)”).

The acid-decomposable group is a group that decomposes by the action of an acid to produce a polar group. The acid-decomposable group preferably has a structure in which the polar group is protected by a leaving group that leaves by the action of an acid. That is, the resin (A) has a repeating unit (A-a) having a group that decomposes by the action of an acid to produce a polar group. A resin having this repeating unit (A-a) has an increased polarity by the action of an acid, and thus has an increased solubility in an alkali developer, and a decreased solubility in an organic solvent.

As the polar group, an alkali-soluble group is preferable, and examples thereof include an acidic group such as a carboxyl group, a phenolic hydroxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

Among those, as the polar group, the carboxyl group, the phenolic hydroxyl group, the fluorinated alcohol group (preferably a hexafluoroisopropanol group), or the sulfonic acid group is preferable.

Examples of the leaving group that leaves by the action of an acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (A4):

In Formula (Y1) and Formula (Y2), Rx₁ to Rx₃ each independently represent an (linear or branched) alkyl group or (monocyclic or polycyclic) cycloalkyl group, an (linear or branched) alkenyl group, or an (monocyclic or polycyclic) aryl group. Furthermore, in a case where all of Rx₁ to Rx₃ are each an (linear or branched) alkyl group, it is preferable that at least two of Rx₁, Rx₂, or R₃ are methyl groups.

Above all, it is preferable that Rx₁ to Rx₃ each independently represent a linear or branched alkyl group, and it is more preferable that Rx₁ to Rx₃ each independently represent the linear alkyl group.

Two of Rx₁ to Rx₃ may be bonded to each other to form a monocycle or a polycycle. As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group as each of Rx₁ to Rx₃, an aryl group having 6 to 10 carbon atoms is preferable, and examples thereof include a phenyl group, a naphthyl group, and an anthryl group.

As the alkenyl group of each of Rx₁ to Rx₃, a vinyl group is preferable.

As the cycloalkyl group formed by the bonding of two of Rx₁ to Rx₃, a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group is preferable, and a monocyclic cycloalkyl group having 5 or 6 carbon atoms is more preferable.

In the cycloalkyl group formed by the bonding of two of Rx₁ to Rx₃, for example, one of the methylene groups constituting the ring may be substituted with a heteroatom such as an oxygen atom, or a group having a heteroatom, such as a carbonyl group.

With regard to the group represented by Formula (Y1) or Formula (Y2), for example, an aspect in which Rx₁ is a methyl group or an ethyl group, and Rx₂ and Rx₃ are bonded to each other to form a cycloalkyl group is preferable.

In a case where the composition of the present invention is, for example, a resist composition for EUV exposure, it is preferable that an alkyl group, a cycloalkyl group, an alkenyl group, or an aryl group represented by each of Rx₁ to Rx₃, and a ring formed by the bonding of two of Rx₁ to Rx₃ further has a fluorine atom or an iodine atom as a substituent.

In Formula (Y3), R₃₆ to R₃₈ each independently represent a hydrogen atom or a monovalent substituent. R₃₇ and R₃₈ may be bonded to each other to form a ring. Examples of the monovalent substituent include an alkyl group, a cycloalkyl group, an aryl group, an aralkyl group, and an alkenyl group. It is also preferable that R₃₆ is the hydrogen atom.

As Formula (Y3), a group represented by Formula (Y3-1) is preferable.

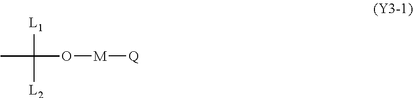

Here, L₁ and L₂ each independently represent a hydrogen atom, an alkyl group, a cycloalkyl group, an aryl group, or a group formed by combination thereof (for example, a group formed by combination of an alkyl group and an aryl group).

M represents a single bond or a divalent linking group.

Q represents an alkyl group which may have a heteroatom, a cycloalkyl group which may have a heteroatom, an aryl group which may have a heteroatom, an amino group, an ammonium group, a mercapto group, a cyano group, an aldehyde group, or a group formed by combination thereof (for example, a group formed by combination of an alkyl group and a cycloalkyl group).

In the alkyl group and the cycloalkyl group, for example, one of the methylene groups may be substituted with a heteroatom such as an oxygen atom or a group having a heteroatom, such as a carbonyl group.

In addition, it is preferable that one of L₁ or L₂ is a hydrogen atom, and the other is an alkyl group, a cycloalkyl group, an aryl group, or a group formed by combination of an alkylene group and an aryl group.

At least two of Q, M, or L₁ may be bonded to each other to form a ring (preferably a 5- or 6-membered ring).

From the viewpoint of pattern miniaturization, L₂ is preferably a secondary or tertiary alkyl group, and more preferably the tertiary alkyl group. Examples of the secondary alkyl group include an isopropyl group, a cyclohexyl group, and a norbornyl group, and examples of the tertiary alkyl group include a tert-butyl group and an adamantane ring group. In these aspects, since the glass transition temperature (Tg) and the activation energy are increased, it is possible to suppress fogging in addition to ensuring film hardness.

In Formula (Y4), Ar represents an aromatic ring group. Rn represents an alkyl group, a cycloalkyl group, or an aryl group. Rn and Ar may be bonded to each other to form a non-aromatic ring. Ar is more preferably the aryl group.

As the repeating unit (A-a), a repeating unit represented by Formula (A) is also preferable.

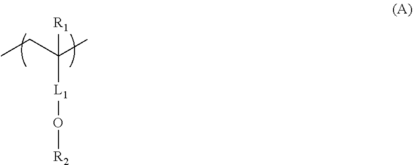

L₁ represents a divalent linking group which may have a fluorine atom or an iodine atom, R₁ represents a hydrogen atom, a fluorine atom, an iodine atom, a fluorine atom, an alkyl group which may have an iodine atom, or an aryl group which may have a fluorine atom or an iodine atom, and R2 represents a leaving group that leaves by the action of an acid and may have a fluorine atom or an iodine atom. It should be noted that at least one of L₁, R₁, or R₂ has a fluorine atom or an iodine atom.

L₁ represents a divalent linking group which may have a fluorine atom or an iodine atom. Examples of the divalent linking group which may have a fluorine atom or an iodine atom include —CO—, —O—, —S—, —SO—, —SO₂—, a hydrocarbon group which may have a fluorine atom or an iodine atom (for example, an alkylene group, a cycloalkylene group, an alkenylene group, and an arylene group), and a linking group formed by the linking of a plurality of these groups. Among those, L₁ is preferably —CO—, or -arylene group-alkylene group having fluorine atom or iodine atom from the viewpoint that the effect of the present invention is more excellent.

As the arylene group, a phenylene group is preferable.

The alkylene group may be linear or branched. The number of carbon atoms of the alkylene group is not particularly limited, but is preferably 1 to 10, and more preferably 1 to 3.

The total number of fluorine atoms and iodine atoms included in the alkylene group having a fluorine atom or an iodine atom is not particularly limited, but is preferably 2 or more, more preferably 2 to 10, and still more preferably 3 to 6 from the viewpoint that the effect of the present invention is more excellent.

R₁ represents a hydrogen atom, a fluorine atom, an iodine atom, an alkyl group which may have a fluorine atom or an iodine atom, or an aryl group which may have a fluorine atom or an iodine atom.

The alkyl group may be linear or branched. The number of carbon atoms of the alkyl group is not particularly limited, but is preferably 1 to 10, and more preferably 1 to 3.

The total number of fluorine atoms and iodine atoms included in the alkyl group having a fluorine atom or an iodine atom is not particularly limited, but is preferably 1 or more, more preferably 1 to 5, and still more preferably 1 to 3 from the viewpoint that the effect of the present invention is more excellent.

The alkyl group may have a heteroatom such as an oxygen atom, other than a halogen atom.

R₂ represents a leaving group that leaves by the action of an acid and may have a fluorine atom or an iodine atom.

Among those, examples of the leaving group include groups represented by Formulae (Z1) to (Z4).

—C(Rx₁₁)(Rx₁₂)(Rx₁₃). Formula (Z1):

—C(═O)OC(Rx₁₁)(Rx₁₂)(Rx₁₃). Formula (Z2):

—C(R₁₃₆)(R₁₃₇)(OR₁₃₈). Formula (Z3):

—C(Rn₁)(H)(Ar₁) Formula (Z4):

In Formulae (Z1) and (Z2), Rx₁₁ to Rx₁₃ each independently represent an (linear or branched) alkyl group which may have a fluorine atom or an iodine atom, or a (monocyclic or polycyclic) cycloalkyl group which may have a fluorine atom or an iodine atom. Furthermore, in a case where all of Rx₁₁ to Rx₁₃ are each an (linear or branched) alkyl group, it is preferable that at least two of Rx₁₁, Rx₁₂, or Rx₁₃ are methyl groups.

Rx₁₁ to Rx₁₃ are the same as Rx₁ to Rx₃ in Formulae (Y1) and (Y2) mentioned above, respectively, except that they may have a fluorine atom or an iodine atom, and have the same definitions and suitable ranges as those of the alkyl group and the cycloalkyl group.

In Formula (Z3), R₁₃₆ to R₁₃₈ each independently represent a hydrogen atom, or a monovalent organic group which may have a fluorine atom or an iodine atom. R₁₃₇ and R₁₃₈ may be bonded to each other to form a ring. Examples of the monovalent organic group which may have a fluorine atom or an iodine atom include an alkyl group which may have a fluorine atom or an iodine atom, a cycloalkyl group which may have a fluorine atom or an iodine atom, an aryl group which may have a fluorine atom or an iodine atom, an aralkyl group which may have a fluorine atom or an iodine atom, and a group formed by combination thereof (for example, a group formed by combination of the alkyl group and the cycloalkyl group).

Incidentally, the alkyl group, the cycloalkyl group, the aryl group, and the aralkyl group may include a heteroatom such as an oxygen atom, in addition to the fluorine atom and the iodine atom. That is, in the alkyl group, the cycloalkyl group, the aryl group, and the aralkyl group, for example, one of the methylene groups may be substituted with a heteroatom such as an oxygen atom or a group having a heteroatom, such as a carbonyl group.

As Formula (Z3), a group represented by Formula (Z3-1) is preferable.

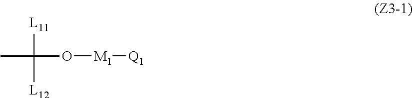

Here, L₁₁ and L₁₂ each independently represent a hydrogen atom; an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; or a group formed by combination thereof (for example, a group formed by combination of an alkyl group and a cycloalkyl group, each of which may have a heteroatom selected from the group consisting of a fluorine atom, an iodine atom, and an oxygen atom).

M₁ represents a single bond or a divalent linking group.

Q₁ represents an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; an amino group; an ammonium group; a mercapto group; a cyano group; an aldehyde group; a group formed by combination thereof (for example, a group formed by combination of the alkyl group and the cycloalkyl group, each of which may have a heteroatom selected from the group consisting of a fluorine atom, an iodine atom, and an oxygen atom).

In Formula (Y4), Ar₁ represents an aromatic ring group which may have a fluorine atom or an iodine atom. Rn₁ is an alkyl group which may have a fluorine atom or an iodine atom, a cycloalkyl group which may have a fluorine atom or an iodine atom, or an aryl group which may have a fluorine atom or an iodine atom. Rn₁ and Ar₁ may be bonded to each other to form a non-aromatic ring.

As the repeating unit (A-a), a repeating unit represented by General Formula (AI) is also preferable.

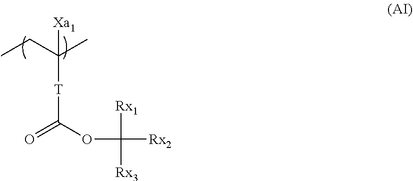

In General Formula (AI),

Xa₁ represents a hydrogen atom, or an alkyl group which may have a substituent.

T represents a single bond or a divalent linking group.

Rx₁ to Rx₃ each independently represent an (linear or branched) alkyl group, a (monocyclic or polycyclic) cycloalkyl group, an (linear or branched) alkenyl group, or an (monocyclic or polycyclic) aryl group. It should be noted that in a case where all of Rx₁ to Rx₃ are (linear or branched) alkyl groups, it is preferable that at least two of Rx₁, Rx₂, or Rx₃ are methyl groups.

Two of Rx₁ to Rx₃ may be bonded to each other to form a (monocyclic or polycyclic) cycloalkyl group.

Examples of the alkyl group which may have a substituent, represented by Xa₁, include a methyl group and a group represented by —CH₂—R₁₁. R₁₁ represents a halogen atom (a fluorine atom or the like), a hydroxyl group, or a monovalent organic group, examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. Xa₁ is preferably a hydrogen atom, a methyl group, a trifluoromethyl group, or a hydroxymethyl group.

Examples of the divalent linking group of T include an alkylene group, an aromatic ring group, a —COO-Rt- group, and an —O-Rt- group. In the formulae, Rt represents an alkylene group or a cycloalkylene group.

T is preferably the single bond or the —COO-Rt- group. In a case where T represents the —COO-Rt-group, Rt is preferably an alkylene group having 1 to 5 carbon atoms, and more preferably a —CH₂— group, a —(CH₂)₂— group, or a —(CH₂)₃— group.

As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group as each of Rx₁ to Rx₃, an aryl group having 6 to 10 carbon atoms is preferable, and examples thereof include a phenyl group, a naphthyl group, and an anthryl group.

As the alkenyl group of each of Rx₁ to Rx₃, a vinyl group is preferable. As the cycloalkyl group formed by the bonding of two of Rx₁ to Rx₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is also preferable. Among those, a monocyclic cycloalkyl group having 5 or 6 carbon atoms is preferable.

In the cycloalkyl group formed by the bonding of two of Rx₁ to Rx₃, for example, one of the methylene groups constituting the ring may be substituted with a heteroatom such as an oxygen atom, or a group having a heteroatom, such as a carbonyl group.

With regard to the repeating unit represented by General Formula (AI), for example, an aspect in which Rx₁ is a methyl group or an ethyl group, and Rx₂ and Rx₃ are bonded to each other to form the above-mentioned cycloalkyl group is preferable.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

The repeating unit represented by General Formula (AI) is preferably an acid-decomposable tertiary alkyl (meth)acrylate ester-based repeating unit (the repeating unit in which Xa₁ represents a hydrogen atom or a methyl group, and T represents a single bond).

The resin (A) may have one kind of the repeating unit (A-a) alone or may have two or more kinds thereof.

A content of the repeating unit (A-a) (a total content in a case where two or more kinds of the repeating units (A-a) are present) is preferably 15% to 80% by mole, and more preferably 20% to 70% by mole with respect to all repeating units in the resin (A).

The resin (A) preferably has at least one repeating unit selected from the group consisting of repeating units represented by General Formulae (A-VIII) to (A-XII) as the repeating unit (A-a).

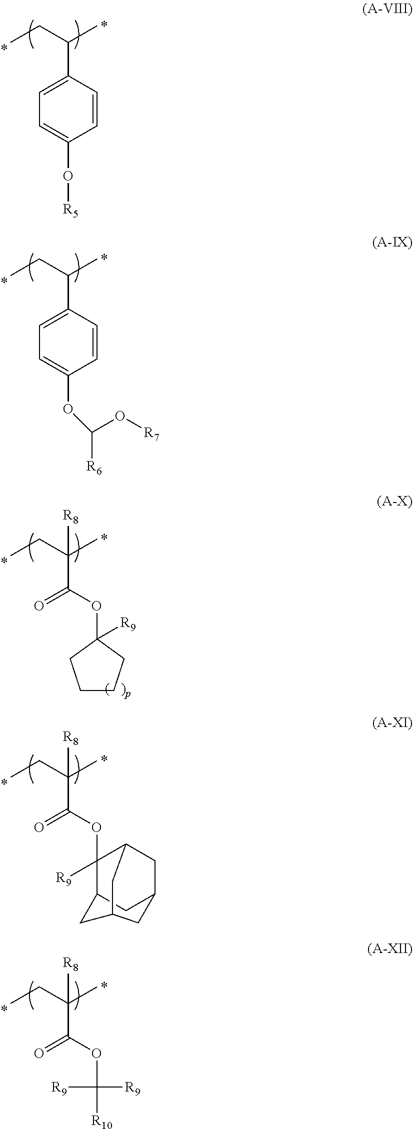

In General Formula (A-VIII), R₅ represents a tert-butyl group or a —CO—O-(tert-butyl) group.

In General Formula (A-IX), R₆ and R₇ each independently represent a monovalent organic group. Examples of the monovalent organic group include an alkyl group, a cycloalkyl group, an aryl group, an aralkyl group, and an alkenyl group.

In General Formula (A-X), p represents 1 to 5, and is preferably 1 or 2.

In General Formulae (A-X) to (A-XII), R₈ represents a hydrogen atom or an alkyl group having 1 to 3 carbon atoms, and R₉ represents an alkyl group having 1 to 3 carbon atoms.

In General Formula (A-XII), R₁₀ represents an alkyl group having 1 to 3 carbon atoms or an adamantyl group.

(Repeating Unit Having Acid Group)

The resin (A) may have a repeating unit having an acid group.

As the acid group, an acid group having a pKa of 13 or less is preferable. The acid dissociation constant of the acid group is preferably 13 or less, more preferably 3 to 13, and still more preferably 5 to 10, as described above.

In a case where the acid-decomposable resin has an acid group having a pKa of 13 or less, the content of the acid group in the acid-decomposable resin is not particularly limited, but is 0.2 to 6.0 mmol/g in many cases. Among those, the content of the acid group is preferably 0.8 to 6.0 mmol/g, more preferably 1.2 to 5.0 mmol/g, and still more preferably 1.6 to 4.0 mmol/g. In a case where the content of the acid group is within the range, the progress of development is improved, and thus, the shape of a pattern thus formed is excellent and the resolution is also excellent.

As the acid group, for example, a carboxyl group, a hydroxyl group, a phenolic hydroxyl group, a fluorinated alcohol group (preferably a hexafluoroisopropanol group), a sulfonic acid group, or a sulfonamide group is preferable.

In addition, the hexafluoroisopropanol group, in which one or more (preferably one or two) fluorine atoms are substituted with a group other than a fluorine atom, is also preferable as the acid group. Examples of such a group include a group containing —C(CF₃)(OH)—CF₂—. Furthermore, the group including —C(CF₃)(OH)—CF₂— may be a ring group including —C(CF₃)(OH)—CF₂—.

As the repeating unit having an acid group, a repeating unit represented by General Formula (B) is preferable.

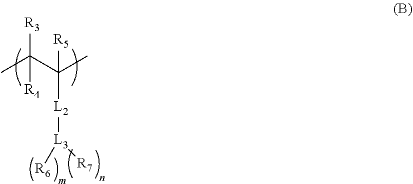

R₃ represents a hydrogen atom or a monovalent substituent which may have a fluorine atom or an iodine atom. The monovalent substituent which may have a fluorine atom or an iodine atom is preferably a group represented by -L₄-R₈. L₄ represents a single bond or an ester group. R₈ is an alkyl group which may have a fluorine atom or an iodine atom, a cycloalkyl group which may have a fluorine atom or an iodine atom, an awl group which may have a fluorine atom or an iodine atom, or a group formed by combination thereof.

R₄ and R₅ each independently represent a hydrogen atom, a fluorine atom, an iodine atom, or an alkyl group which may have a fluorine atom or an iodine atom.

L₂ represents a single bond or an ester group.

L₃ represents an (n+m+1)-valent aromatic hydrocarbon ring group or an (n+m+1)-valent alicyclic hydrocarbon ring group. Examples of the aromatic hydrocarbon ring group include a benzene ring group and a naphthalene ring group. The alicyclic hydrocarbon ring group may be either a monocycle or a polycycle, and examples thereof include a cycloalkyl ring group.

R₆ represents a hydroxyl group or a fluorinated alcohol group (preferably a hexafluoroisopropanol group). Furthermore, in a case where R₆ is a hydroxyl group, L₃ is preferably the (n+m+1)-valent aromatic hydrocarbon ring group.

R₇ represents a halogen atom. Examples of the halogen atom include a fluorine atom, a chlorine atom, a bromine atom, and an iodine atom.

m represents an integer of 1 or more. m is preferably an integer of 1 to 3 and more preferably an integer of 1 or 2.

n represents 0 or an integer of 1 or more. n is preferably an integer of 1 to 4.

Furthermore, (n+m+1) is preferably an integer of 1 to 5.

As the repeating unit having an acid group, a repeating unit represented by General Formula (I) is also preferable.

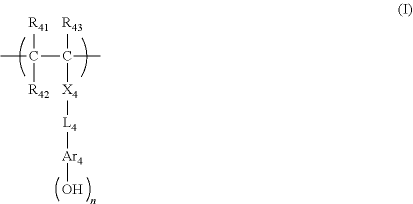

In General Formula (I),

R₄₁, R₄₂, and R₄₃ each independently represent a hydrogen atom, an alkyl group, a cycloalkyl group, a halogen atom, a cyano group, or an alkoxycarbonyl group. It should be noted that R₄₂ may be bonded to Ar₄ to form a ring, in which case R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group, and in a case where Ar4 is bonded to R₄₂ to form a ring, Ar₄ represents an (n+2)-valent aromatic ring group.

n represents an integer of 1 to 5.

As the alkyl group represented by each of R₄₁, R₄₂, and R₄₃ in General Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group is preferable, an alkyl group having 8 or less carbon atoms is more preferable, and an alkyl group having 3 or less carbon atoms is still more preferable.

The cycloalkyl group of each of R₄₁, R₄₂, and R₄₃ in General Formula (I) may be monocyclic or polycyclic. Among those, a monocyclic cycloalkyl group having 3 to 8 carbon atoms, such as a cyclopropyl group, a cyclopentyl group, and a cyclohexyl group, is preferable.

Examples of the halogen atom of each of R₄₁, R₄₂, and R₄₃ in General Formula (I) include a fluorine atom, a chlorine atom, a bromine atom, and an iodine atom, and the fluorine atom is preferable.

As the alkyl group included in the alkoxycarbonyl group of each of R₄₁, R₄₂, and R₄₃ in General Formula (I), the same ones as the alkyl group in each of R₄₁, R₄₂, and R₄₃ are preferable.

Ar₄ represents an (n+1)-valent aromatic ring group. The divalent aromatic ring group in a case where n is 1 may have a substituent, and is preferably for example, an arylene group having 6 to 18 carbon atoms, such as a phenylene group, a tolylene group, a naphthylene group, and an anthracenylene group, or an aromatic ring group including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring.

Specific examples of the (n+1)-valent aromatic ring group in a case where n is an integer of 2 or more include groups formed by removing any (n−1) hydrogen atoms from the above-described specific examples of the divalent aromatic ring group. The (n+1)-valent aromatic ring group may further have a substituent.

Examples of the substituent which can be contained in the alkyl group, the cycloalkyl group, the alkoxycarbonyl group, the alkylene group, and the (n+1)-valent aromatic ring group, each mentioned above, include the alkyl groups; the alkoxy groups such as a methoxy group, an ethoxy group, a hydroxyethoxy group, a propoxy group, a hydroxypropoxy group, and a butoxy group; the aryl groups such as a phenyl group; and the like, as mentioned for each of R₄₁, R₄₂, and R₄₃ in General Formula (I).

Examples of the alkyl group of R₆₄ in —CONR₆₄— represented by X₄ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms, is preferable.

As X₄, a single bond, —COO—, or —CONH— is preferable, and the single bond or —COO— is more preferable.

As the alkylene group in L₄, an alkylene group having 1 to 8 carbon atoms, such as a methylene group, an ethylene group, a propylene group, a butylene group, a hexylene group, and an octylene group, is preferable.

As Ar₄, an aromatic ring group having 6 to 18 carbon atoms is preferable, and a benzene ring group, a naphthalene ring group, and a biphenylene ring group are more preferable.

Specific examples of the repeating unit represented by General Formula (I) will be shown below, but the present invention is not limited thereto. In the formulae, a represents 1 or 2.

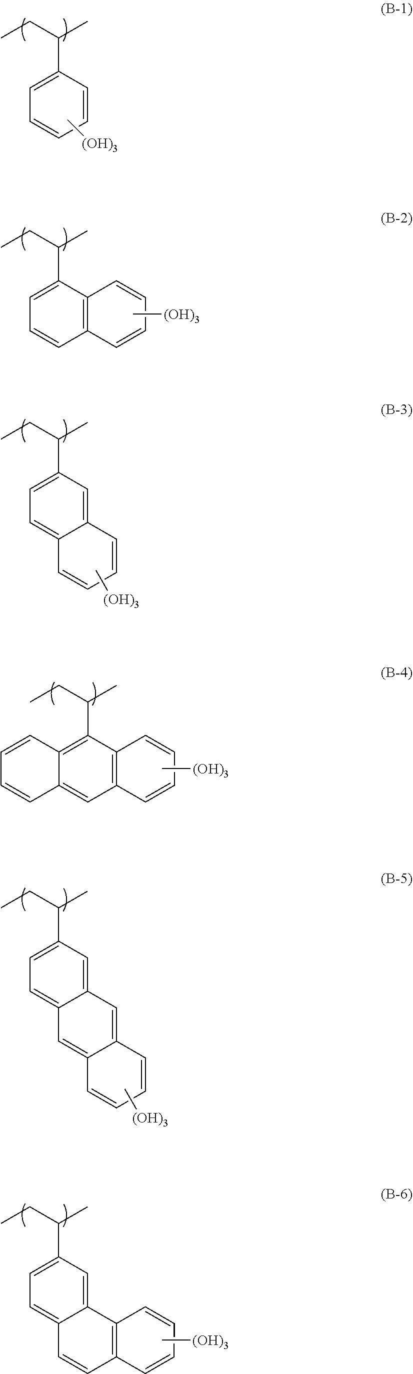

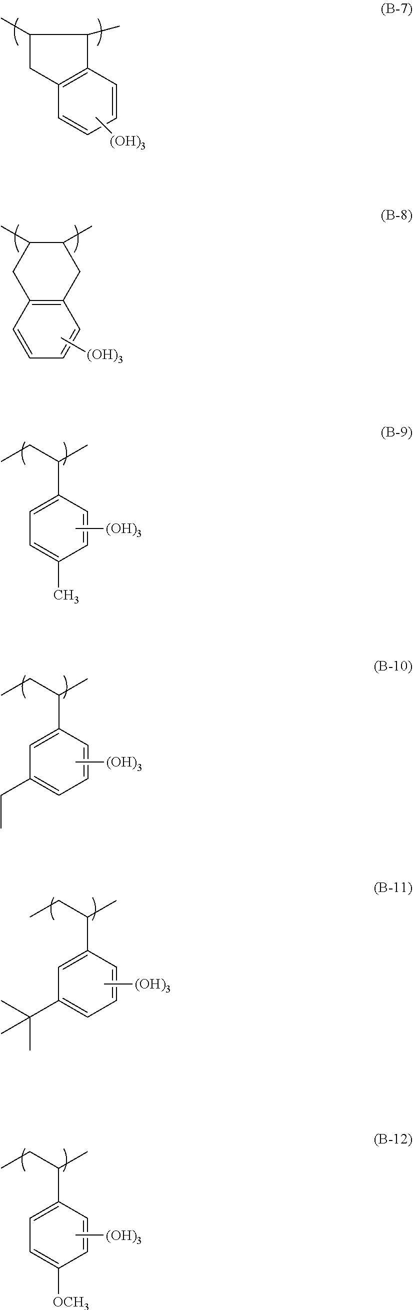

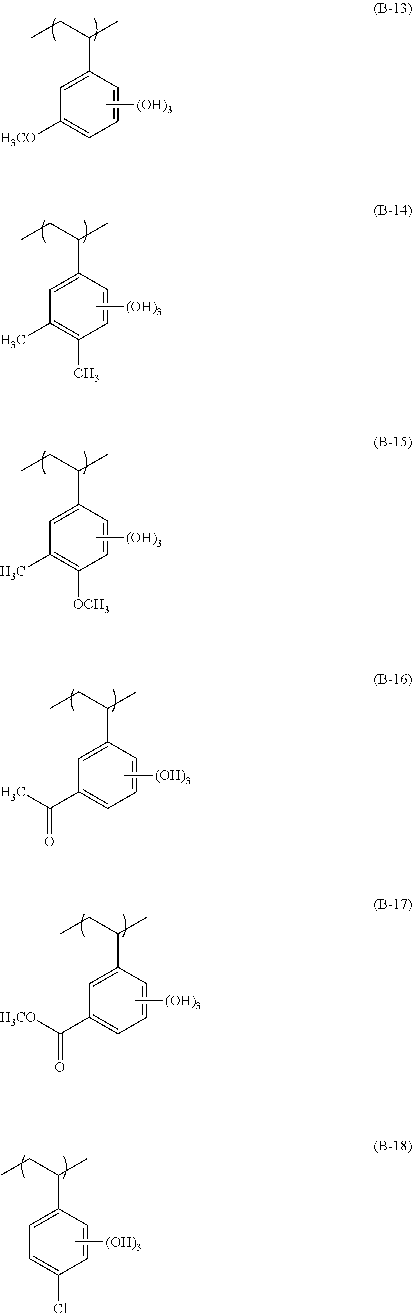

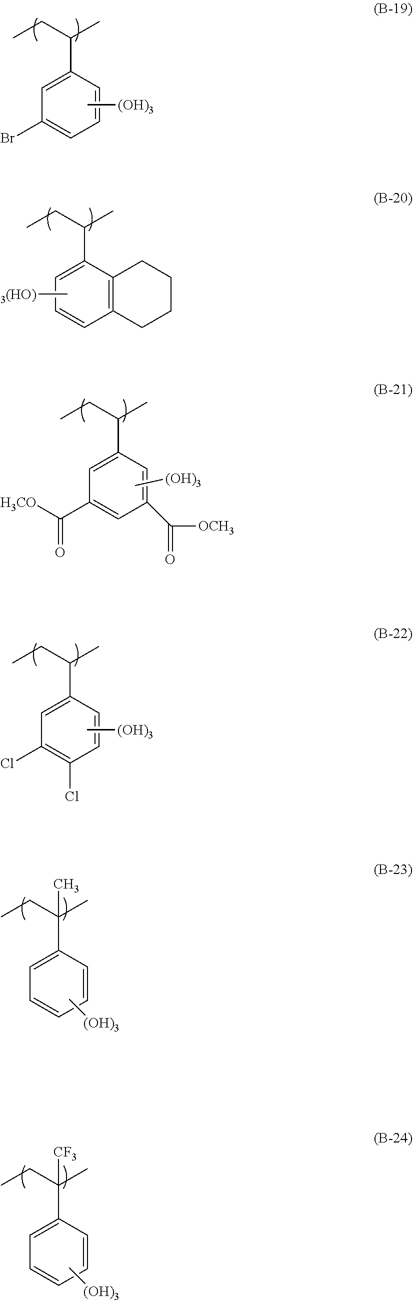

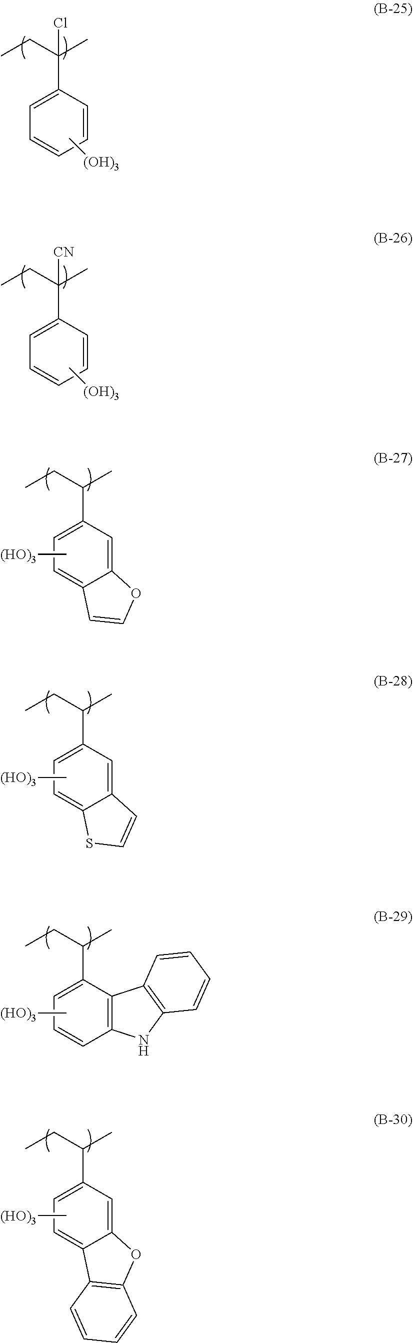

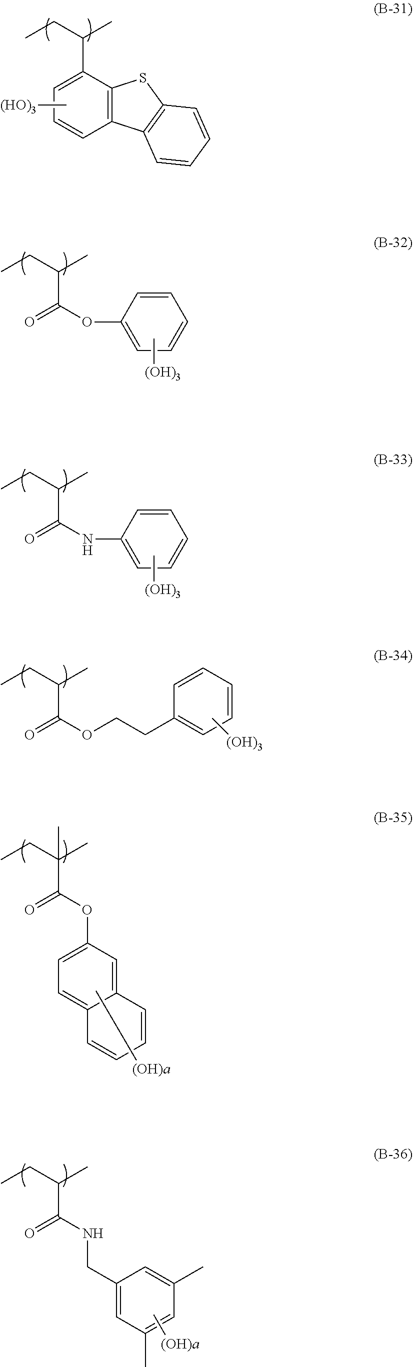

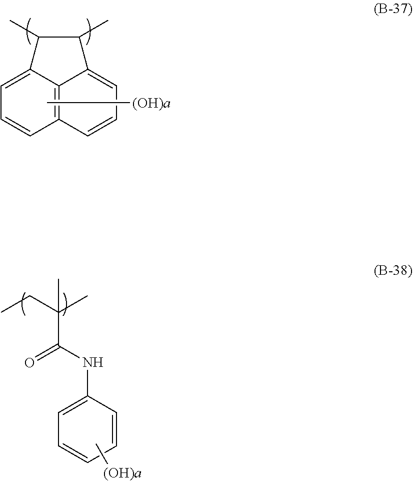

(Repeating Unit Derived from Hydroxystyrene (A-1))

The resin (A) preferably has a repeating unit (A-1) derived from hydroxystyrene as the repeating unit having an acid group.

Examples of the repeating unit (A-1) derived from hydroxystyrene include a repeating unit represented by General Formula (1).

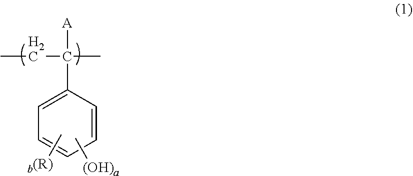

In General Formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, and in a case where a plurality of R's are present, R's may be the same as or different from each other. In a case where there are a plurality of R's, R's may be bonded to each other to form a ring. As R, the hydrogen atom is preferable.

a represents an integer of 1 to 3, and b represents an integer of 0 to (5-a).

As the repeating unit (A-1), a repeating unit represented by General Formula (A-I) is preferable.

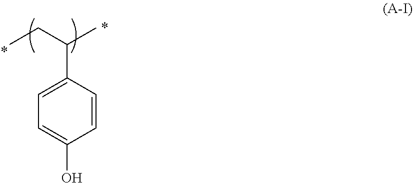

The composition including the resin (A) having the repeating unit (A-1) is preferable for KrF exposure, EB exposure, or EUV exposure. A content of the repeating unit (A-1) in such a case is preferably 30% to 100% by mole, more preferably 40% to 100% by mole, and still more preferably 50% to 100% by mole with respect to all repeating units in the resin (A).

(Repeating unit (A-2) Having at Least One selected from Group Consisting of Lactone Structure, Sultone Structure, Carbonate Structure, and Hydroxyadamantane Structure)

The resin (A) may have a repeating unit (A-2) having at least one selected from the group consisting of a lactone structure, a carbonate structure, a sultone structure, and a hydroxyadamantane structure.

The lactone structure or the sultone structure in a repeating unit having the lactone structure or the sultone structure is not particularly limited, but is preferably a 5- to 7-membered ring lactone structure or a 5- to 7-membered ring sultone structure, and more preferably a 5- to 7-membered ring lactone structure to which another ring structure is fused to form a bicyclo structure or a spiro structure, or a 5- to 7-membered ring sultone structure to which another ring structure is fused so as to form a bicyclo structure or a Spiro structure.

Examples of the repeating unit having the lactone structure or the sultone structure include the repeating units described in paragraphs 0094 to 0107 of WO2016/136354A.

The resin (A) may have a repeating unit having a carbonate structure. The carbonate structure is preferably a cyclic carbonic acid ester structure.

Examples of the repeating unit having a carbonate structure include the repeating unit described in paragraphs 0106 to 0108 of WO2019/054311A.

The resin (A) may have a repeating unit having a hydroxyadamantane structure.

Examples of the repeating unit having a hydroxyadamantane structure include a repeating unit represented by General Formula (AIIa).

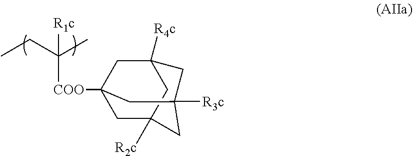

In General Formula (AIIa), R₁c represents a hydrogen atom, a methyl group, a trifluoromethyl group, or a hydroxymethyl group. R₂c to R₄c each independently represent a hydrogen atom or a hydroxyl group. It should be noted that at least one of R₂c, or R₄c represents a hydroxyl group. It is preferable that one or two of R₂c to R₄c are hydroxyl groups, and the rest are hydrogen atoms.

(Repeating Unit Having Fluorine Atom or Iodine Atom)

The resin (A) may have a repeating unit having a fluorine atom or an iodine atom.

Examples of the repeating unit having a fluorine atom or an iodine atom include the repeating units described in paragraphs 0080 and 0081 of JP2019-045864A.

(Repeating Unit Having Photoacid Generating Group)

The resin (A) may have, as a repeating unit other than those above, a repeating unit having a group that generates an acid upon irradiation with radiation.

Examples of such the repeating unit include a repeating unit represented by Formula (4).

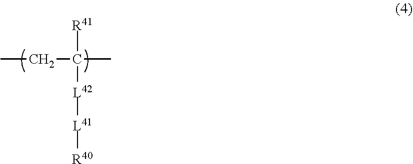

R⁴¹ represents a hydrogen atom or a methyl group. L⁴¹ represents a single bond or a divalent linking group. L⁴² represents a divalent linking group. R⁴⁰ represents a structural moiety that decomposes upon irradiation with actinic rays or radiation to generate an acid in a side chain.

The repeating unit having a photoacid generating group is exemplified below.

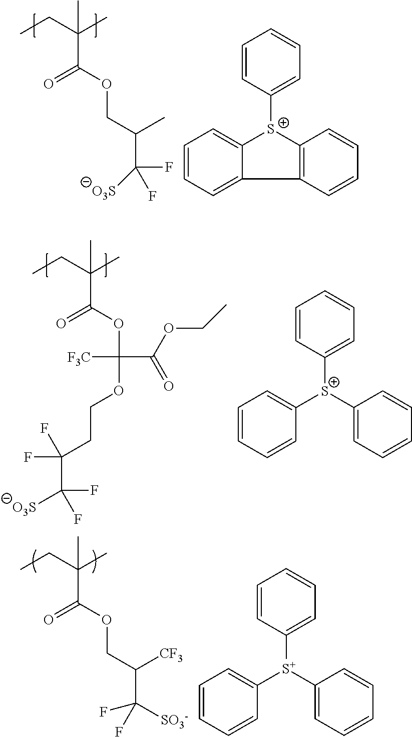

In addition, examples of the repeating unit represented by Formula (4) include the repeating units described in paragraphs [0094] to [0105] of JP2014-041327A and the repeating units described in paragraph [0094] of WO2018/193954A.

The content of the repeating unit having a photoacid generating group is preferably 1% by mole or more, and more preferably 2% by mole or more with respect to all repeating units in the acid-decomposable resin. In addition, an upper limit value thereof is preferably 20% by mole or less, more preferably 10% by mole or less, and still more preferably 5% by mole or less.

Examples of the repeating unit having a photoacid generating group also include the repeating units described in paragraphs 0092 to 0096 of JP2019-045864A.

(Repeating Unit Having Alkali-Soluble Group)

The resin (A) may have a repeating unit having an alkali-soluble group.

Examples of the alkali-soluble group include a carboxyl group, a sulfonamide group, a sulfonylimide group, a bissulfonylimide group, and an aliphatic alcohol (for example, a hexafluoroisopropanol group) in which the a-position is substituted with an electron-withdrawing group, and the carboxyl group is preferable. By allowing the resin (A) to have a repeating unit having an alkali-soluble group, the resolution for use in contact holes increases.

Examples of the repeating unit having an alkali-soluble group include a repeating unit in which an alkali-soluble group is directly bonded to the main chain of a resin such as a repeating unit with acrylic acid and methacrylic acid, or a repeating unit in which an alkali-soluble group is bonded to the main chain of the resin through a linking group. Furthermore, the linking group may have a monocyclic or polycyclic cyclic hydrocarbon structure.

The repeating unit having an alkali-soluble group is preferably a repeating unit with acrylic acid or methacrylic acid.

(Repeating Unit Having Neither Acid-Decomposable Group Nor Polar Group)

The resin (A) may further have a repeating unit having neither an acid-decomposable group nor a polar group. The repeating unit having neither an acid-decomposable group nor a polar group preferably has an alicyclic hydrocarbon.

Examples of the repeating unit having neither an acid-decomposable group nor a polar group include the repeating units described in paragraphs 0236 and 0237 of the specification of US2016/0026083A and the repeating units described in paragraph 0433 of the specification of US2016/0070167A.

The resin (A) may have a variety of repeating structural units, in addition to the repeating structural units described above, for the purpose of adjusting dry etching resistance, suitability for a standard developer, adhesiveness to a substrate, a resist profile, resolving power, heat resistance, sensitivity, and the like.

(Characteristics of Resin (A))

In the resin (A), all repeating units are preferably composed of repeating units derived from a compound having an ethylenically unsaturated bond. In particular, in the resin (A), all repeating units are preferably composed of repeating units derived from a (meth)acrylate-based monomer (monomer having a (meth)acryloyl group). In this case, any of a resin in which all repeating units are derived from a methacrylate-based monomer, a resin in which all repeating units are derived from an acrylate-based monomer, and a resin in which all repeating units are derived from a methacrylate-based monomer and an acrylate-based monomer may be used. The repeating units derived from the acrylate-based monomer are preferably 50% by mole or less with respect to all repeating units in the resin (A).

In a case where the composition is for argon fluoride (ArF) exposure, it is preferable that the resin (A) does not substantially have an aromatic group from the viewpoint of the transmittance of ArF light. More specifically, the repeating unit having an aromatic group is preferably 5% by mole or less, more preferably 3% by mole or less, and ideally 0% by mole with respect to all repeating units in the resin (A), that is, it is still more preferable that the repeating unit having an aromatic group is not included.

In addition, in a case where the composition is for ArF exposure, the resin (A) preferably has a monocyclic or polycyclic alicyclic hydrocarbon structure, and preferably does not include either a fluorine atom or a silicon atom.

In a case where the composition is for krypton difluoride (KrF) exposure, EB exposure, or EUV exposure, the resin (A) preferably has a repeating unit having an aromatic hydrocarbon group, and more preferably has a repeating unit having a phenolic hydroxyl group.

Examples of the repeating unit having a phenolic hydroxyl group include a repeating unit derived from hydroxystyrene (A-1) and a repeating unit derived from hydroxystyrene (meth)acrylate.

In addition, in a case where the composition is for KrF exposure, EB exposure, or EUV exposure, it is also preferable that the resin (A) has a repeating unit having a structure in which a hydrogen atom of the phenolic hydroxyl group is protected by a group (leaving group) that leaves through decomposition by the action of an acid.

In a case where the composition is for KrF exposure, EB exposure, or EUV exposure, a content of the repeating unit having an aromatic hydrocarbon group included in the resin (A) is preferably 30% to 100% by mole, more preferably 40% to 100% by mole, and still more preferably 50% to 100% by mole, with respect to all repeating units in the resin (A).

The resin (A) can be synthesized in accordance with an ordinary method (for example, radical polymerization).

The weight-average molecular weight (Mw) of the resin (A) is preferably 1,000 to 200,000, more preferably 3,000 to 20,000, and still more preferably 5,000 to 15,000. By setting the weight-average molecular weight (Mw) of the resin (A) to 1,000 to 200,000, it is possible to prevent deterioration of heat resistance and dry etching resistance, and it is also possible to prevent deterioration of the film forming property due to deterioration of developability and an increase in the viscosity. Incidentally, the weight-average molecular weight (Mw) of the resin (A) is a value expressed in terms of polystyrene as measured by the above-mentioned GPC method.

The dispersity (molecular weight distribution) of the resin (A) is usually 1 to 5, preferably 1 to 3, and more preferably 1.1 to 2.0. The smaller the dispersity, the better the resolution and the resist shape, and the smoother the side wall of a pattern, the more excellent the roughness.

In the composition of the present invention, a content of the resin (A) is preferably 50% to 99.9% by mass, and more preferably 60% to 99.0% by mass with respect to the total solid content of the composition.

In addition, the resin (A) may be used alone or in combination of two or more kinds thereof.

Furthermore, in the present specification, the solid content means a component that can form a resist film excluding the solvent. Even in a case where the properties of the components are liquid, they are treated as solid contents.

<Photoacid Generator (P)>

The composition of the present invention may include a photoacid generator (P). The photoacid generator (P) is not particularly limited as long as it is a compound that generates an acid upon irradiation with radiation.

The photoacid generator (P) may be in a form of a low-molecular-weight compound or a form incorporated into a part of a polymer. Furthermore, a combination of the form of a low-molecular-weight compound and the form incorporated into a part of a polymer may also be used.

In a case where the photoacid generator (P) is in the form of the low-molecular-weight compound, the weight-average molecular weight (Mw) is preferably 3,000 or less, more preferably 2,000 or less, and still more preferably 1,000 or less.

In a case where the photoacid generator (P) is in the form incorporated into a part of a polymer, it may be incorporated into the part of the resin (A) or into a resin that is different from the resin (A).

In the present invention, the photoacid generator (P) is preferably in the form of a low-molecular-weight compound.

The photoacid generator (P) is not particularly limited as long as it is a known one, but a compound that generates an organic acid upon irradiation with radiation is preferable, and a photoacid generator having a fluorine atom or an iodine atom in the molecule is more preferable.

Examples of the organic acid include sulfonic acids (an aliphatic sulfonic acid, an aromatic sulfonic acid, and a camphor sulfonic acid), carboxylic acids (an aliphatic carboxylic acid, an aromatic carboxylic acid, and an aralkylcarboxylic acid), a carbonylsulfonylimide acid, a bis(alkylsulfonyl)imide acid, and a tris(alkylsulfonyl)methide acid.

The volume of an acid generated from the photoacid generator (P) is not particularly limited, but from the viewpoint of suppression of diffusion of an acid generated to the unexposed area upon exposure and improvement of the resolution, the volume is preferably 240 Å³ or more, more preferably 305 Å³ or more, and still more preferably 350 Å³ or more, and particularly preferably 400 Å³ or more. Incidentally, from the viewpoint of the sensitivity or the solubility in an application solvent, the volume of the acid generated from the photoacid generator (P) is preferably 1,500 Å³ or less, more preferably 1,000 Å³ or less, and still more preferably 700 Å³ or less.

The value of the volume is obtained using “WinMOPAC” manufactured by Fujitsu Limited. For the computation of the value of the volume, first, the chemical structure of the acid according to each example is input, next, using this structure as the initial structure, the most stable conformation of each acid is determined by molecular force field computation using a Molecular Mechanics (MM) 3 method, and thereafter, with respect to the most stable conformation, molecular orbital computation using a parameterized model number (PM) 3 method is performed, whereby the “accessible volume” of each acid can be computed.

The structure of an acid generated from the photoacid generator (P) is not particularly limited, but from the viewpoint that the diffusion of the acid is suppressed and the resolution is improved, it is preferable that the interaction between the acid generated from the photoacid generator (P) and the resin (A) is strong. From this viewpoint, in a case where the acid generated from the photoacid generator (P) is an organic acid, it is preferable that a polar group is further contained, in addition to an organic acid group such as a sulfonic acid group, a carboxylic acid group, a carbonylsulfonylimide acid group, a bissulfonylimide acid group, and a trissulfonylmethide acid group.

Examples of the polar group include an ether group, an ester group, an amide group, an acyl group, a sulfo group, a sulfonyloxy group, a sulfonamide group, a thioether group, a thioester group, a urea group, a carbonate group, a carbamate group, a hydroxyl group, and a mercapto group.

The number of the polar groups contained in the acid generated is not particularly limited, and is preferably 1 or more, and more preferably 2 or more. It should be noted that from the viewpoint that excessive development is suppressed, the number of the polar groups is preferably less than 6, and more preferably less than 4.

Among those, the photoacid generator (P) is preferably a photoacid generator consisting of an anionic moiety and a cationic moiety from the viewpoint that the effect of the present invention is more excellent.

Examples of the photoacid generator (P) include the photoacid generators described in paragraphs 0144 to 0173 of JP2019-045864A.

The content of the photoacid generator (P) is not particularly limited, but from the viewpoint that the effect of the present invention is more excellent, the content is preferably 5% to 50% by mass, more preferably 10% to 40% by mass, and still more preferably 10% to 35% by mass with respect to the total solid content of the composition.

The photoacid generators (P) may be used alone or in combination of two or more kinds thereof. In a case where two or more kinds of the photoacid generators (P) are used in combination, the total amount thereof is preferably within the range.

The composition of the present invention may include the specific photoacid generator defined by the compounds (I) and (II) as the photoacid generator (P).

(Compound (I))

The compound (I) is a compound having one or more of the following structural moieties X and one or more of the following structural moieties Y, in which the compound generates an acid including the following first acidic moiety derived from the following structural moiety X and the following second acidic moiety derived from the following structural moiety Y upon irradiation with actinic rays or radiation.

Structural moiety X: A structural moiety which consists of an anionic moiety A₁⁻ and a cationic moiety M₁⁺, and forms a first acidic moiety represented by HA₁ upon irradiation with actinic rays or radiation

Structural moiety Y: A structural moiety which consists of an anionic moiety A₂⁻ and a cationic moiety M₂⁺, and forms a second acidic moiety represented by HA₂ upon irradiation with actinic rays or radiation

It should be noted that the compound (I) satisfies the following condition I.

Condition I: a compound PI formed by substituting the cationic moiety M₁⁺ in the structural moiety X and the cationic moiety M₂⁺ in the structural moiety Y with H⁺ in the compound (I) has an acid dissociation constant a1 derived from an acidic moiety represented by HA₁, formed by substituting the cationic moiety M₁⁺ in the structural moiety X with H⁺, and an acid dissociation constant a2 derived from an acidic moiety represented by HA2, formed by substituting the cationic moiety M₂⁺ in the structural moiety Y with H⁺, and the acid dissociation constant a2 is larger than the acid dissociation constant a1.

Hereinafter, the condition I will be described more specifically.

In a case where the compound (I) is, for example, a compound that generates an acid having one of the first acidic moieties derived from the structural moiety X and one of the second acidic moieties derived from the structural moiety Y, the compound PI corresponds to a “compound having HA₁ and HA₂”.

More specifically, with regard to the acid dissociation constant a1 and the acid dissociation constant a2 of such a compound PI, in a case where the acid dissociation constant of the compound PI is determined, the pKa with which the compound PI serves as a “compound having A₁⁻ and HA₂” is the acid dissociation constant a1, and the pKa with which “compound having A₁⁻ and HA₂” serves as a “compound having A₁⁻ and A₂⁻” is the acid dissociation constant a2.

In addition, in a case where the compound (I) is, for example, a compound that generates an acid having two of the first acidic moieties derived from the structural moiety X and one of the second acidic moieties derived from the structural moiety Y, the compound PI corresponds to a “compound having two HA₁'s and one HA₂”.

In a case where the acid dissociation constant of such a compound PI is determined, an acid dissociation constant in a case where the compound PI serves as a “compound having one A₁⁻, one HA₁, and one HA₂” and an acid dissociation constant in a case where the “compound having one A₁⁻, one HA₁, and one HA₂” serves as a “compound having two A₁⁻'s and one HA₂” correspond to the acid dissociation constant al. In addition, the acid dissociation constant in a case where the “compound having two A₁⁻ and one HA₂” serves as a “compound having two A₁⁻ and A₂⁻” corresponds to the acid dissociation constant a2. That is, in a case where such as compound PI has a plurality of acid dissociation constants derived from the acidic moiety represented by HA₁, formed by substituting the cationic moiety M₁⁺ in the structural moiety X with H⁺, the value of the acid dissociation constant a2 is larger than the largest value among the plurality of acid dissociation constants a1. Furthermore, the acid dissociation constant in a case where the compound PI serves as a “compound having one A₁⁻, one HA₁ and one HA₂” is aa and the acid dissociation constant in a case where the compound PI serves as a “compound having one A₁⁻, one HA₁, and one HA₂” is ab, a relationship between aa and ab satisfies aa<ab.

The acid dissociation constant a1 and the acid dissociation constant a2 can be determined by the above-mentioned method for measuring an acid dissociation constant.

The compound PI corresponds to an acid generated upon irradiating the compound (I) with actinic rays or radiation.

In a case where compound (I) has two or more structural moieties X, the structural moieties X may be the same as or different from each other. In addition, two or more A₁⁻'s and two or more M₁⁺'s may be the same as or different from each other.

Moreover, in the compound (I), A₁⁻'s and A₂⁻', and M₁⁺'s and M₂⁺'s may be the same as or different from each other, but it is preferable that A₁⁻'s and A₂⁻', are each different from each other.

From the viewpoint that the LWR performance of a pattern formed is more excellent, in the compound PI, the difference between the acid dissociation constant a1 (the maximum value in a case where a plurality of acid dissociation constants a1 are present) and the acid dissociation constant a2 is preferably 0.1 or more, more preferably 0.5 or more, and still more preferably 1.0 or more. Furthermore, the upper limit value of the difference between the acid dissociation constant a1 (the maximum value in a case where a plurality of acid dissociation constants a1 are present) and the acid dissociation constant a2 is not particularly limited, but is, for example, 16 or less.

In addition, from the viewpoint that the LWR performance of a pattern formed is more excellent, in the compound PI, the acid dissociation constant a2 is, for example, 20 or less, and preferably 15 or less. Furthermore, a lower limit value of the acid dissociation constant a2 is preferably −4.0 or more.

In addition, from the viewpoint that the LWR performance of a pattern formed is more excellent, the acid dissociation constant a1 is preferably 2.0 or less, and more preferably 0 or less in the compound PI. Furthermore, a lower limit value of the acid dissociation constant a1 is preferably −20.0 or more.

The anionic moiety A₁⁻ and the anionic moiety A₂⁻ are structural moieties including negatively charged atoms or atomic groups, and examples thereof include structural moieties selected from the group consisting of Formulae (AA-1) to (AA-3) and Formulae (BB-1) to (BB-6) shown below. As the anionic moiety A₁⁻, those capable of forming an acidic moiety having a small acid dissociation constant are preferable, and among those, any of Formulae (AA-1) to (AA-3) is preferable. In addition, as the anionic moiety A₂⁻, those capable of forming an acidic moiety having a larger acid dissociation constant than the anionic moiety A₁⁻ are preferable, and those selected from any of Formulae (BB-1) to (BB-6) are more preferable. Furthermore, in Formulae (AA-1) to (AA-3) and Formulae (BB-1) to (BB-6), * represents a bonding position.

In Formula (AA-2), R^{A} represents a monovalent organic group. Examples of the monovalent organic group represented by R^{A} include a cyano group, a trifluoromethyl group, and a methanesulfonyl group.

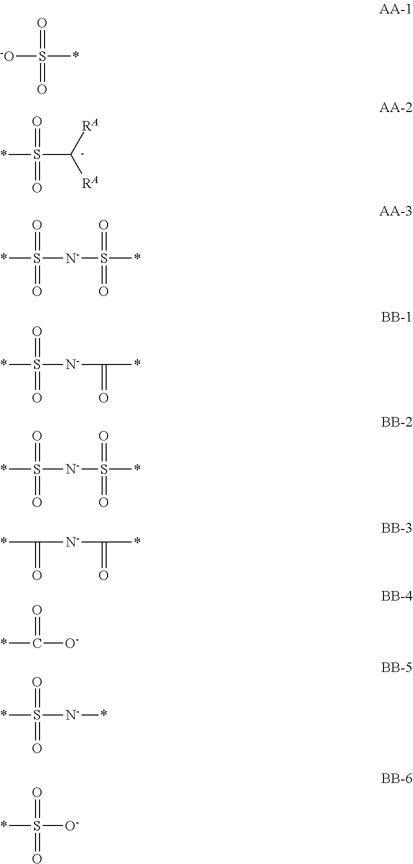

In addition, the cationic moiety M₁⁺ and the cationic moiety M₂⁺ are structural moieties including positively charged atoms or atomic groups, and examples thereof include a monovalent organic cation. Furthermore, the organic cation is not particularly limited, and examples thereof include the same ones as the organic cations represented by M₁₁⁺ and M₁₂⁺ in Formula (Ia-1) which will be described later.

The specific structure of the compound (I) is not particularly limited, and examples thereof include compounds represented by Formulae (Ia-1) to (Ia-5) which will be described later.

In the following, first, the compound represented by Formula (Ia-1) will be described. The compound represented by Formula (Ia-1) is as follows.

M₁₁⁺A₁₁⁻-L₁-A₁₂⁻M₁₂⁺ (Ia-1)

The compound (Ia-1) generates an acid represented by HA₁₁-L₁-A₁₂H upon irradiation with actinic rays or radiation.

In Formula (Ia-1), M₁₁⁺ and M₁₂⁺ each independently represent an organic cation.

A₁₁⁻ and A₁₂⁻ each independently represent a monovalent anionic functional group.

L₁ represents a divalent linking group.

M₁₁⁺ and M₁₂⁺ may be the same as or different from each other.

A₁₁⁻ and A₁₂⁻ may be the same as or different from each other, but are preferably different from each other.

It should be noted that in the compound PIa (HA₁₁-L₁-A₁₂H) formed by substituting the organic cations represented by M₁₁⁺ and M₁₂⁺ with H⁺ in Formula (Ia-1), the acid dissociation constant a2 derived from the acidic moiety represented by A₁₂H is larger than the acid dissociation constant a1 derived from the acidic moiety represented by HA₁₁. Furthermore, suitable values of the acid dissociation constant a1 and the acid dissociation constant a2 are as described above. In addition, the acids generated from the compound PIa and the compound represented by Formula (Ia-1) upon irradiation with actinic rays or radiation are the same.

In addition, at least one of M₁₁⁺, M₁₂⁺, A₁₁⁻, A₁₂⁻, or L₁ may have an acid-decomposable group as a substituent.

The organic cations represented by M₁⁺ and M₂⁺ in Formula (Ia-1) are as described later.

The monovalent anionic functional group represented by A₁₁⁻ is intended to be a monovalent group including the above-mentioned anionic moiety A₁⁻. In addition, the monovalent anionic functional group represented by A₁₂⁻ is intended to be a monovalent group including the above-mentioned anionic moiety A₂⁻.

The monovalent anionic functional group represented by each of A₁₁⁻ and A₁₂⁻ is preferably a monovalent anionic functional group including any of the anionic moieties of Formulae (AA-1) to (AA-3) and Formulae (BB-1) to (BB-6) mentioned above, and more preferably a monovalent anionic functional group selected from the group consisting of Formulae (AX-1) to (AX-3), and Formulae (BX-1) to (BX-7). The monovalent anionic functional group represented by A₁₁⁻ is preferably, among those, the monovalent anionic functional group represented by any of Formulae (AX-1) to (AX-3). In addition, the monovalent anionic functional group represented by A₁₂ is preferably, among those, the monovalent anionic functional group represented by any of Formulae (BX-1) to (BX-7), and more preferably the monovalent anionic functional group represented by any of Formulae (BX-1) to (BX-6).

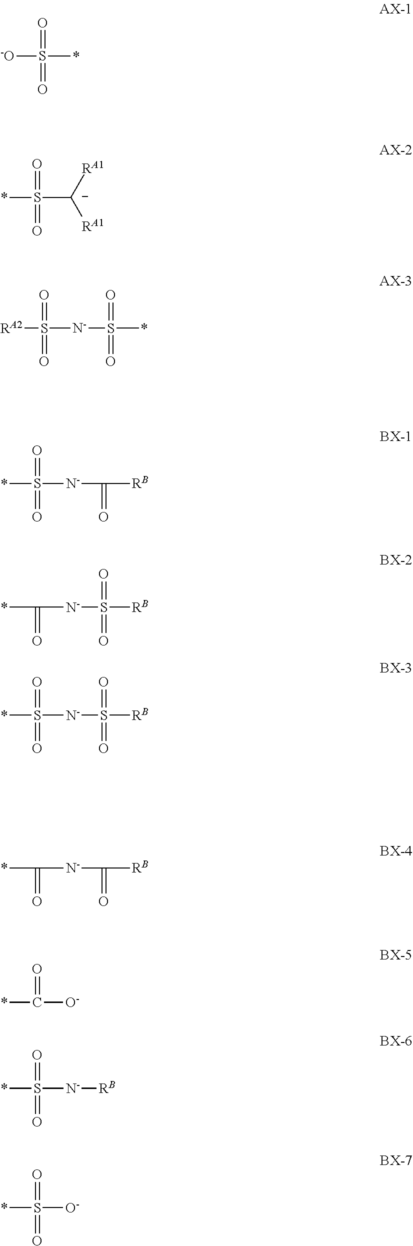

In Formulae (AX-1) to (AX-3), R^{A1} and R^{A2} each independently represent a monovalent organic group. * represents a bonding position.

Examples of the monovalent organic group represented by R^{A1} include a cyano group, a trifluoromethyl group, and a methanesulfonyl group.

As the monovalent organic group represented by R^{A2}, a linear, branched, or cyclic alkyl group or aryl group is preferable.

The number of carbon atoms of the alkyl group is preferably 1 to 15, more preferably 1 to 10, and still more preferably 1 to 6.

The alkyl group may have a substituent. As the substituent, a fluorine atom or a cyano group is preferable, and the fluorine atom is more preferable. In a case where the alkyl group has the fluorine atom as the substituent, it may be a perfluoroalkyl group.

As the aryl group, a phenyl group or a naphthyl group is preferable, and the phenyl group is more preferable.

The aryl group may have a substituent. As the substituent, a fluorine atom, an iodine atom, a perfluoroalkyl group (for example, preferably a perfluoroalkyl group having 1 to 10 carbon atoms, and more preferably a perfluoroalkyl group having 1 to 6 carbon atoms), or a cyano group is preferable, and the fluorine atom, the iodine atom, or the perfluoroalkyl group is more preferable.

In Formulae (BX-1) to (BX-4) and Formula (BX-6), R^{B} represents a monovalent organic group. * represents a bonding position.

As the monovalent organic group represented by R^{B}, a linear, branched, or cyclic alkyl group, or an aryl group is preferable.

The number of carbon atoms of the alkyl group is preferably 1 to 15, more preferably 1 to 10, and still more preferably 1 to 6.

The alkyl group may have a substituent. The substituent is not particularly limited, but as the substituent, a fluorine atom or a cyano group is preferable, and the fluorine atom is more preferable. In a case where the alkyl group has the fluorine atom as the substituent, it may be a perfluoroalkyl group.

Moreover, in a case where the carbon atom that serves as a bonding position in the alkyl group (for example, in a case of Formulae (BX-1) and (BX-4), the carbon atom corresponds to a carbon atom that directly bonds to —CO— specified in the formula in the alkyl group, and in a case of Formulae (BX-2) and (BX-3), the carbon atom corresponds to a carbon atom that directly bonded to —SO₂— specified in the formula in the alkyl group, and in a case of Formula (BX-6), the carbon atom corresponds to a carbon atom that directly bonded to N⁻ specified in the formula in the alkyl group) has a substituent, it is also preferable that the carbon atom has a substituent other than a fluorine atom or a cyano group.

In addition, the alkyl group may have a carbon atom substituted with a carbonyl carbon.

As the aryl group, a phenyl group or a naphthyl group is preferable, and the phenyl group is more preferable.

The aryl group may have a substituent. As the substituent, a fluorine atom, an iodine atom, a perfluoroalkyl group (for example, preferably a perfluoroalkyl group having 1 to 10 carbon atoms, and more preferably a perfluoroalkyl group having 1 to 6 carbon atoms), a cyano group, an alkyl group (for example, preferably an alkyl group having 1 to 10 carbon atoms, and more preferably an alkyl group having 1 to 6 carbon atoms), an alkoxy group (for example, preferably an alkoxy group having 1 to 10 carbon atoms, and more preferably an alkoxy group having 1 to 6 carbon atoms), or an alkoxycarbonyl group (for example, preferably an alkoxycarbonyl group having 2 to 10 carbon atoms, and more preferably an alkoxycarbonyl group having 2 to 6 carbon atoms) is preferable, and the fluorine atom, the iodine atom, the perfluoroalkyl group, the alkyl group, the alkoxy group, or the alkoxycarbonyl group is more preferable.

In Formula (Ia-1), the divalent linking group represented by L₁ is not particularly limited, and examples thereof include —CO—, —NR—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent linking group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may have a substituent. Examples of the substituent include a halogen atom (preferably a fluorine atom).

As the divalent linking group by L₁, the divalent linking group represented by Formula (L1) is preferable among those.

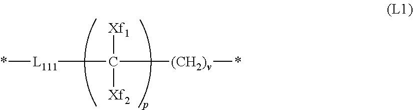

In Formula (L1), L₁₁₁ represents a single bond or a divalent linking group.

The divalent linking group represented by L₁₁₁ is not particularly limited, and examples thereof include —CO—, —NH—, —O—, —SO—, —SO₂—, an alkylene group (which more preferably has 1 to 6 carbon atoms, and may be linear or branched), which may have a substituent, a cycloalkylene group (preferably having 3 to 15 carbon atoms), which may have a substituent, an aryl group (preferably having 6 to 10 carbon atoms) which may have a substituent, and a divalent linking group formed by combination of these groups. The substituent is not particularly limited, and examples thereof include a halogen atom.

p represents an integer of 0 to 3, and preferably represents an integer of 1 to 3.

v represents an integer of 0 or 1.

Xf₁'s each independently represent a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf₂'s each independently represent a hydrogen atom, an alkyl group which may have a fluorine atom as a substituent, or a fluorine atom. The alkyl group preferably has 1 to 10 carbon atoms, and more preferably has 1 to 4 carbon atoms. Among those, Xf₂ preferably represents the fluorine atom or the alkyl group substituted with at least one fluorine atom, and is more preferably the fluorine atom or a perfluoroalkyl group.

Among those, Xf₁ and Xf₂ are each independently preferably the fluorine atom or a perfluoroalkyl group having 1 to 4 carbon atoms, and more preferably the fluorine atom or CF₃. In particular, it is still more preferable that both Xf₁ and Xf₂ are fluorine atoms.

* represents a bonding position.

In a case where L₁₁ in Formula (Ia-1) represents a divalent linking group represented by Formula (L1), it is preferable that a bonding site (*) on the L₁₁₁ side in Formula (L1) is bonded to A12⁻ in Formula (Ia-1).

In Formula (Ia-1), preferred modes of the organic cations represented by M₁₁⁺ and M₁₂⁺ will be described in detail.

The organic cations represented by M₁₁⁺ and M₁₂⁺ are each independently preferably an organic cation represented by Formula (ZaI) (cation (ZaI)) or an organic cation represented by Formula (ZaII) (cation (ZaII)).

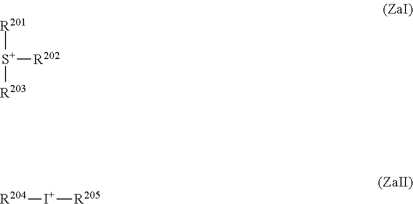

In Formula (ZaI),

R²⁰¹, R²⁰², and R²⁰³ each independently represent an organic group.

The organic group as each of R²⁰¹, R²⁰², and R²⁰³ usually has 1 to 30 carbon atoms, and preferably has 1 to 20 carbon atoms. In addition, two of R²⁰¹ to R²⁰³ may be bonded to each other to form a ring structure, and the ring may include an oxygen atom, a sulfur atom, an ester group, an amide group, or a carbonyl group. Examples of the group formed by the bonding of two of R²⁰¹ to R²⁰³ include an alkylene group (for example, a butylene group and a pentylene group), and —CH₂—CH₂—O—CH₂—CH₂—.

Suitable aspects of the organic cation in Formula (ZaI) include a cation (ZaI-1), a cation (ZaI-2), an organic cation represented by Formula (ZaI-3b) (cation (ZaI-3b)), and an organic cation represented by Formula (ZaI-4b) (cation (ZaI-4b)), each of which will be described later.

First, the cation (ZaI-1) will be described.

The cation (ZaI-1) is an arylsulfonium cation in which at least one of R²⁰¹, R²⁰², or R²⁰³ of Formula (ZaI) is an aryl group.

In the arylsulfonium cation, all of R²⁰¹ to R²⁰³ may be aryl groups, or some of R²⁰¹ to R²⁰³ may be an aryl group, and the rest may be an alkyl group or a cycloalkyl group.

In addition, one of R²⁰¹ to R²⁰³ may be an aryl group, two of R²⁰¹ to R²⁰³ may be bonded to each other to form a ring structure, and an oxygen atom, a sulfur atom, an ester group, an amide group, or a carbonyl group may be included in the ring. Examples of the group formed by the bonding of two of R²⁰¹ to R²⁰³ include an alkylene group (for example, a butylene group, a pentylene group, or —CH₂—CH₂—O13 CH₂—CH₂—) in which one or more methylene groups may be substituted with an oxygen atom, a sulfur atom, an ester group, an amide group, and/or a carbonyl group.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

As the aryl group included in the arylsulfonium cation, a phenyl group or a naphthyl group is preferable, and the phenyl group is more preferable. The aryl group may be an aryl group which has a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium cation has two or more awl groups, the two or more awl groups may be the same as or different from each other.

The alkyl group or the cycloalkyl group contained in the arylsulfonium cation as necessary is preferably a linear alkyl group having 1 to 15 carbon atoms, a branched alkyl group having 3 to 15 carbon atoms, or a cycloalkyl group having 3 to 15 carbon atoms, and for example, a methyl group, an ethyl group, a propyl group, an n-butyl group, a sec-butyl group, a t-butyl group, a cyclopropyl group, a cyclobutyl group, a cyclohexyl group, or the like is more preferable.

The substituents which may be contained in each of the aryl group, the alkyl group, and the cycloalkyl group of each of R²⁰¹ to R²⁰³ are each independently preferably an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom (for example, fluorine and iodine), a hydroxyl group, a carboxyl group, an ester group, a sulfinyl group, a sulfonyl group, an alkylthio group, a phenylthio group, or the like.

The substituent may further have a substituent as possible and is also preferably in the form of an alkyl halide group such as a trifluoromethyl group, for example, in which the alkyl group has a halogen atom as a substituent.

In addition, it is also preferable that the substituents form an acid-decomposable group by any combination.

Furthermore, the acid-decomposable group is intended to be a group that decomposes by the action of an acid to produce an acid group, and is preferably a structure in which an acid group is protected by a leaving group that leaves by the action of an acid. The acid group and the leaving group are as described above.

Next, the cation (ZaI-2) will be described.

The cation (ZaI-2) is a cation in which R²⁰¹ to R²⁰³ in Formula (ZaI) are each independently a cation representing an organic group having no aromatic ring. Here, the aromatic ring also encompasses an aromatic ring including a heteroatom.

The organic group having no aromatic ring as each of R²⁰¹ to R²⁰³ generally has 1 to 30 carbon atoms, and preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably the linear or branched 2-oxoalkyl group.

Examples of the alkyl group and the cycloalkyl group of each of R²⁰¹ to R²⁰³ include a linear alkyl group having 1 to 10 carbon atoms or branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

R²⁰¹ to R²⁰³ may further be substituted with a halogen atom, an alkoxy group (for example, having 1 to 5 carbon atoms), a hydroxyl group, a cyano group, or a nitro group.

In addition, it is also preferable that the substituents of R²⁰¹ to R²⁰³ each independently form an acid-decomposable group by any combination of the substituents.

Next, the cation (ZaI-3b) will be described.

The cation (ZaI-3b) is a cation represented by Formula (ZaI-3b).

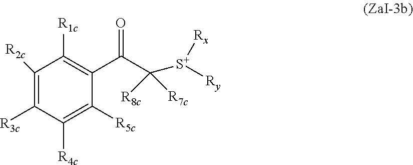

In Formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group (a t-butyl group or the like), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

In addition, it is also preferable that the substituents of R_{1c} to R_{7c}, and Rₓ, and R_{y} each independently form an acid-decomposable group by any combination of substituents.

Any two or more of R_{1c} to R_{5c}, R_{5c} and R_{6c}, R_{6c} and R_{7c}, R_{5c} and Rₓ, and Rₓ and R_{y} may each be bonded to each other to form a ring, and the ring may each independently include an oxygen atom, a sulfur atom, a ketone group, an ester bond, or an amide bond.

Examples of the ring include an aromatic or non-aromatic hydrocarbon ring, an aromatic or non-aromatic heterocyclic ring, and a polycyclic fused ring formed by combination of two or more of these rings. Examples of the ring include a 3- to 10-membered ring, and the ring is preferably a 4- to 8-membered ring, and more preferably a 5- or 6-membered ring.

Examples of the group formed by the bonding of any two or more of R_{1c}, or R_{5c}, R_{6c} and R_{7c}, and Rₓ and R_{y} include an alkylene group such as a butylene group and a pentylene group. The methylene group in this alkylene group may be substituted with a heteroatom such as an oxygen atom.

As the group formed by the bonding of R_{5c} and R_{6c}, and R_{5c} and Rₓ, a single bond or an alkylene group is preferable. Examples of the alkylene group include a methylene group and an ethylene group.

A ring formed by the mutual bonding of any two of R_{1c} to R_{5c}, R_{6c}, R_{7c}, Rₓ, R_{y}, and R_{1c} to R_{5c}, and a ring formed by the mutual bonding of each pair of R_{5c} and R_{6c}, R_{6c} and R_{7c}, R_{5c} and Rₓ, and Rₓ and R_{y} may have a substituent.

Next, the cation (ZaI-4b) will be described.

The cation (ZaI-4b) is a cation represented by Formula (ZaI-4b).

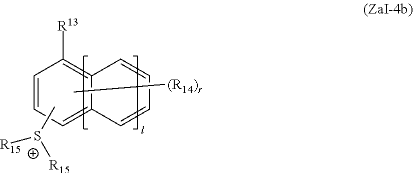

In Formula (ZaI-4b),

l represents an integer of 0 to 2.

r represents an integer of 0 to 8.

R₁₃ represents a hydrogen atom, a halogen atom (for example, a fluorine atom and an iodine atom), a hydroxyl group, an alkyl group, an alkyl halide group, an alkoxy group, a carboxyl group, an alkoxycarbonyl group, or a group having a cycloalkyl group (which may be the cycloalkyl group itself or a group including the cycloalkyl group in a part thereof). These groups may have a substituent.

R₁₄ represents a hydroxyl group, a halogen atom (for example, a fluorine atom and an iodine atom), an alkyl group, an alkyl halide group, an alkoxy group, an alkoxycarbonyl group, an alkylcarbonyl group, an alkylsulfonyl group, a cycloalkylsulfonyl group, or a group having a cycloalkyl group (which may be the cycloalkyl group itself or a group including the cycloalkyl group in a part thereof). These groups may have a substituent. In a case where R₁₄'s are present in a plural number, they each independently represent the group such as a hydroxyl group.

R₁₅'s each independently represent an alkyl group, a cycloalkyl group, or a naphthyl group. Two R₁₅'s may be bonded to each other to form a ring. In a case where two R₁₅'s are bonded to each other to form a ring, the ring skeleton may include a heteroatom such as an oxygen atom and a nitrogen atom. In one aspect, it is preferable that two R₁₅'s are alkylene groups and are bonded to each other to form a ring structure. Furthermore, the alkyl group, the cycloalkyl group, the naphthyl group, and the ring formed by the mutual bonding two R₁₅'s may have a substituent.

In Formula (ZaI-4b), the alkyl groups of each of R₁₃, R₁₄, and R₁₅ are linear or branched. The alkyl group preferably has 1 to 10 carbon atoms. The alkyl group is more preferably a methyl group, an ethyl group, an n-butyl group, a t-butyl group, or the like.

In addition, it is also preferable that the substituents of R₁₃ to R₁₅, and Rₓ and R_{y} each independently form an acid-decomposable group by any combination of substituents.

Next, Formula (ZaII) will be described.

In Formula (ZaII), R₂₀₄ and R₂₀₅ each independently represent an aryl group, an alkyl group, or a cycloalkyl group.

The aryl group of each of R²⁰⁴ and R²⁰⁵ is preferably a phenyl group or a naphthyl group, and more preferably the phenyl group. The aryl group of each of R²⁰⁴ and R²⁰⁵ may be an aryl group which has a heterocyclic ring having an oxygen atom, a nitrogen atom, a sulfur atom, or the like. Examples of the skeleton of the aryl group having a heterocyclic ring include pyrrole, furan, thiophene, indole, benzofuran, and benzothiophene.

The alkyl group and the cycloalkyl group of each of R²⁰⁴ and R²⁰⁵ is preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

The aryl group, the alkyl group, and the cycloalkyl group of each of R²⁰⁴ and R²⁰⁵ may each independently have a substituent. Examples of the substituent which may be contained in each of the aryl group, the alkyl group, and the cycloalkyl group of each of R²⁰⁴ and R²⁰⁵ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group. In addition, it is also preferable that the substituents of R²⁰⁴ and R²⁰⁵ each independently form an acid-decomposable group by any combination of the substituents.

Next, the compounds represented by Formulae (Ia-2) to (Ia-4) will be described.

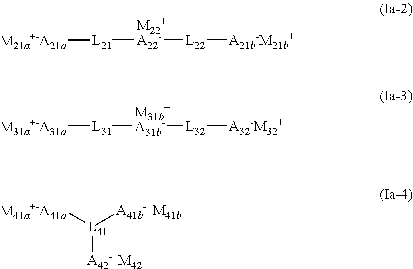

In Formula (Ia-2), A₂₁ₐ⁻ and A_{21b}⁻ each independently represent a monovalent anionic functional group. Here, the monovalent anionic functional group represented by each of A₂₁ₐ⁻ and A_{21b}⁻ is intended to be a monovalent group including the above-mentioned anionic moiety A₁⁻. The monovalent anionic functional group represented by each of A₂₁ₐ⁻ and A_{21b}⁻ is not particularly limited, but examples thereof include a monovalent anionic functional group selected from the group consisting of Formulae (AX-1) to (AX-3) mentioned above.

A₂₂⁻ represents a divalent anionic functional group. Here, the divalent anionic functional group represented by A₂₂⁻ is intended to be a divalent group including the above-mentioned anionic moiety A₂⁻. Examples of the divalent anionic functional group represented by A₂₂⁻ include divalent anionic functional groups represented by Formulae (BX-8) to (BX-11).

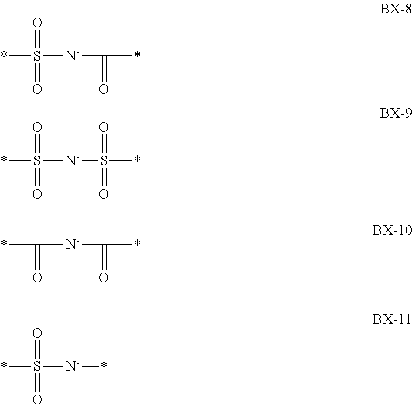 [SMILES: *C(=O)[N-]S(*)(=O)=O ; *S(=O)(=O)[N-]S(*)(=O)=O ; *C(=O)[N-]C(*)=O ; *[N-]S(*)(=O)=O]

M₂₁ₐ⁺, M_{21b}⁺, and M₂₂⁺ each independently represent an organic cation. The organic cations represented by M₂₁ₐ^{+, M}_{21b}⁺, and M₂₂⁺ each have the same definition as the above-mentioned M₁⁺, and suitable aspects thereof are also the same.

L₂₁ and L₂₂ each independently represent a divalent organic group.

In addition, in the compound PIa-2 formed by substituting an organic cation represented by M₂₁ₐ⁺, M_{21b}⁺, and M₂₂⁺ with H⁺ in Formula (Ia-2), the acid dissociation constant a2 derived from the acidic moiety represented by A₂₂H is larger than the acid dissociation constant a1-1 derived from the acidic moiety represented by A₂₁ₐH and the acid dissociation constant a1-2 derived from the acidic moiety represented by A_{21b}H. Incidentally, the acid dissociation constant a1-1 and the acid dissociation constant a1-2 correspond to the above-mentioned acid dissociation constant a1.

Furthermore, A₂₁ₐ⁻ and A_{21b}⁻ may be the same as or different from each other. In addition, M₂₁ₐ⁺, M_{21b}⁺, and M₂₂⁺ may be the same as or different from each other.

Moreover, at least one of M₂₁ₐ⁺, M_{21b}⁺, M₂₂⁺, A₂₁ₐ⁻, A_{21b}⁻, L₂₁, or L₂₂ may have an acid-decomposable group as a substituent.

In Formula (Ia-3), A₃₁ₐ⁻ and A₃₂⁻ each independently represent a monovalent anionic functional group. Furthermore, the monovalent anionic functional group represented by A₃₁ₐ⁻ has the same definition as A₂₁ₐ⁻ and A_{21b}⁻ in Formula (Ia-2) mentioned above, and a suitable aspect thereof is also the same.

The monovalent anionic functional group represented by A₃₂⁻ is intended to be a monovalent group including the above-mentioned anionic moiety A₂⁻. The monovalent anionic functional group represented by A₃₂⁻ is not particularly limited, but examples thereof include a monovalent anionic functional group selected from the group consisting of Formulae (BX-1) to (BX-7) mentioned above.

A_{31b}⁻ represents a divalent anionic functional group. Here, the divalent anionic functional group represented by A_{31b}⁻ is intended to be a divalent group containing the above-mentioned anionic moiety A₁⁻. Examples of the divalent anionic functional group represented by A_{31b}⁻ include a divalent anionic functional group represented by Formula (AX-4).

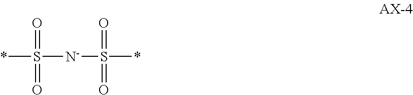 [SMILES: *S(=O)(=O)[N-]S(*)(=O)=O]

M₃₁ₐ⁺, M_{31b}⁺, and M₃₂⁺ each independently represent a monovalent organic cation. The organic cations of M₃₁ₐ⁺, M_{31b}⁺, and M₃₂⁺ have the same definitions as the above-mentioned M₁⁺, and suitable aspects thereof are also the same.

L₃₁ and L₃₂ each independently represent a divalent organic group.

In addition, in the compound PIa-3 formed by substituting an organic cation represented by M₃₁ₐ⁺, M_{31b}⁺, and M₃₂⁺ with H⁺ in Formula (Ia-3), the acid dissociation constant a2 derived from the acidic moiety represented by A₃₂H is larger than the acid dissociation constant a1-3 derived from the acidic moiety represented by A₃₁ₐH and the acid dissociation constant a1-4 derived from the acidic moiety represented by A_{31b}H. Incidentally, the acid dissociation constant a1-3 and the acid dissociation constant a1-4 correspond to the above-mentioned acid dissociation constant a1.

Furthermore, A₃₁ₐ⁻ and A₃₂⁻ may be the same as or different from each other. In addition, M₃₁ₐ⁺, M_{31b}⁺, and M₃₂⁺ may be the same as or different from each other.

Moreover, at least one of M₃₁ₐ⁺, M_{31b}⁺, M₃₂⁺, A₃₁ₐ⁻, A₃₂⁻, L₃₁, or L₃₂ may have an acid-decomposable group as a substituent.

In Formula (Ia-4), A₄₁ₐ⁻, A_{41b}⁻, and A₄₂⁻ each independently represent a monovalent anionic functional group. Furthermore, the monovalent anionic functional groups represented by A₄₁ₐ⁻ and A_{41b}⁻ have the same definitions as A₂₁ₐ⁻ and A_{21b}⁻ in Formula (Ia-2) mentioned above. In addition, the monovalent anionic functional group represented by A₄₂⁻ has the same definition as A₃₂⁻ in Formula (Ia-3) mentioned above, and a suitable aspect thereof is also the same.

M₄₁ₐ⁺, M_{41b}⁺, and M₄₂⁺ each independently represent an organic cation.

L₄₁ represents a trivalent organic group.

In addition, in the compound PIa-4 formed by substituting an organic cation represented by M₄₁ₐ⁺, M_{41b}⁺, and M₄₂⁺ with H⁺ in Formula (Ia-4), the acid dissociation constant a2 derived from the acidic moiety represented by A₄₂H is larger than the acid dissociation constant a1-5 derived from the acidic moiety represented by A₄₁ₐH and the acid dissociation constant a1-6 derived from the acidic moiety represented by A_{41b}H. Incidentally, the acid dissociation constant a1-5 and the acid dissociation constant a1-6 correspond to the above-mentioned acid dissociation constant a1.

Furthermore, A₄₁ₐ⁻, A_{41b}⁻, and A₄₂⁻ may be the same as or different from each other. In addition, M₄₁ₐ⁺, M_{41b}⁺, and M₄₂⁺ may be the same as or different from each other.

Moreover, at least one of M₄₁ₐ⁺, M_{41b}⁺, M₄₂⁺, A₄₁ₐ⁻, A_{41b}⁻, A₄₂⁻, or L₄₁ may have an acid-decomposable group as a substituent.

The divalent organic group represented by each of L₂₁ and L₂₂ in Formula (Ia-2) and L₃₁ and L₃₂ in Formula (Ia-3) is not particularly limited, but examples thereof include —CO—, —NR—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent organic group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may have a substituent. Examples of the substituent include a halogen atom (preferably a fluorine atom).

As the divalent organic group represented by each of L₂₁ and L₂₂ in Formula (Ia-2) and L₃₁ and L₃₂ in Formula (Ia-3), for example, a divalent organic group represented by Formula (L2) is preferable.

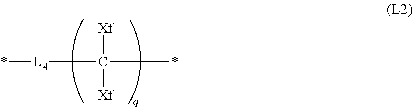

In Formula (L2), q represents an integer of 1 to 3. * represents a bonding position.

Xf's each independently represent a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf is preferably the fluorine atom or a perfluoroalkyl group having 1 to 4 carbon atoms, and more preferably the fluorine atom or CF₃. In particular, it is still more preferable that both Xf's are fluorine atoms.

L_{A} represents a single bond or a divalent linking group.

The divalent linking group represented by L_{A} is not particularly limited, and examples thereof include —CO—, —O—, —SO—, —SO₂—, an alkylene group (which preferably has 1 to 1 to 6 carbon atoms and may be linear or branched), a cycloalkylene group (preferably having 3 to 15 carbon atoms), a divalent aromatic hydrocarbon ring group (preferably having a 6 to 10-membered ring, and more preferably having a 6-membered ring), and a divalent linking group formed by combination of a plurality of these groups.

In addition, the alkylene group, the cycloalkylene group, and the divalent aromatic hydrocarbon ring group may have a substituent. Examples of the substituent include a halogen atom (preferably a fluorine atom).

Examples of the divalent organic group represented by Formula (L2) include *—CF₂—*, *—CF₂—CF₂—*, *—CF₂—CF₂—CF₂—*, *—Ph—O—SO₂—CF₂—*, *—Ph—O—SO₂—CF₂—CF₂—*, *—Ph—O—SO₂—CF₂—CF₂—CF₂—*, and d*-Ph—OCO—CF₂—*. In addition, Ph is a phenylene group which may have a substituent, and is preferably a 1,4-phenylene group. The substituent is not particularly limited, but is preferably an alkyl group (for example, preferably an alkyl group having 1 to 10 carbon atoms, and more preferably an alkyl group having 1 to 6 carbon atoms), an alkoxy group (for example, preferably an alkoxy group having 1 to 10 carbon atoms, and more preferably an alkoxy group having 1 to 6 carbon atoms), or an alkoxycarbonyl group (for example, preferably an alkoxycarbonyl group having 2 to 10 carbon atoms, and more preferably an alkoxycarbonyl group having 2 to 6 carbon atoms).

In a case where L₂₁ and L₂₂ in Formula (Ia-2) represent a divalent organic group represented by Formula (L2), it is preferable that a bonding site (*) on the L_{A} side in Formula (L2) is bonded to A₂₁ₐ⁻ and A_{21b}⁻ in Formula (Ia-2).

In addition, in a case where L₃₁ and L₃₂ in Formula (Ia-3) represent a divalent organic group represented by Formula (L2), it is preferable that a bonding site (*) on the LA side in Formula (L2) is bonded to A₃₁ₐ⁻ and A₃₂⁻ in Formula (Ia-3).

The trivalent organic group represented by L₄₁ in Formula (Ia-4) is not particularly limited, and examples thereof include a trivalent organic group represented by Formula (L3).

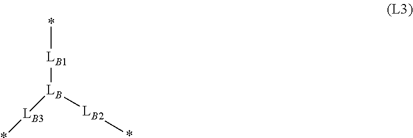

In Formula (L3), L_{B} represents a trivalent hydrocarbon ring group or a trivalent heterocyclic group. * represents a bonding position.

The hydrocarbon ring group may be an aromatic hydrocarbon ring group or an aliphatic hydrocarbon ring group. The number of carbon atoms included in the hydrocarbon ring group is preferably 6 to 18, and more preferably 6 to 14. The heterocyclic group may be either an aromatic heterocyclic group or an aliphatic heterocyclic group. The heterocyclic ring is preferably a 5- to 10-membered ring, more preferably a 5- to 7-membered ring, and still more preferably a 5- or 6-membered ring, each of which has at least one N atom, O atom, S atom, or Se atom in the ring structure.

As L_{B}, a trivalent hydrocarbon ring group is preferable, and a benzene ring group or an adamantane ring group is more preferable. The benzene ring group or the adamantane ring group may have a substituent. The substituent is not particularly limited, and examples thereof include a halogen atom (preferably a fluorine atom).

In addition, in Formula (L3), L_{B1} to L_{B3} each independently represent a single bond or a divalent linking group. The divalent linking group represented by each of L_{B1} to L_{B3} is not particularly limited, and examples thereof include —CO—, —NR—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent linking group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may have a substituent. Examples of the substituent include a halogen atom (preferably a fluorine atom).

As the divalent linking group represented by each of L_{B1} to L_{B3}, among those, —CO—, —NR—, —O—, —S—, —SO—, and —SO₂—, the alkylene group which may have a substituent, and the divalent linking group formed by combination of these groups are preferable.

As the divalent linking group represented by each of L_{B1} to L_{B3}, the divalent linking group represented by Formula (L3-1) is more preferable.

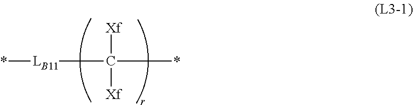

In Formula (L3-1), L_{B11} represents a single bond or a divalent linking group.

The divalent linking group represented by L_{B11} is not particularly limited, and examples thereof include —CO—, —O—, —SO—, —SO₂—, an alkylene group (which preferably has 1 to 6 carbon atoms, and may be linear or branched) which may have a substituent, and a divalent linking group formed by combination of a plurality of these groups. The substituent is not particularly limited, and examples thereof include a halogen atom.

r represents an integer of 1 to 3.

Xf has the same definition as Xf in Formula (L2) mentioned above, and a suitable aspect thereof is also the same.

* represents a bonding position.

Examples of the divalent linking groups represented by each of L_{B1} to L_{B3} include *—O—*, *—O—SO₂—CF₂—*, *—O—SO₂—CF₂—CF₂—*, *—O—SO₂—CF₂—CF₂—CF₂—*, and *—COO—CH₂—CH₂—*.

In a case where L₄₁ in Formula (Ia-4) includes a divalent organic group represented by Formula (L3-1), and the divalent organic group represented by Formula (L3-1) and A₄₂⁻ are bonded to each other, it is preferable that the bonding site (*) on the carbon atom side specified in Formula (L3-1) is bonded to A₄₂⁻ in Formula (Ia-4).

Next, a compound represented by Formula (Ia-5) will be described.

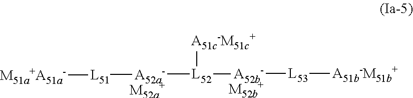

In Formula (Ia-5), A₅₁ₐ⁻, A_{51b}⁻, and A_{51c}⁻ each independently represent a monovalent anionic functional group. Here, the monovalent anionic functional group represented by each of A₅₁ₐ⁻, A_{51b}⁻, and A_{51c}⁻ is intended to be a monovalent group including the above-mentioned anionic moiety A₁⁻. The monovalent anionic functional group represented by each of A₅₁ₐ⁻, A_{51b}⁻, and A_{51c}⁻ is not particularly limited, but examples thereof include a monovalent anionic functional group selected from the group consisting of Formulae (AX-1) to (AX-3) mentioned above.

A₅₂ₐ⁻ and A_{52b}⁻ each represent a divalent anionic functional group. Here, the divalent anionic functional group represented by each of A₅₂ₐ⁻ and A_{52b}⁻ is intended to be a divalent group including the above-mentioned anionic moiety A₂⁻. Examples of the divalent anionic functional group represented by A₂₂⁻ include a divalent anionic functional group selected from the group consisting of Formulae (BX-8) to (BX-11) mentioned above.

M₅₁ₐ⁺, M_{51b}⁺, M_{51c}⁺, M₅₂ₐ⁺, and M_{52b}⁺ each independently represent an organic cation. The organic cation represented by each of M₅₁ₐ⁺, M_{51b}⁺, M_{51c}⁺, M₅₂ₐ⁺, and M_{52b}⁺ has the same definition as the above-mentioned M₁⁺, and a suitable aspect thereof is also the same.

L₅₁ and L₅₃ each independently represent a divalent organic group. The divalent organic group represented by each of L₅₁ and L₅₃ has the same definition as L₂₁ and L₂₂ in Formula (Ia-2) mentioned above, and suitable aspects thereof are also the same.

L₅₂ represents a trivalent organic group. The trivalent organic group represented by L₅₂ has the same definition as L₄₁ in Formula (Ia-4) mentioned above, and a suitable aspect thereof is also the same.

In addition, in the compound PIa-5 formed by substituting an organic cation represented by each of M₅₁ₐ⁺, M_{51b}⁺, M_{51c}⁺, M₅₂ₐ⁺, and M_{52b}⁺ with H⁺ in Formula (Ia-5), the acid dissociation constant a2-1 derived from the acidic moiety represented by A₅₂ₐH and the acid dissociation constant a2-2 derived from the acidic moiety represented by A_{52b}H are larger than the acid dissociation constant a1-1 derived from the acidic moiety represented by A₅₁ₐH, the acid dissociation constant a1-2 derived from the acidic moiety represented by A_{51b}H, and the acid dissociation constant a1-3 derived from the acidic moiety represented by A_{51c}H. Incidentally, the acid dissociation constants a1-1 to a1-3 correspond to the above-mentioned acid dissociation constant a1, and the acid dissociation constants a2-1 and a2-2 correspond to the above-mentioned acid dissociation constant a2.

Furthermore, A₅₁ₐ⁻, A_{51b}⁻, and A_{51c}⁻ may be the same as or different from each other. Moreover, A₅₂ₐ⁻ and A_{52b}⁻ may be the same as or different from each other. In addition, M₅₁ₐ⁺, M_{51b}⁺, M_{51c}⁺, M₅₂ₐ⁺, and M_{52b}⁺ may be the same as or different from each other.

Moreover, at least one of M_{51b}, M_{51c}⁺, M₅₂ₐ⁺, M_{52b}⁺, A₅₁ₐ⁻, A_{51b}⁻, A_{51c}⁻, L₅₁, L₅₂, or L₅₃ may have an acid-decomposable group as a substituent.

(Compound (II))

The compound (II) is an acid generating compound, including a compound having two or more of the structural moieties X and one or more of the following structural moieties Z, in which the compound generates an acid including the two or more first acidic moieties derived from the structural moieties X and the structural moiety Z upon irradiation with actinic rays or radiation.

Structural moiety Z: A nonionic moiety capable of neutralizing an acid

In the compound (II), the definition of the structural moiety X and the definitions of A₁⁻ and M₁⁺ are the same as the definition of the structural moiety X in the compound (I), and the definitions of and M₁⁺, each mentioned above, and suitable aspects thereof are also the same.

In the compound PII formed by substituting the cationic moiety M₁⁺ in the structural moiety X with H⁺ in the compound (II), a suitable range of the acid dissociation constant a1 derived from the acidic moiety represented by HA_{I}, formed by substituting the cationic moiety M₁⁺ in the structural moiety X with H⁺, is the same as the acid dissociation constant a1 in the compound PI.

Furthermore, in a case where the compound (II) is, for example, a compound that generates an acid having two of the first acidic moieties derived from the structural moiety X, and the structural moiety Z, the compound PII corresponds to a “compound having two HA₁'s”. In a case where the acid dissociation constant of the compound PII was determined, the acid dissociation constant in a case where the compound PII serves as a “compound having one A₁⁻ and one HA₁” and the acid dissociation constant in a case where the “compound having one A₁⁻ and one HA₁” serves as a “compound having two A₁⁻'s” correspond to the acid dissociation constant a1.

The acid dissociation constant a1 is determined by the above-mentioned method for measuring an acid dissociation constant.

The compound PII corresponds to an acid generated upon irradiating the compound (II) with actinic rays or radiation.

Furthermore, the two or more structural moieties X may be the same as or different from each other. In addition, two or more A₁⁻'s and two or more M₁⁺'s may be the same as or different from each other.

The nonionic moiety capable of neutralizing an acid in the structural moiety Z is not particularly limited, and is preferably, for example, a moiety including a functional group having a group or electron which is capable of electrostatically interacting with a proton.

Examples of the functional group having a group or electron capable of electrostatically interacting with a proton include a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by the following formula.

[symbol]

Unshared electron pair

Examples of the partial structure of the functional group having a group or electron capable of electrostatically interacting with a proton include a crown ether structure, an azacrown ether structure, primary to tertiary amine structures, a pyridine structure, an imidazole structure, and a pyrazine structure, and among these, the primary to tertiary amine structures are preferable.

The compound (II) is not particularly limited, and examples thereof include compounds represented by Formula (IIa-1) and Formula (IIa-2).

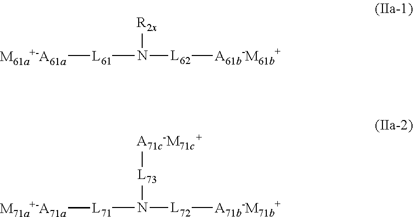

In Formula (IIa-1), A₆₁ₐ⁻ and A_{61b}⁻ each have the same definition as A₁₁⁻ in Formula (Ia-1) mentioned above, and suitable aspects thereof are also the same. In addition, M₆₁ₐ⁺ and M_{61b}⁺ each have the same definition as M₁₁⁺ in Formula (Ia-1) mentioned above, and suitable aspects thereof are also the same.

In Formula (IIa-1), L₆₁ and L₆₂ each have the same definition as L₁ in Formula (Ia-1) mentioned above, and suitable aspects thereof are also the same.

In Formula (IIa-1), R₂ₓ represents a monovalent organic group. The monovalent organic group represented by R₂ₓ is not particularly limited, and examples thereof include an alkyl group (which preferably has 1 to 10 carbon atoms, and may be linear or branched), a cycloalkyl group (preferably having 3 to 15 carbon atoms), and an alkenyl group (preferably having 2 to 6 carbon atoms), in which —CH₂— may be substituted with one or a combination of two or more selected from the group consisting of —CO—, —NH—, —O—, —S—, —SO—, and —SO₂—.

In addition, the alkylene group, the cycloalkylene group, and the alkenylene group may have a substituent. The substituent is not particularly limited, and examples thereof include a halogen atom (preferably a fluorine atom).

In addition, in the compound PIIa-1 formed by substituting an organic cation represented by M₆₁ₐ⁺ and M_{61b}⁺ with H⁺ in Formula (IIa-1), the acid dissociation constant a1-7 derived from the acidic moiety represented by A₆₁ₐH and the acid dissociation constant a1-8 derived from the acidic moiety represented by A_{61b}H correspond to the above-mentioned acid dissociation constant a1.

Furthermore, the compound PIIa-1 formed by substituting the cationic moieties M₆₁ₐ⁺ and M_{61b}⁺ in the structural moiety X with H⁺ in the compound (IIa-1) corresponds to HA₆₁ₐ-L₆₁-N(R_{2X})-L₆₂-A_{61b}H. In addition, the acids generated from the compound PIIa-1 and the compound represented by Formula (IIa-1) upon irradiation with actinic rays or radiation are the same.

Moreover, at least one of M₆₁ₐ⁺, M_{61b}⁺, A₆₁ₐ⁻, A_{61b}⁻, L₆₁, L₆₂, or R₂ₓ may have an acid-decomposable group as a substituent.

In Formula (IIa-2), A₇₁ₐ⁻, A_{71b}⁻, and A_{71c}⁻ each have the same definition as A₁₁⁻ in Formula (Ia-1) mentioned above, and suitable aspects thereof are also the same. In addition, M₇₁ₐ⁺, M_{71b}⁺, and M_{71c}⁺ each have the same definition as M₁₁⁺ in Formula (Ia-1) mentioned above, and suitable aspects thereof are the same.

In Formula (IIa-2), L₇₁, L₇₂, and L₇₃ each have the same definition as L₁ in Formula (Ia-1) mentioned above, and suitable aspects thereof are also the same.

In addition, in the compound PIIa-2 formed by substituting an organic cation represented by M₇₁ₐ⁺, M_{71b}⁺, and M_{71c}⁺ with H⁺ in Formula (IIa-2), the acid dissociation constant a1-9 derived from the acidic moiety represented by A₇₁ₐH, the acid dissociation constant a1-10 derived from the acidic moiety represented by A_{71b}H, and the acid dissociation constant a1-11 derived from the acidic moiety represented by A_{71c}H correspond to the above-mentioned acid dissociation constant a1.

Furthermore, the compound PIIa-2 formed by substituting the cationic moieties M₇₁ₐ⁺, M_{71b}⁺, and M_{71c}⁺ in the structural moiety X with H⁺ in the compound (IIa-1) with H⁺ corresponds to HA₇₁ₐ-L₇₁-N(L₇₃-A_{71c}H)-L₇₂-A_{71b}H. In addition, the acids generated from the compound PIIa-2 and the compound represented by Formula (IIa-2) upon irradiation with actinic rays or radiation are the same.

Moreover, at least one of M₇₁ₐ⁺, M_{71b}⁺, M_{71c}⁺, A₇₁ₐ⁻, A_{71b}⁻, L₇₁, L₇₂, or L₇₃ may have an acid-decomposable group as a substituent.

The organic cations and the other moieties, which can be contained in the specific photoacid generator, are exemplified below.

The organic cations can be used as, for example, M₁₁⁺, M₁₂⁺, M₂₁ₐ⁺, M_{21b}⁺, M₂₂⁺, M₃₁ₐ⁺, M_{31b}⁺, M₃₂⁺, M₄₁ₐ⁺, M_{41b}⁺, M₄₂⁺, M₅₁ₐ⁺, M_{51b}⁺, M_{51c}⁺, M₅₂ₐ⁺, or M_{52b}⁺ in the compounds represented by Formulae (Ia-1) to (Ia-5).

The other moieties can be used as, for example, moieties other than M₁₁⁺, M₁₂⁺, M₂₁ₐ⁺, M_{21b}⁺, M₂₂⁺, M₃₁ₐ⁺, M_{31b}⁺, M₃₂⁺, M₄₁ₐ⁺, M_{41b}⁺, M₄₂⁺, M₅₁ₐ⁺, M_{51b}⁺, M_{51c}⁺, M₅₂ₐ⁺, or M_{52b}⁺ in the compounds represented by Formulae (Ia-1) to (Ia-5).

The organic cations and the other moieties shown below can be appropriately combined and used as a specific photoacid generator.

First, an organic cation which can be contained in a specific photoacid generator will be exemplified.

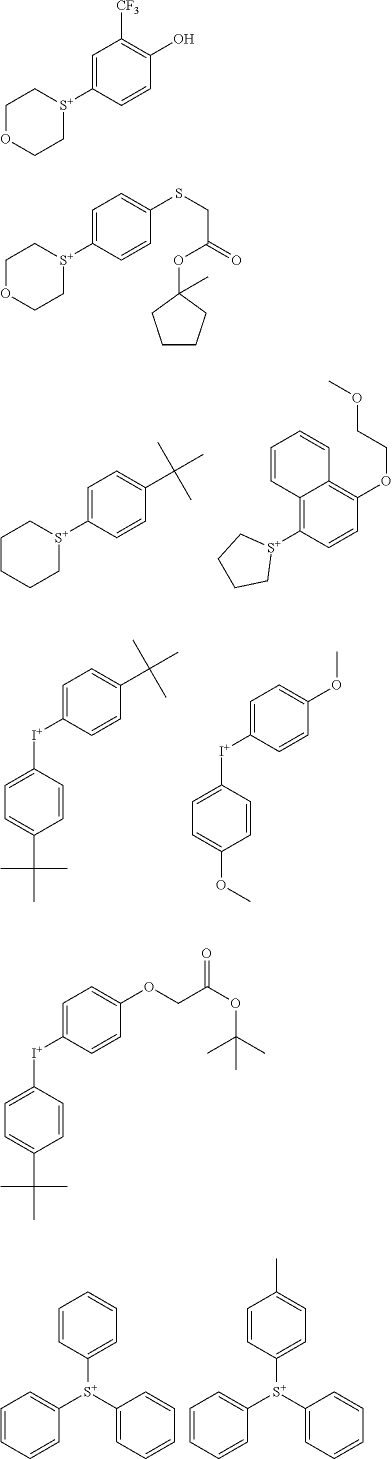

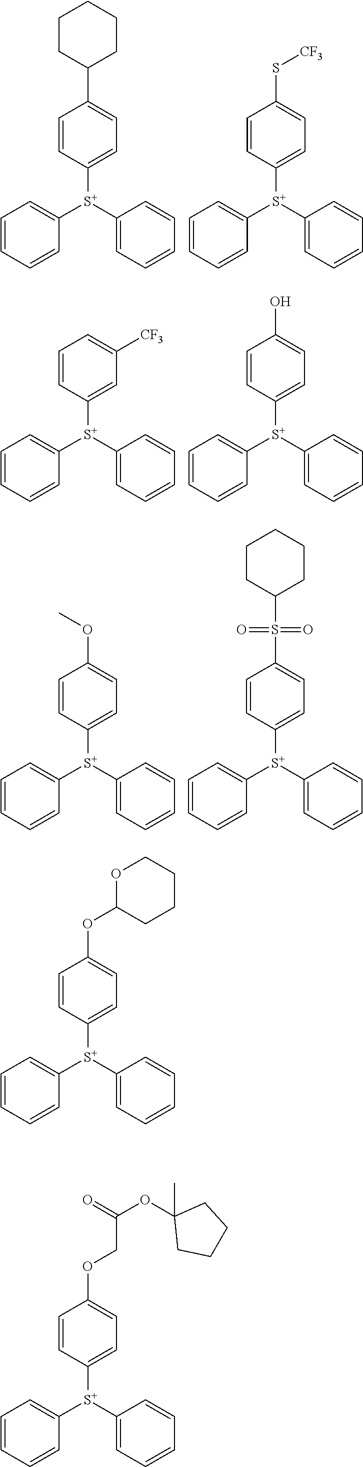

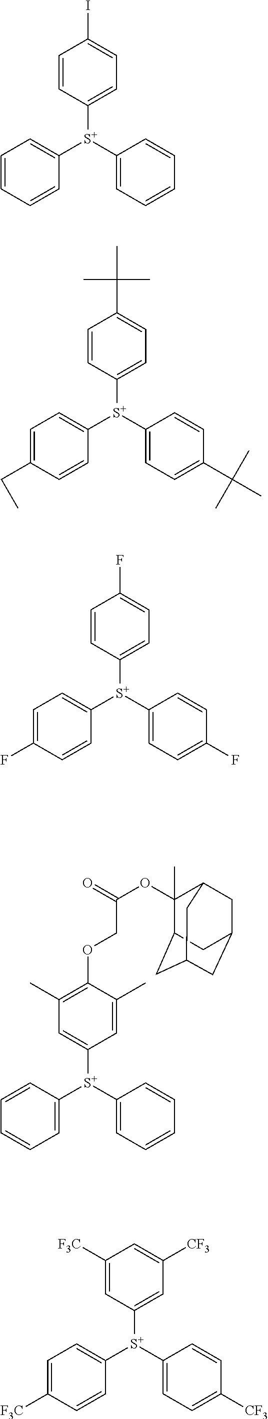 [SMILES: Ic1ccc([S+](c2ccccc2)c2ccccc2)cc1 ; CCc1ccc([S+](c2ccc(C(C)(C)C)cc2)c2ccc(C(C)(C)C)cc2)cc1 ; Fc1ccc([S+](c2ccc(F)cc2)c2ccc(F)cc2)cc1 ; Cc1cc([S+](c2ccccc2)c2ccccc2)cc(C)c1OCC(=O)OC1(C)C2CC3CC(C2)CC1C3 ; FC(F)(F)c1ccc([S+](c2ccc(C(F)(F)F)cc2)c2cc(C(F)(F)F)cc(C(F)(F)F)c2)cc1]

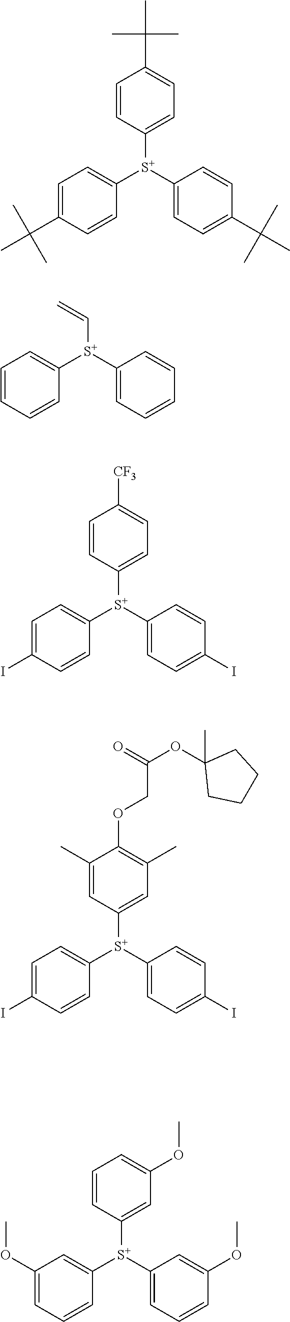 [SMILES: CC(C)(C)c1ccc([S+](c2ccc(C(C)(C)C)cc2)c2ccc(C(C)(C)C)cc2)cc1 ; C=C[S+](c1ccccc1)c1ccccc1 ; FC(F)(F)c1ccc([S+](c2ccc(I)cc2)c2ccc(I)cc2)cc1 ; Cc1cc([S+](c2ccc(I)cc2)c2ccc(I)cc2)cc(C)c1OCC(=O)OC1(C)CCCC1 ; COc1cccc([S+](c2cccc(OC)c2)c2cccc(OC)c2)c1]

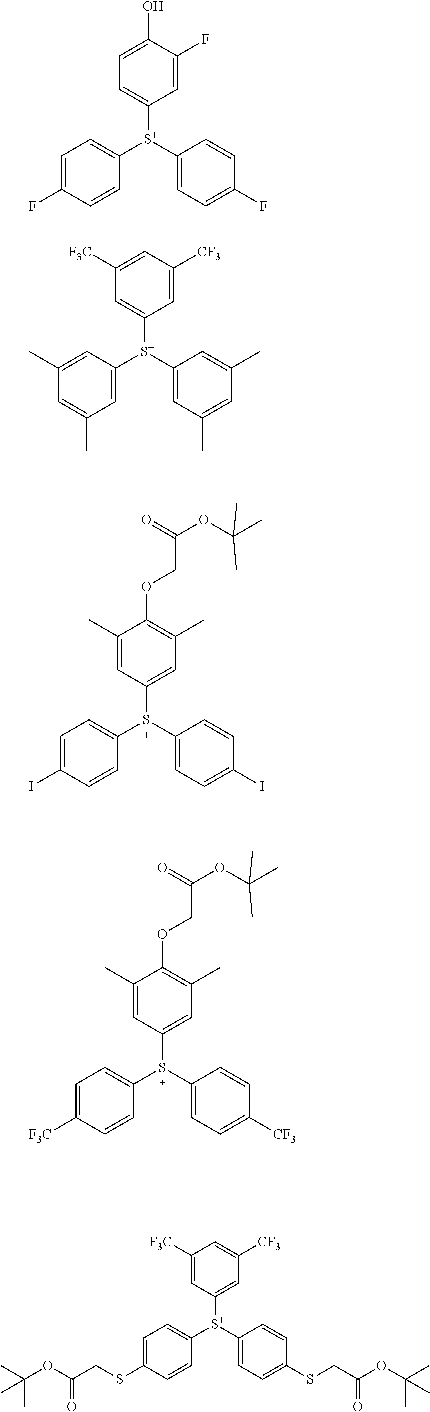

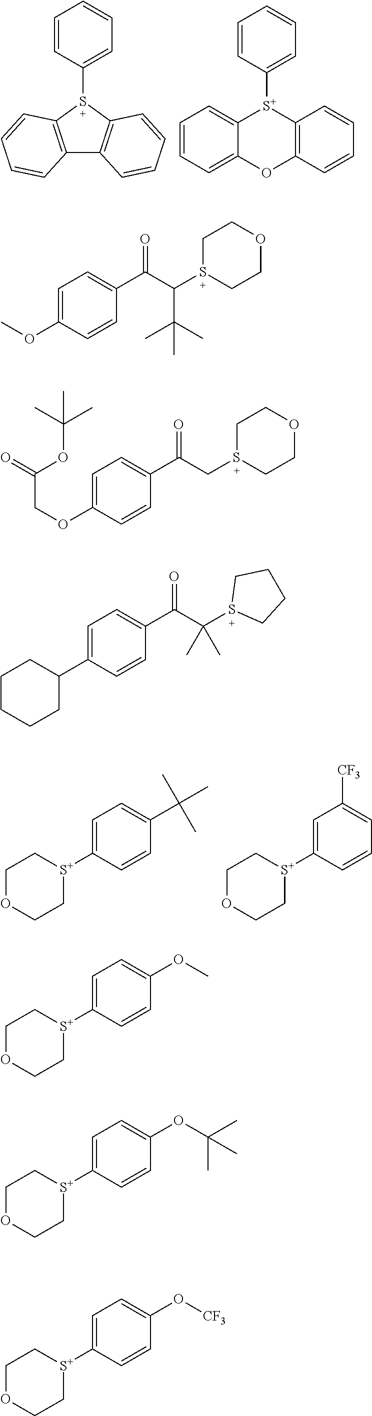

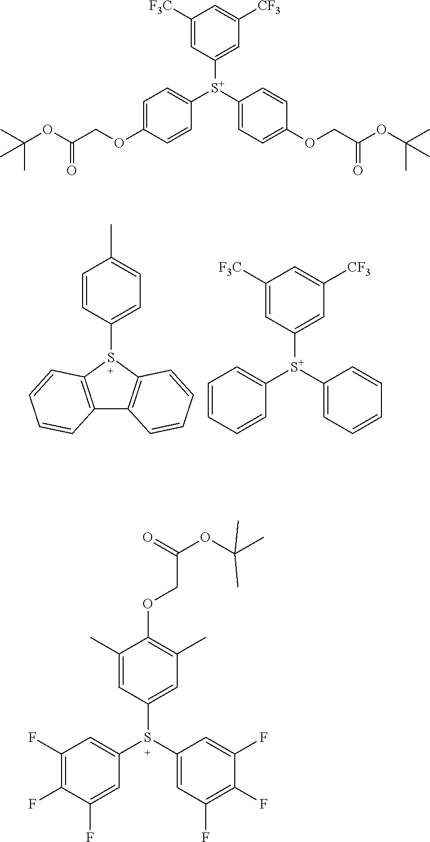

Next, a moiety other than the organic cation which can be contained in the specific photoacid generator will be exemplified.

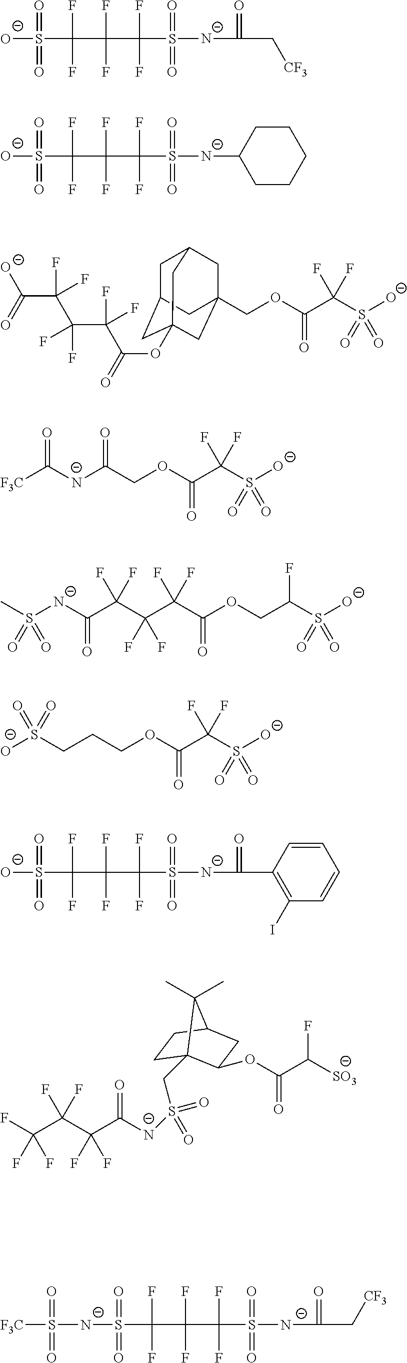

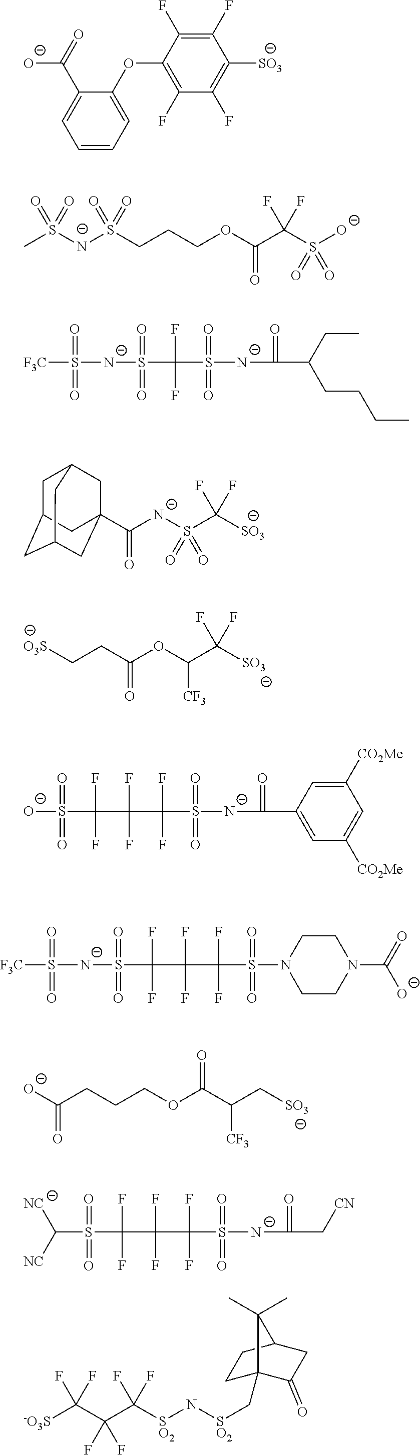

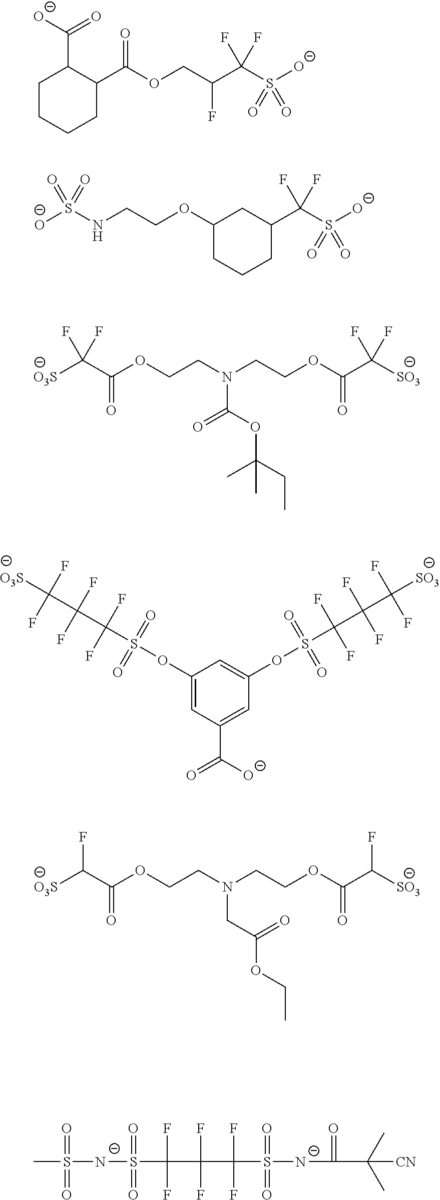

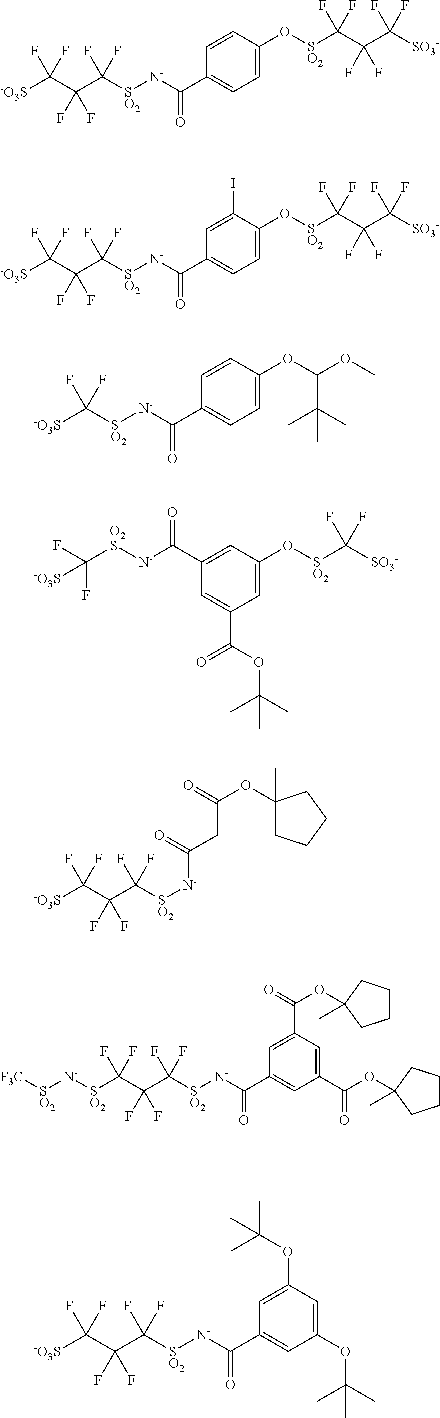

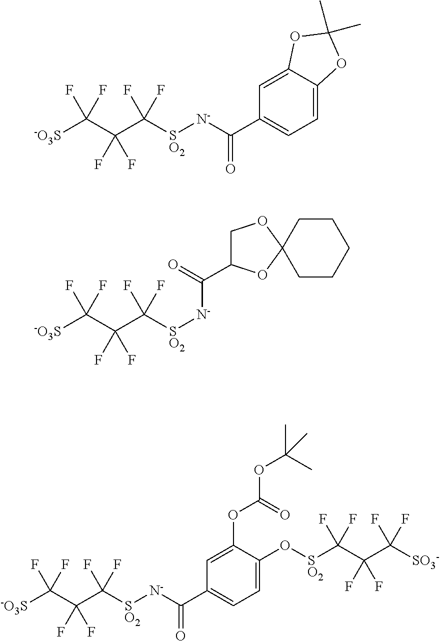

The molecular weight of the specific photoacid generator is preferably 100 to 10,000, more preferably 100 to 2,500, and still more preferably 100 to 1,500.

In a case where the composition of the present invention contains a specific photoacid generator, a content (a total content of the compounds (I) and (II)) of the specific photoacid generator is preferably 10% by mass or more, and more preferably 20% by mass or more with respect to a total solid content of the composition. In addition, the upper limit value is preferably 80% by mass or less, more preferably 70% by mass or less, and still more preferably 60% by mass or less.

The specific photoacid generators may be used alone or in combination of two or more kinds thereof. In a case where two or more kinds of such other photoacid generators are used, a total content thereof is preferably within the suitable content range.

(Compound (III))

The composition of the present invention may have the following compound (III) as the photoacid generator (P).

The compound (III) is a compound having two or more of the following structural moieties X, which the compound generates two acidic moieties derived from the following structural moieties X upon irradiation with actinic rays or radiation.

Structural moiety X: A structural moiety which consists of an anionic moiety A₁⁻ and a cationic moiety M₁⁺, and forms an acidic moiety represented by HA₁ upon irradiation with actinic rays or radiation.

The two or more structural moieties X included in the compound (III) may be the same as or different from each other. In addition, two or more A₁⁻'s and two or more M₁⁺'s may be the same as or different from each other.

In the compound (III), the definition of the structural moiety X and the definitions of A₁⁻ and M₁⁺ are the same as the definition of the structural moiety X in the compound (I), and the definitions of A₁⁻ and M₁⁺, each mentioned above, and suitable aspects thereof are also the same.

The photoacid generator is preferably a compound represented by “M⁺X⁻”. M⁺ represents an organic cation.

The organic cation is preferably the above-mentioned cation represented by Formula (ZaI) (cation (ZaI)) or the above-mentioned cation represented by Formula (ZaII) (cation (ZaII)).

<Acid Diffusion Control Agent (Q)>

The composition of the present invention may include an acid diffusion control agent (Q).

The acid diffusion control agent (Q) acts as a quencher that suppresses a reaction of an acid-decomposable resin in the unexposed area by excessive generated acids by trapping the acids generated from a photoacid generator (P) and the like upon exposure. For example, a basic compound (DA), a basic compound (DB) having basicity reduced or lost upon irradiation with radiation, an onium salt (DC) which is a relatively weak acid with respect to the photoacid generator (P), a low-molecular-weight compound (DD) having a nitrogen atom, and a group that leaves by the action of an acid, an onium salt compound (DE) having a nitrogen atom in the cationic moiety, can be used as the acid diffusion control agent (Q).

In the composition of the present invention, a known acid diffusion control agent can be appropriately used. For example, the known compounds disclosed in paragraphs 0627 to 0664 of the specification of US2016/0070167A, paragraphs 0095 to 0187 of the specification of US2015/0004544A, paragraphs 0403 to 0423 of the specification of US2016/0237190A, and paragraphs 0259 to 0328 of the specification of US2016/0274458A can be suitably used as the acid diffusion control agent (Q).

Examples of the basic compound (DA) include the repeating units described in paragraphs 0188 to 0208 of JP2019-045864A.

In the composition of the present invention, the onium salt (DC) which is a relatively weak acid with respect to the photoacid generator (P) can be used as the acid diffusion control agent (Q).

In a case where the photoacid generator (P) and the onium salt that generates an acid which is a relatively weak acid with respect to an acid generated from the photoacid generator (P) are mixed and used, an acid generated from the photoacid generator (P) upon irradiation with actinic rays or radiation produces an onium salt having a strong acid anion by discharging the weak acid through salt exchange in a case where the acid collides with an onium salt having an unreacted weak acid anion. In this process, the strong acid is exchanged with a weak acid having a lower catalytic ability, and thus, the acid is apparently deactivated and the acid diffusion can be controlled.

Examples of the onium salt that is relatively weak acid with respect to the photoacid generator (P) include the onium salts described in paragraphs 0226 to 0233 of JP2019-070676A.

In a case where the composition of the present invention includes an acid diffusion control agent (Q), a content of the acid diffusion control agent (Q) (a total content in a case where a plurality of kinds of the acid diffusion control agents are present) is preferably 0.1% to 10.0% by mass, and more preferably 0.1% to 5.0% by mass, with respect to the total solid content of the composition.

In the composition of the present invention, the acid diffusion control agents (Q) may be used alone or in combination of two or more kinds thereof.

<Hydrophobic Resin (E)>

The composition of the present invention may include a hydrophobic resin different from the resin (A), in addition to the resin (A), as the hydrophobic resin (E).

Although it is preferable that the hydrophobic resin (E) is designed to be unevenly distributed on a surface of the resist film, it does not necessarily need to have a hydrophilic group in the molecule as different from the surfactant, and does not need to contribute to uniform mixing of polar materials and non-polar materials.

Examples of the effect of addition of the hydrophobic resin (E) include a control of static and dynamic contact angles of a surface of the resist film with respect to water and suppression of out gas.

The hydrophobic resin (E) preferably has any one or more of a “fluorine atom”, a “silicon atom”, and a “CH₃ partial structure which is contained in a side chain moiety of a resin” from the viewpoint of uneven distribution on the film surface layer, and more preferably has two or more kinds thereof. Incidentally, the hydrophobic resin (E) preferably has a hydrocarbon group having 5 or more carbon atoms. These groups may be contained in the main chain of the resin or may be substituted in a side chain.

In a case where hydrophobic resin (E) includes a fluorine atom and/or a silicon atom, the fluorine atom and/or the silicon atom in the hydrophobic resin may be included in the main chain or a side chain of the resin.

In a case where the hydrophobic resin (E) contains a fluorine atom, as a partial structure having a fluorine atom, an alkyl group having a fluorine atom, a cycloalkyl group having a fluorine atom, or an aryl group having a fluorine atom is preferable.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and the alkyl group may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

Examples of the aryl group having a fluorine atom include an aryl group such as a phenyl group and a naphthyl group, in which at least one hydrogen atom is substituted with a fluorine atom, and the aryl group may further have a substituent other than a fluorine atom.

Examples of the repeating unit having a fluorine atom or a silicon atom include those exemplified in paragraph 0519 of US2012/0251948A.

Furthermore, as described above, it is also preferable that the hydrophobic resin (E) contains a CH₃ partial structure in a side chain moiety.

Here, the CH₃ partial structure contained in the side chain moiety in the hydrophobic resin includes a CH₃ partial structure contained in an ethyl group, a propyl group, and the like.

On the other hand, a methyl group bonded directly to the main chain of the hydrophobic resin (E) (for example, an α-methyl group in the repeating unit having a methacrylic acid structure) makes only a small contribution of uneven distribution on the surface of the hydrophobic resin (E) due to the effect of the main chain, and it is therefore not included in the CH₃ partial structure in the present invention.

With regard to the hydrophobic resin (E), reference can be made to the description in paragraphs 0348 to 0415 of JP2014-010245A, the contents of which are incorporated herein by reference.

Furthermore, the resins described in JP2011-248019A, JP2010-175859A, and JP2012-032544A can also be preferably used as the hydrophobic resin (E).

In a case where the composition of the present invention includes the hydrophobic resin (E), a content of the hydrophobic resin (E) is preferably 0.01% to 20% by mass, and more preferably 0.1% to 15% by mass with respect to the total solid content of the composition.

<Solvent (F)>

The composition of the present invention may include a solvent (F).

In a case where the composition of the present invention is a radiation-sensitive resin composition for EUV, it is preferable that the solvent (F) includes at least one solvent of (M1) propylene glycol monoalkyl ether carboxylate or (M2) at least one selected from the group consisting of a propylene glycol monoalkyl ether, a lactic acid ester, an acetic acid ester, an alkoxypropionic acid ester, a chain ketone, a cyclic ketone, a lactone, and an alkylene carbonate as the solvent. The solvent in this case may further include components other than the components (M1) and (M2).

The solvent including the components (M1) and (M2) is preferable since a use of the solvent in combination with the above-mentioned resin (A) makes it possible to form a pattern having a small number of development defects can be formed while improving the coating property of the composition.

In a case where the composition of the present invention is a radiation-sensitive resin composition for ArF, examples of the solvent (F) include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may include a ring, alkylene carbonate, alkyl alkoxyacetate, and alkyl pyruvate.

A content of the solvent (F) in the composition of the present invention is preferably set so that the concentration of solid contents is 0.5% to 40% by mass.

Among those, the concentration of solid contents is preferably 10% by mass or more from the viewpoint that the effect of the present invention is more excellent.

<Surfactant (H)>

The composition of the present invention may include a surfactant (H). By incorporation of the surfactant (H), it is possible to form a pattern having more excellent adhesiveness and fewer development defects.

As the surfactant (H), fluorine-based and/or silicon-based surfactants are preferable.

Examples of the fluorine-based and/or silicon-based surfactant include the surfactants described in paragraph 0276 of the specification of US2008/0248425A. In addition, EFTOP EF301 or EF303 (manufactured by Shin-Akita Chemical Co., Ltd.); FLUORAD FC430, 431, or 4430 (manufactured by Sumitomo 3M Inc.); MEGAFACE F171, F173, F176, F189, F113, F110, F177, F120, or R08 (manufactured by DIC Corporation); SURFLON S-382, SC101, 102, 103, 104, 105, or 106 (manufactured by Asahi Glass Co., Ltd.); TROYSOL S-366 (manufactured by Troy Corporation); GF-300 or GF-150 (manufactured by Toagosei Co., Ltd.); SURFLON S-393 (manufactured by AGC Seimi Chemical Co., Ltd.); EFTOP EF121, EF122A, EF122B, RF122C, EF125M, EF135M, EF351, EF352, EF801, EF802, or EF601 (manufactured by JEMCO Inc.); PF636, PF656, PF6320, or PF6520 (manufactured by OMNOVA Solutions Inc.); KH-20 (manufactured by Asahi Kasei Corporation); or FTX-204G, 208G, 218G, 230G, 204D, 208D, 212D, 218D, or 222D (manufactured by NEOS COMPANY LIMITED) may be used. In addition, a polysiloxane polymer, KP-341 (manufactured by Shin-Etsu Chemical Co., Ltd.), can also be used as the silicon-based surfactant.

Moreover, the surfactant (H) may be synthesized using a fluoroaliphatic compound manufactured using a telomerization method (also referred to as a telomer method) or an oligomerization method (also referred to as an oligomer method), in addition to the known surfactants as shown above. Specifically, a polymer including a fluoroaliphatic group derived from fluoroaliphatic compound may be used as the surfactant (H). This fluoroaliphatic compound can be synthesized, for example, by the method described in JP2002-90991A.

As the polymer having a fluoroaliphatic group, a copolymer of a monomer having a fluoroaliphatic group and (poly(oxyalkylene))acrylate and/or (poly(oxyalkylene))methacrylate is preferable, and the polymer may be unevenly distributed or block-copolymerized. Furthermore, examples of the poly(oxyalkylene) group include a poly(oxyethylene) group, a poly(oxypropylene) group, and a poly(oxybutylene) group, and the group may also be a unit such as those having alkylenes having different chain lengths within the same chain length such as poly(block-linked oxyethylene, oxypropylene, and oxyethylene) and poly(block-linked oxyethylene and oxypropylene). In addition, the copolymer of a monomer having a fluoroaliphatic group and (poly(oxyalkylene))acrylate (or methacrylate) is not limited only to a binary copolymer but may also be a ternary or higher copolymer obtained by simultaneously copolymerizing monomers having two or more different fluoroaliphatic groups or two or more different (poly(oxyalkylene)) acrylates (or methacrylates).

Examples of a commercially available surfactant thereof include MEGAFACE F-178, F-470, F-473, F-475, F-476, and F-472 (manufactured by DIC Corporation), a copolymer of acrylate (or methacrylate) having a C₆F₁₃ group and (poly(oxyalkylene))acrylate (or methacrylate), and a copolymer of acrylate (or methacrylate) having a C₃F₇ group, (poly(oxyethylene))acrylate (or methacrylate), and (poly(oxypropylene))acrylate (or methacrylate).

In addition, a surfactant other than the fluorine-based surfactant and/or the silicon-based surfactants described in paragraph 0280 of the specification of US2008/0248425A may be used.

These surfactants (H) may be used alone or in combination of two or more kinds thereof.

The content of the surfactant (H) is preferably 0.0001% to 2% by mass and more preferably 0.0005% to 1% by mass with respect to the total solid content of the composition.

The composition of the present invention is also suitably used as a photosensitive composition for EUV light.

EUV light has a wavelength of 13.5 nm, which is a shorter wavelength than that of ArF (wavelength of 193 nm) light or the like, and therefore, the EUV light has a smaller number of incidence photons upon exposure with the same sensitivity. Thus, an effect of “photon shot noise” that the number of photons is statistically non-uniform is significant, and a deterioration in LER and a bridge defect are caused. In order to reduce the photon shot noise, a method in which an exposure amount increases to cause an increase in the number of incidence photons is available, but the method is a trade-off with a demand for a higher sensitivity.

In a case where the A value obtained by Expression (1) is high, the absorption efficiency of EUV light and electron beam of the resist film formed from the composition is higher, which is effective in reducing the photon shot noise. The A value represents the absorption efficiency of EUV light and electron beams of the resist film in terms of a mass proportion.

A=([H]×0.04+[C]×1.0+[N]×2.1+[O]×3.6+[F]×5.6+[S]×1.5+[I]×39.5)/([H]×1+[C]×12+[N]×14+[O]×16+[F]×19+[S]×32+[I]×127) Expression (1):

The A value is preferably 0.120 or more. An upper limit thereof is not particularly limited, but in a case where the A value is extremely high, the transmittance of EUV light and electron beams of the resist film is lowered and the optical image profile in the resist film is deteriorated, which results in difficulty in obtaining a good pattern shape, and therefore, the upper limit is preferably 0.240 or less, and more preferably 0.220 or less.

Moreover, in Expression (1), [H] represents a molar ratio of hydrogen atoms derived from the total solid content with respect to all the atoms of the total solid content in the radiation-sensitive resin composition, [C] represents a molar ratio of carbon atoms derived from the total solid content with respect to all the atoms of the total solid content in the radiation-sensitive resin composition, [N] represents a molar ratio of nitrogen atoms derived from the total solid content with respect to all the atoms of the total solid content in the radiation-sensitive resin composition, [O] represents a molar ratio of oxygen atoms derived from the total solid content with respect to all the atoms of the total solid content in the radiation-sensitive resin composition, [F] represents a molar ratio of fluorine atoms derived from the total solid content with respect to all the atoms of the total solid content in the radiation-sensitive resin composition, [S] represents a molar ratio of sulfur atoms derived from the total solid content with respect to all the atoms of the total solid content in the radiation-sensitive resin composition, and [I] represents a molar ratio of iodine atoms derived from the total solid content with respect to all the atoms of the total solid content in the radiation-sensitive resin composition.

For example, in a case where the composition includes a resin (acid-decomposable resin) having a polarity that increases by the action of an acid, a photoacid generator, an acid diffusion control agent, and a solvent, the resin, the photoacid generator, and the acid diffusion control agent correspond to the solid content. That is, all the atoms of the total solid content correspond to a sum of all the atoms derived from the resin, all the atoms derived from the photoacid generator, and all the atoms derived from the acid diffusion control agent. For example, [H] represents a molar ratio of hydrogen atoms derived from the total solid content with respect to all the atoms in the total solid content, and by way of description based on the example above, [H] represents a molar ratio of a sum of the hydrogen atoms derived from the resin, the hydrogen atoms derived from the photoacid generator, and the hydrogen atoms derived from the acid diffusion control agent with respect to a sum of all the atoms derived from the resin, all the atoms derived from the photoacid generator, and all the atoms derived from the acid diffusion control agent.

The A value can be calculated by computation of the structure of constituents of the total solid content in the composition, and the atomic number ratio contained in a case where the content is already known. In addition, even in a case where the constituent is not known yet, it is possible to calculate an atomic number ratio by subjecting a resist film obtained after evaporating the solvent components of the composition to computation according to an analytic approach such as elemental analysis.

<Other Additives>

The composition of the present invention may further include a crosslinking agent, an alkali-soluble resin, a dissolution inhibiting compound, a dye, a plasticizer, a photosensitizer, a light absorber, and/or a compound that accelerates solubility in a developer.

### EXAMPLES

Hereinbelow, the present invention will be described in more detail with reference to Examples. The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

<Synthesis of Resin (A)>

In Examples and Comparative Examples, resins A-1 to A-61 exemplified below were used as the resin (A). As the resins A-1 to A-61, those synthesized based on known techniques were used.

The compositional ratio (molar ratio; corresponding in order from the left), the weight-average molecular weight (Mw), and the dispersity (Mw/Mn) of each repeating unit in the resin (A) are shown in Table 7.

Furthermore, the weight-average molecular weight (Mw) and the dispersity (Mw/Mn) of the resins A-1 to A-61 are value expressed in terms of polystyrenes, as measured by the above-mentioned GPC method (carrier: tetrahydrofuran (THF)). In addition, the compositional ratio (ratio based on % by mole) of the repeating unit in the resin was measured by ¹³C-nuclear magnetic resonance (NMR).

TABLE 7

| Resin | Molar ratio of repeating unit | | | | | Mw | Mw/Mn |
|---|---|---|---|---|---|---|---|
| A-1 | 64 | 18 | 18 | | | 21,000 | 1.5 |
| A-2 | 62 | 13 | 20 | 5 | | 13,000 | 1.3 |
| A-3 | 75 | 20 | 5 | | | 10,000 | 1.4 |
| A-4 | 40 | 18 | 42 | | | 28,000 | 1.9 |
| A-5 | 70 | 25 | 5 | | | 7,000 | 1.7 |
| A-6 | 53 | 12 | 35 | | | 15,000 | 1.6 |
| A-7 | 70 | 12 | 18 | | | 17,000 | 1.6 |
| A-8 | 60 | 20 | 20 | | | 12,000 | 2.8 |
| A-9 | 75 | 25 | | | | 21,000 | 1.3 |
| A-10 | 75 | 25 | | | | 21,000 | 1.3 |
| A-11 | 65 | 25 | 10 | | | 21,000 | 1.3 |
| A-12 | 68 | 25 | 7 | | | 21,000 | 1.9 |
| A-13 | 65 | 25 | 10 | | | 21,000 | 1.4 |
| A-14 | 55 | 35 | 10 | | | 21,000 | 1.4 |
| A-15 | 65 | 25 | 10 | | | 21,000 | 1.3 |
| A-16 | 65 | 25 | 10 | | | 21,000 | 1.3 |
| A-17 | 65 | 25 | 10 | | | 21,000 | 1.3 |
| A-18 | 40 | 50 | 10 | | | 13,000 | 1.4 |
| A-19 | 45 | 55 | | | | 18,000 | 1.7 |
| A-20 | 20 | 10 | 40 | 30 | | 10,500 | 1.6 |
| A-21 | 40 | 40 | 20 | | | 8,000 | 1.6 |
| A-22 | 40 | 40 | 10 | 10 | | 13,500 | 1.7 |
| A-23 | 50 | 50 | | | | 10,000 | 1.6 |
| A-24 | 35 | 45 | 20 | | | 9,000 | 1.7 |
| A-25 | 50 | 10 | 40 | | | 7,500 | 1.6 |
| A-26 | 50 | 50 | | | | 8,600 | 1.6 |
| A-27 | 45 | 15 | 5 | 35 | | 7,600 | 1.6 |
| A-28 | 20 | 15 | 55 | 10 | | 8,300 | 1.7 |
| A-29 | 35 | 15 | 25 | 25 | | 10,000 | 1.7 |
| A-30 | 50 | 25 | 25 | | | 9,000 | 1.8 |
| A-31 | 40 | 10 | 35 | 5 | 10 | 10,000 | 1.7 |
| A-32 | 40 | 60 | | | | 8,000 | 1.6 |
| A-33 | 30 | 60 | 10 | | | 8,600 | 1.5 |
| A-34 | 25 | 25 | 50 | | | 9,000 | 1.8 |
| A-35 | 30 | 50 | 20 | | | 8,000 | 1.6 |
| A-36 | 40 | 35 | 25 | | | 8,000 | 1.5 |
| A-37 | 30 | 10 | 50 | 10 | | 6,000 | 1.5 |
| A-38 | 10 | 30 | 40 | 20 | | 8,000 | 1.7 |
| A-39 | 35 | 40 | 25 | | | 12,000 | 1.8 |
| A-40 | 35 | 40 | 25 | | | 4,000 | 1.4 |
| A-41 | 30 | 20 | 20 | 30 | | 3,000 | 1.4 |
| A-42 | 15 | 35 | 20 | 5 | 25 | 4,000 | 1.3 |
| A-43 | 20 | 20 | 40 | 20 | | 15,000 | 1.8 |
| A-44 | 10 | 20 | 50 | 20 | | 6,500 | 1.5 |
| A-45 | 40 | 15 | 30 | 15 | | 8,000 | 1.5 |
| A-46 | 10 | 20 | 20 | 30 | 20 | 5,500 | 1.7 |
| A-47 | 35 | 35 | 30 | | | 7,200 | 1.5 |
| A-48 | 25 | 45 | 30 | | | 7,600 | 1.9 |
| A-49 | 60 | 40 | | | | 6,800 | 1.6 |
| A-50 | 19 | 32 | 34 | 4 | 11 | 8,000 | 1.6 |
| A-51 | 10 | 30 | 20 | 25 | 15 | 7,600 | 1.7 |

TABLE 8

| Resin | Molar ratio of repeating unit | | | | Mw | Mw/Mn |
|---|---|---|---|---|---|---|
| A-52 | 20 | 30 | 10 | 40 | 10,000 | 1.6 |
| A-53 | 25 | 20 | 10 | 45 | 8,000 | 1.6 |
| A-54 | 20 | 20 | 60 | | 12,000 | 1.7 |
| A-55 | 30 | 20 | 50 | | 6,000 | 1.6 |
| A-56 | 40 | 10 | 50 | | 5,000 | 1.4 |
| A-57 | 20 | 10 | 70 | | 7,000 | 1.4 |
| A-58 | 30 | 15 | 55 | | 9,000 | 1.5 |
| A-59 | 40 | 30 | 30 | | 10,000 | 1.6 |
| A-60 | 50 | 45 | 5 | | 6,000 | 1.4 |
| A-61 | 40 | 57 | 3 | | 6,000 | 1.5 |

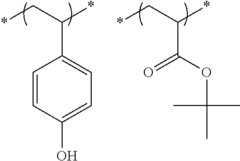

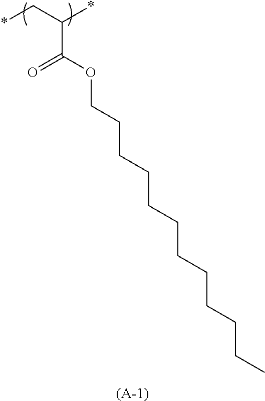

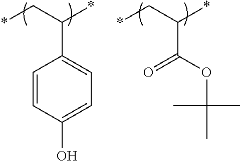

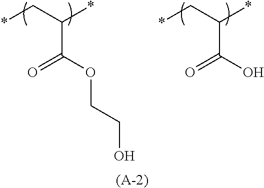

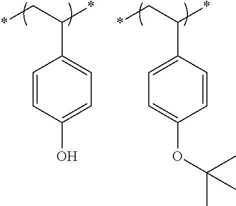

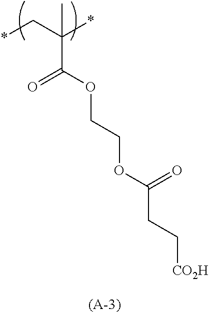

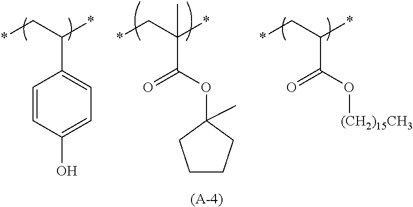

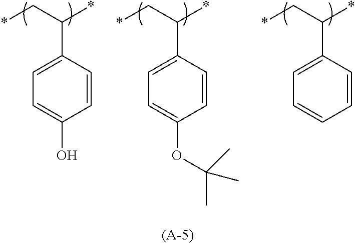

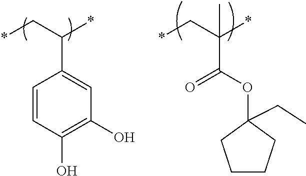

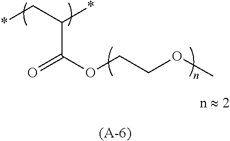

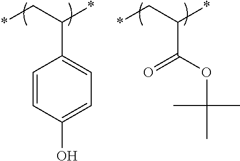

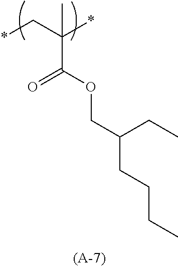

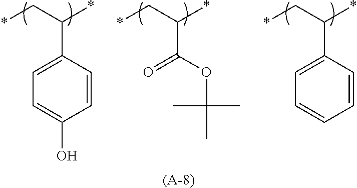

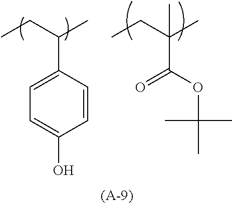

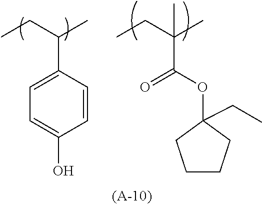

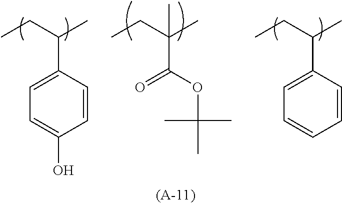

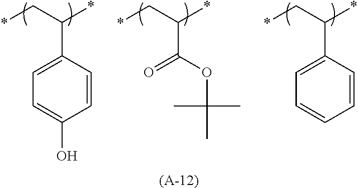

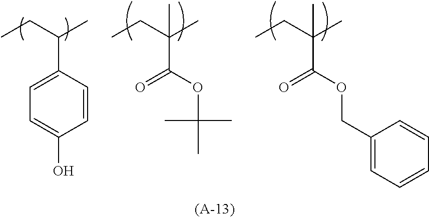

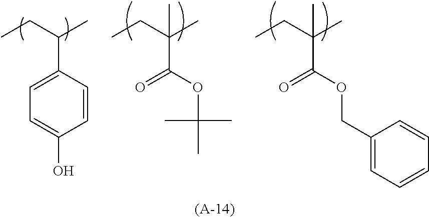

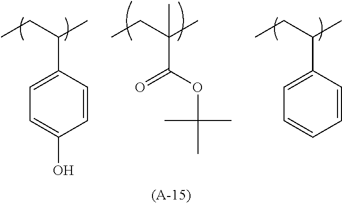

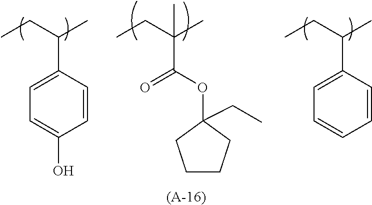

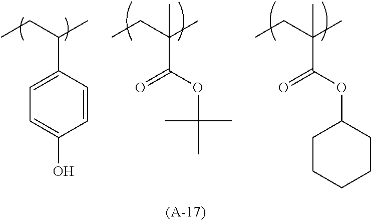

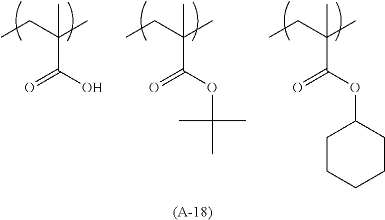

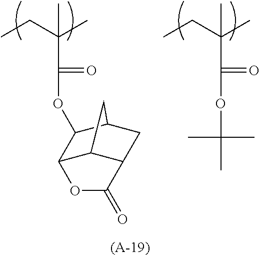

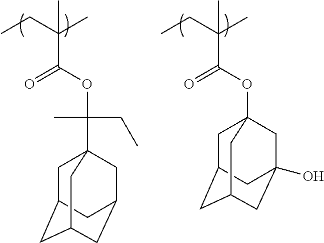

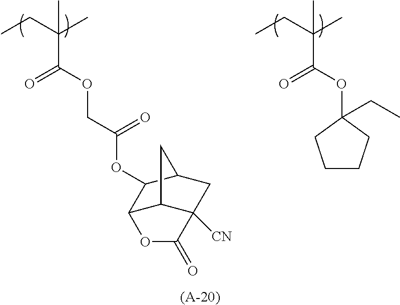

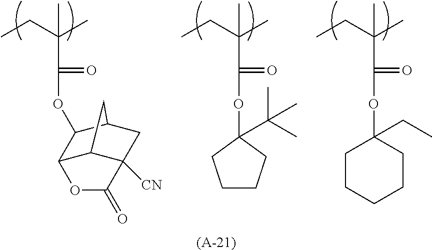

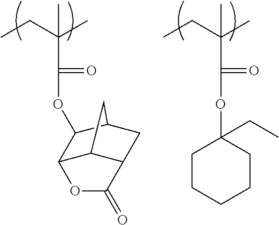

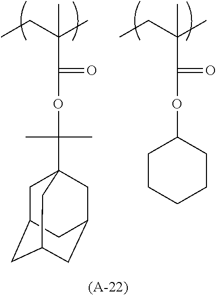

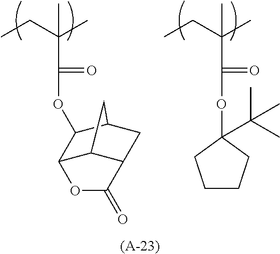

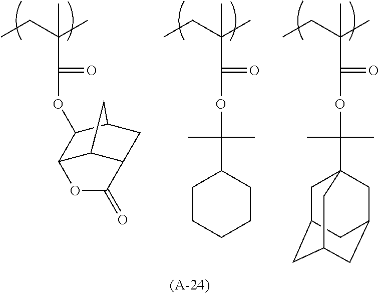

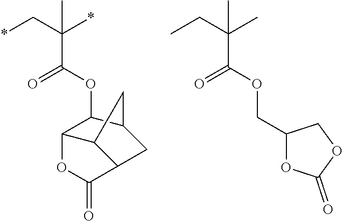 [SMILES: *CC(*)(C)C(=O)OC1C2CC3C(=O)OC1C3C2 ; CCC(C)(C)C(=O)OCC1COC(=O)O1]

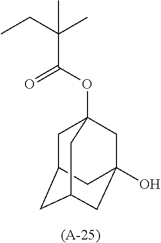

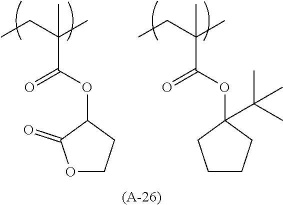

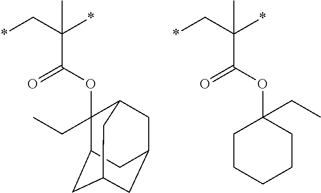 [SMILES: *CC(*)(C)C(=O)OC1(CC)C2CC3CC(C2)CC1C3 ; *CC(*)(C)C(=O)OC1(CC)CCCCC1]

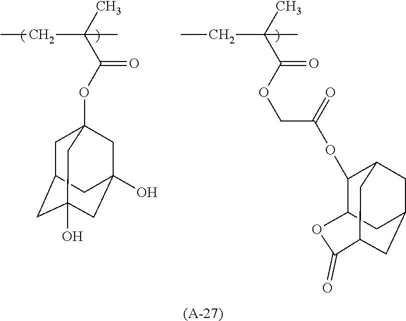

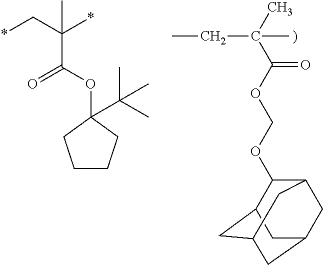

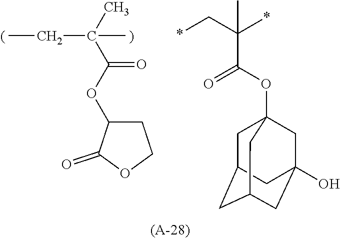

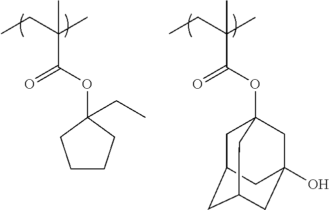

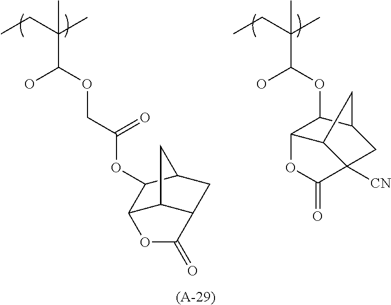

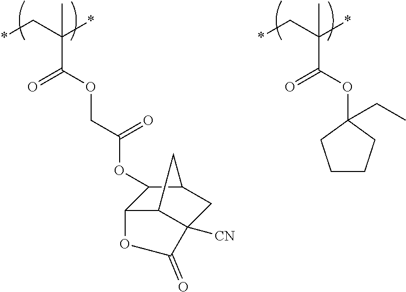

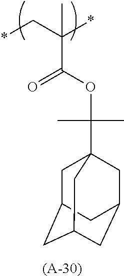

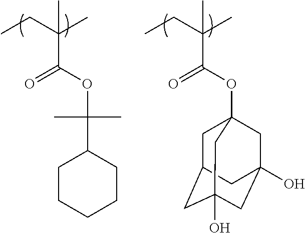

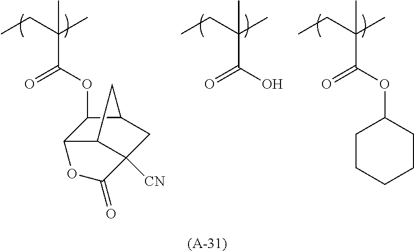

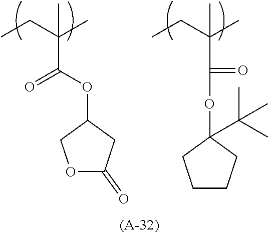

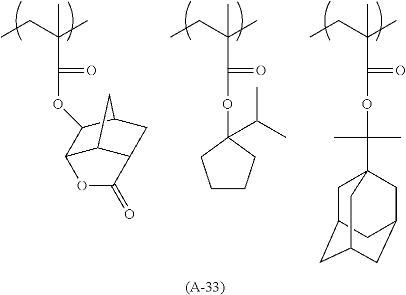

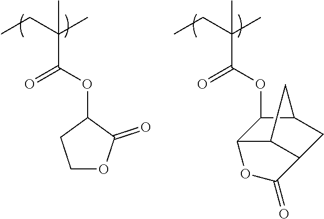

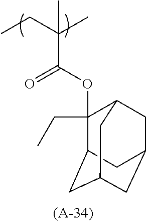

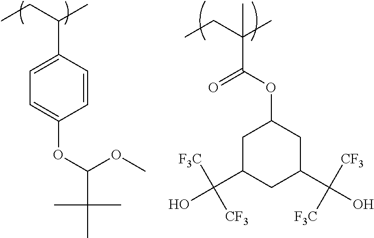

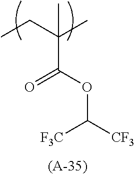

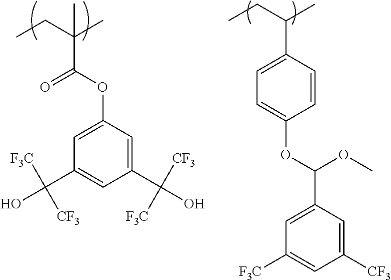

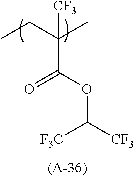

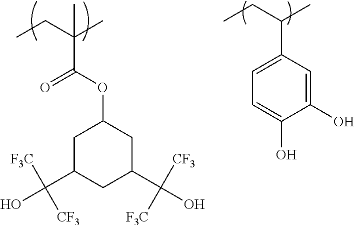

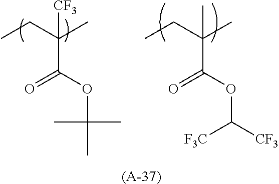

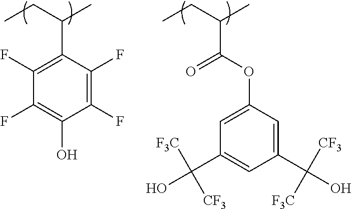

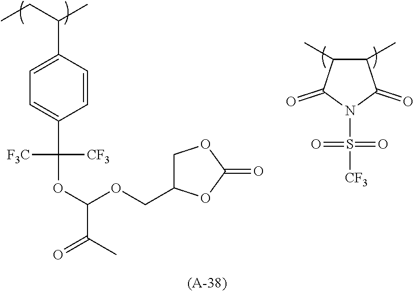

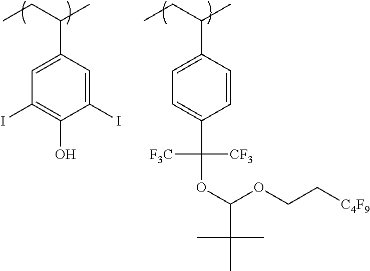

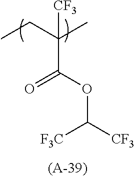

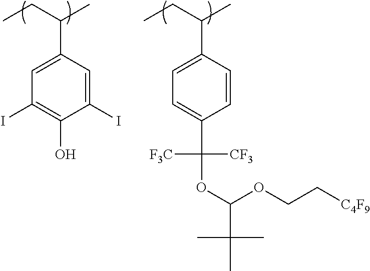

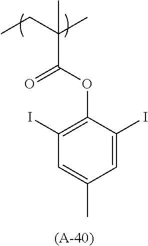

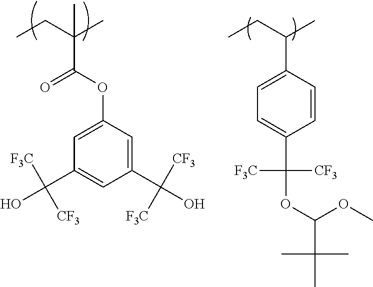

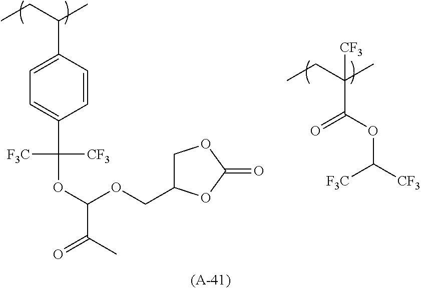

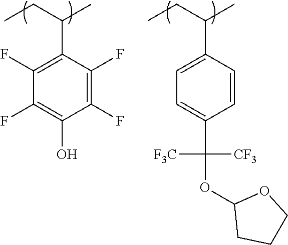

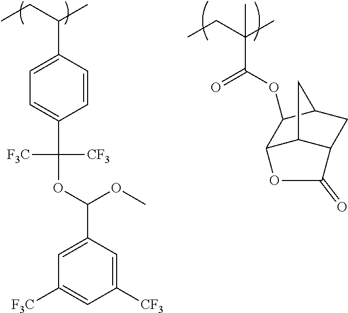

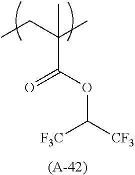

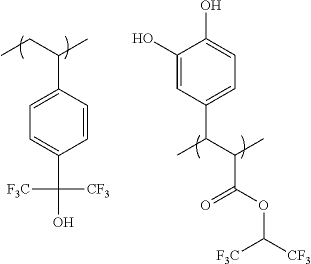

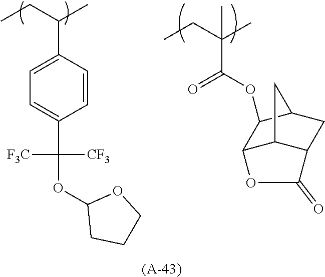

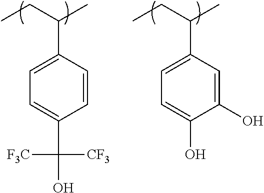

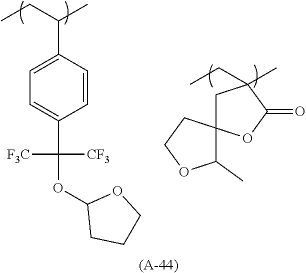

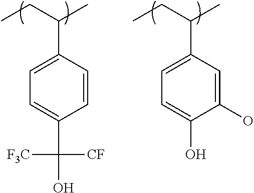

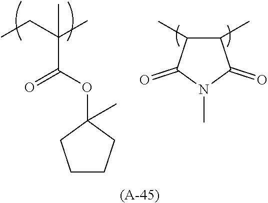

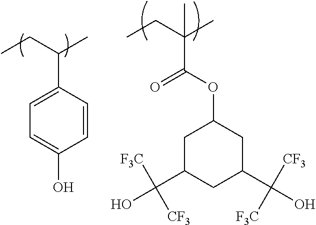

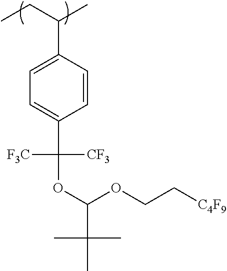

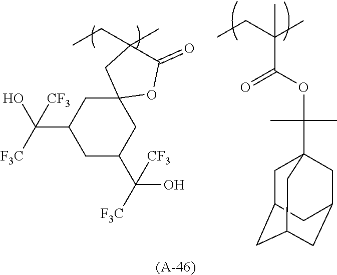

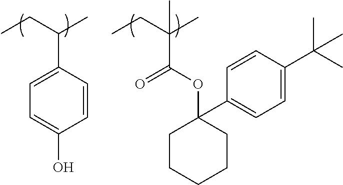

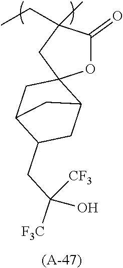

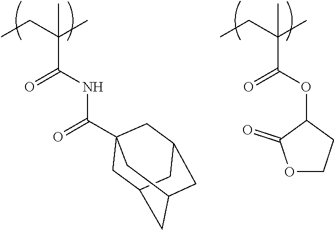

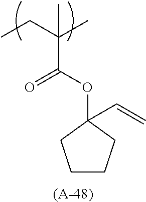

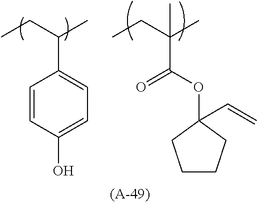

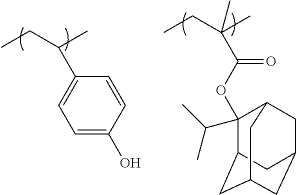

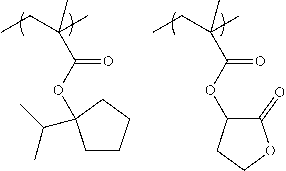

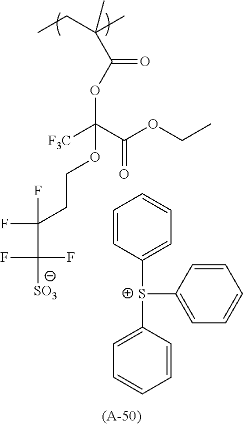

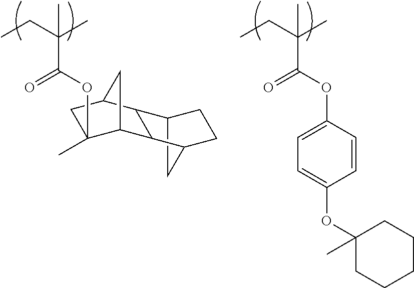

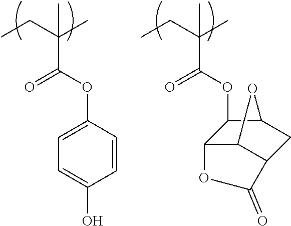

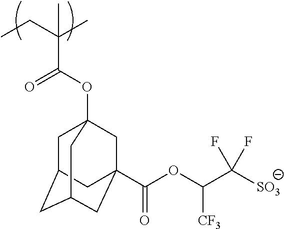

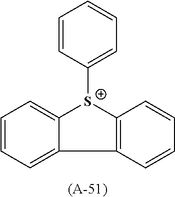

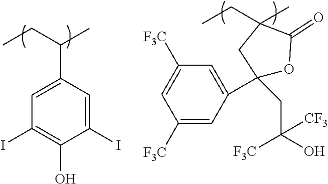

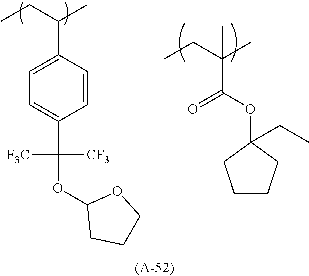

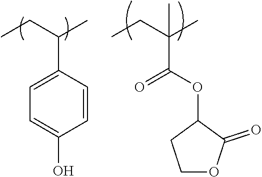

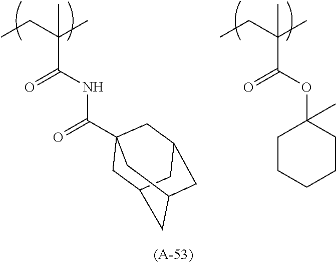

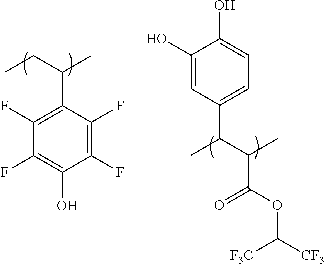

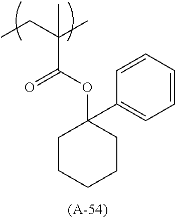

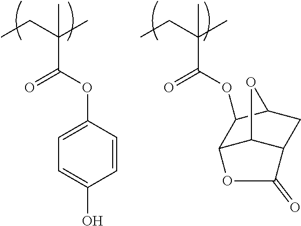

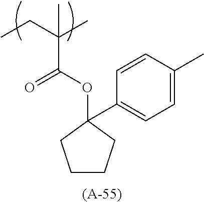

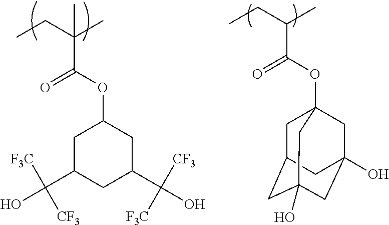

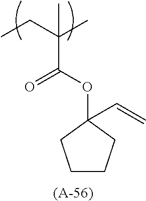

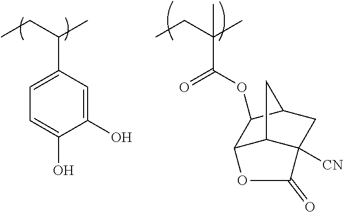

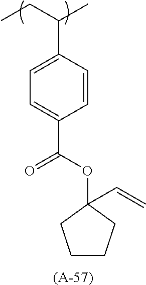

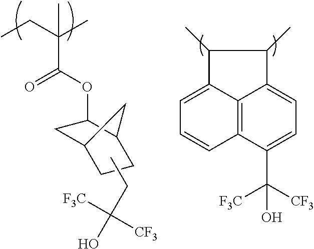

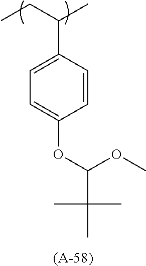

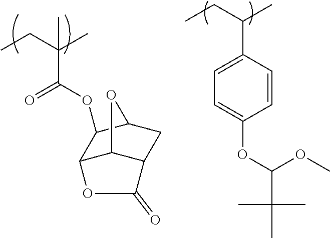

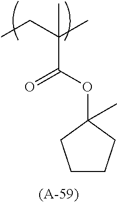

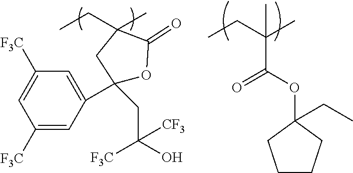

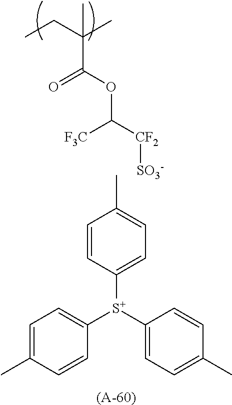

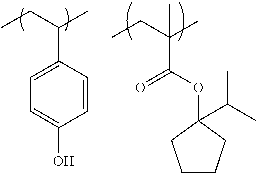

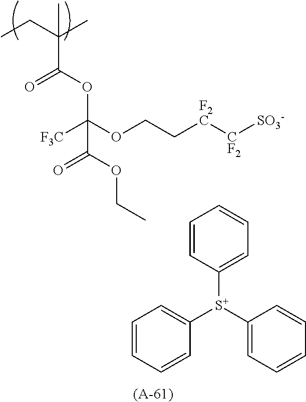

<Photoacid Generator>

The structures of the compounds P-1 to P-63 used as the photoacid generator in Examples and Comparative Examples are shown below.

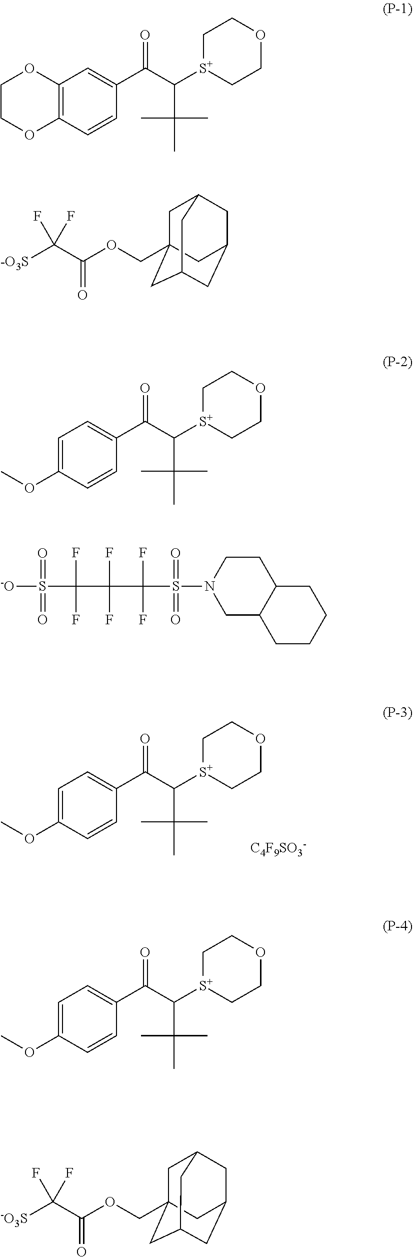

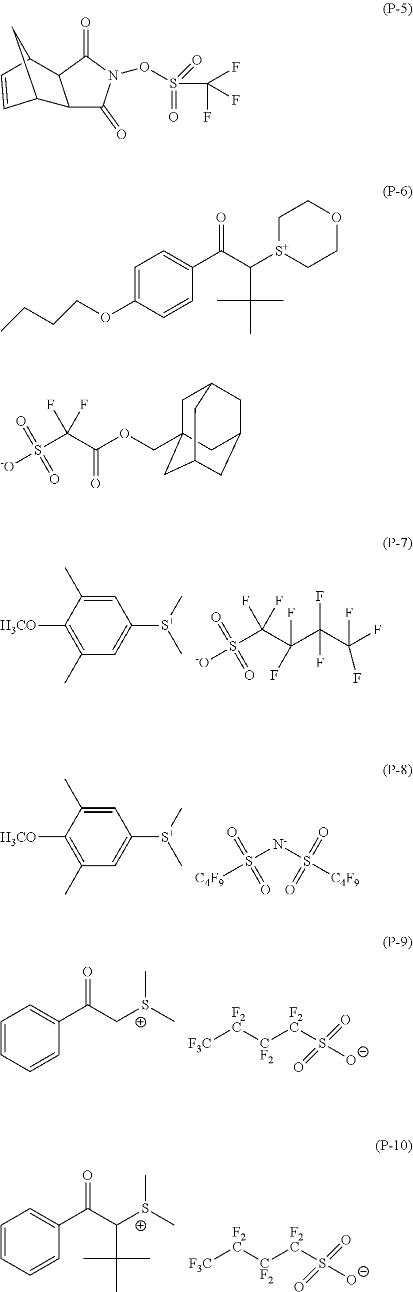

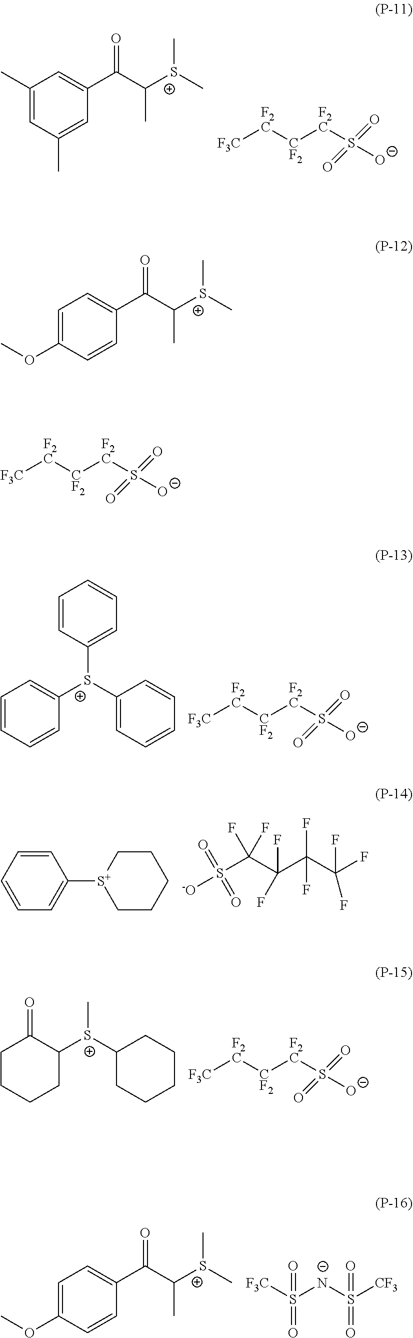

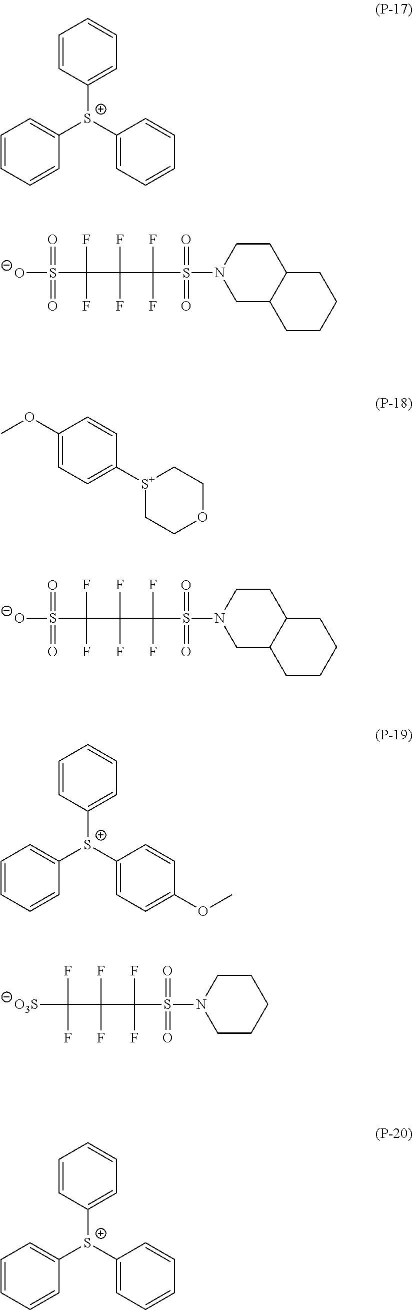

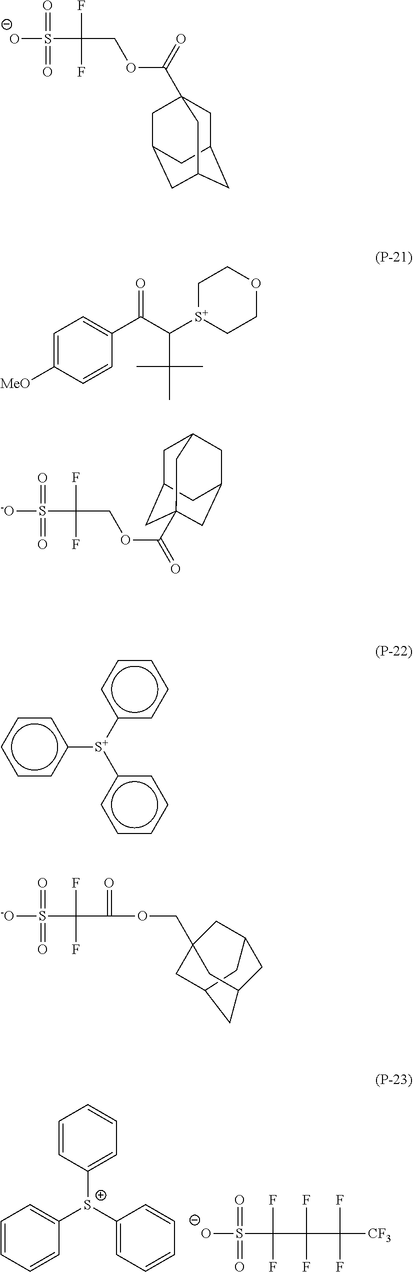

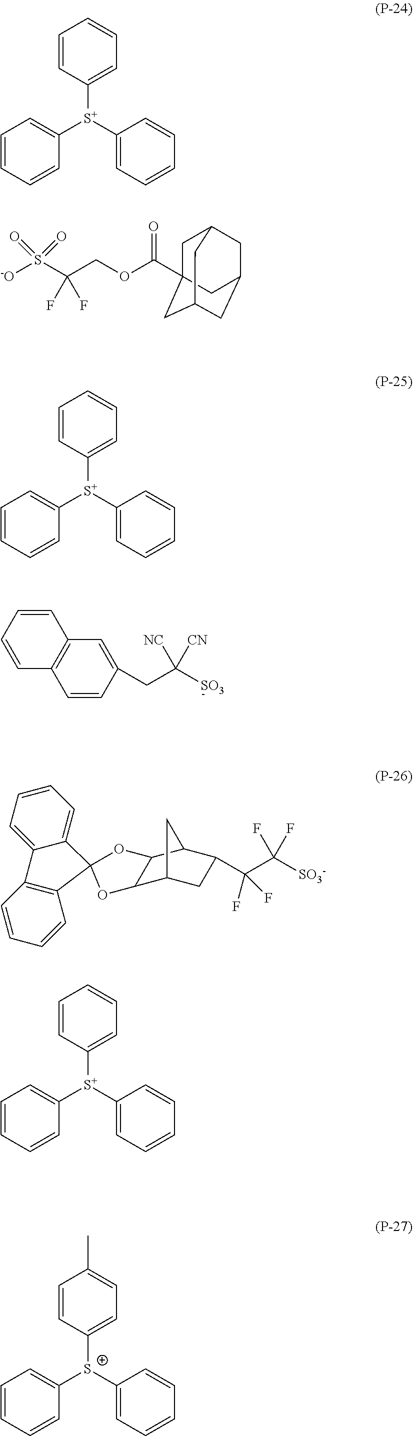

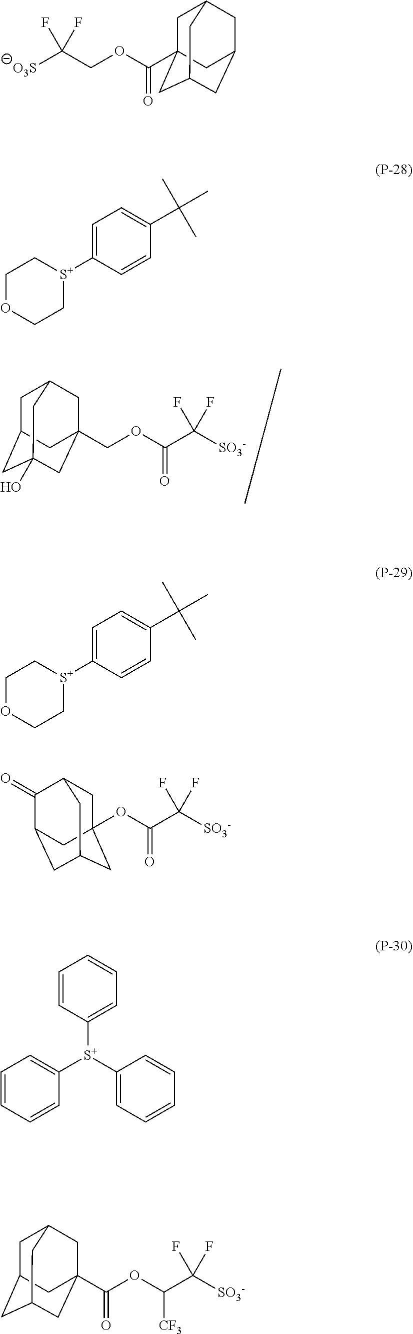

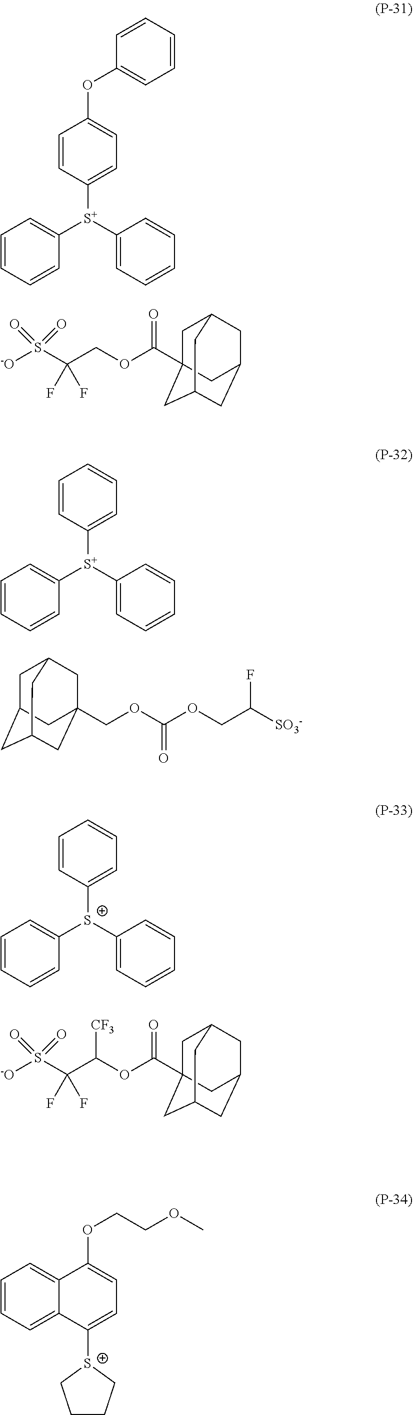

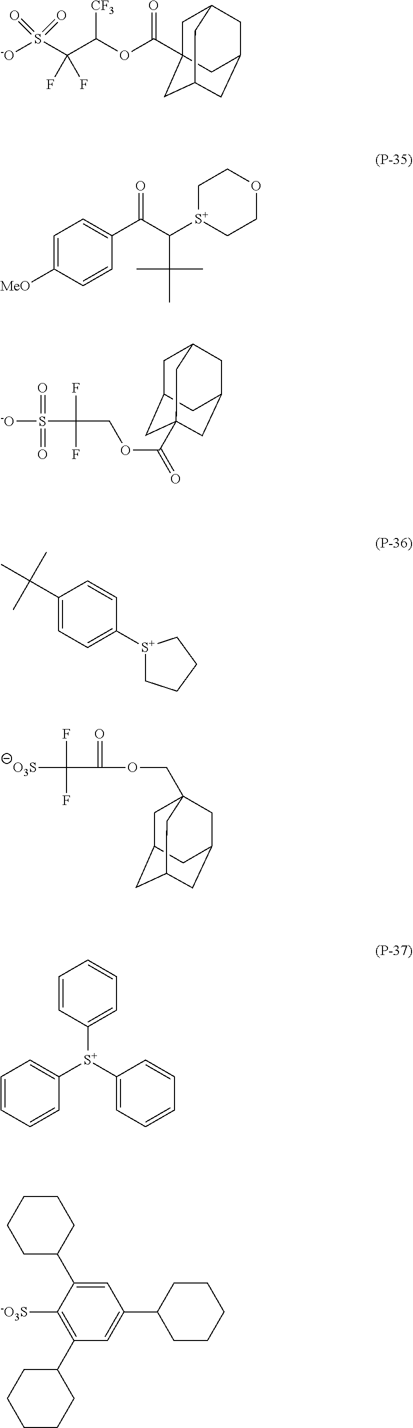

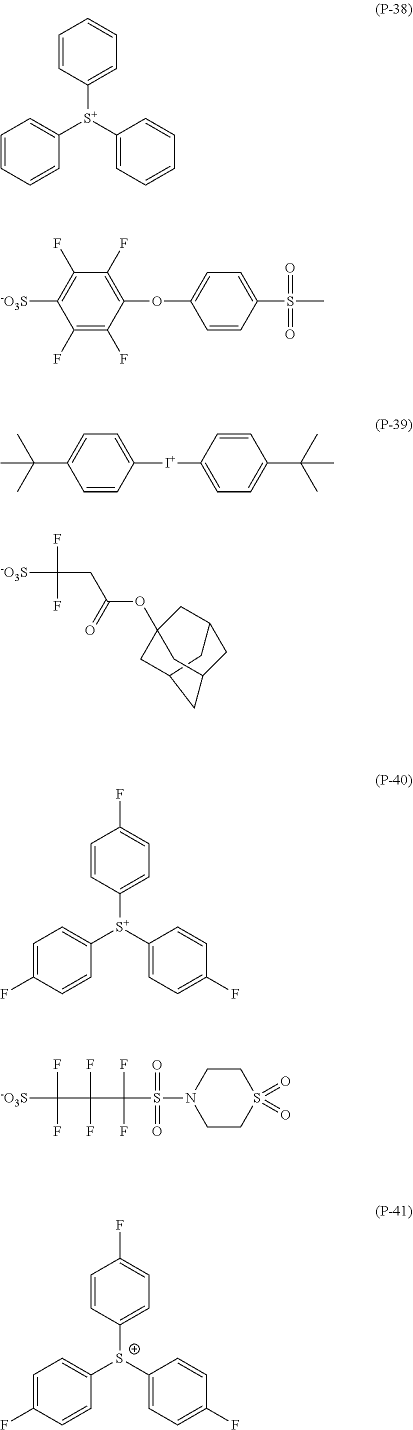

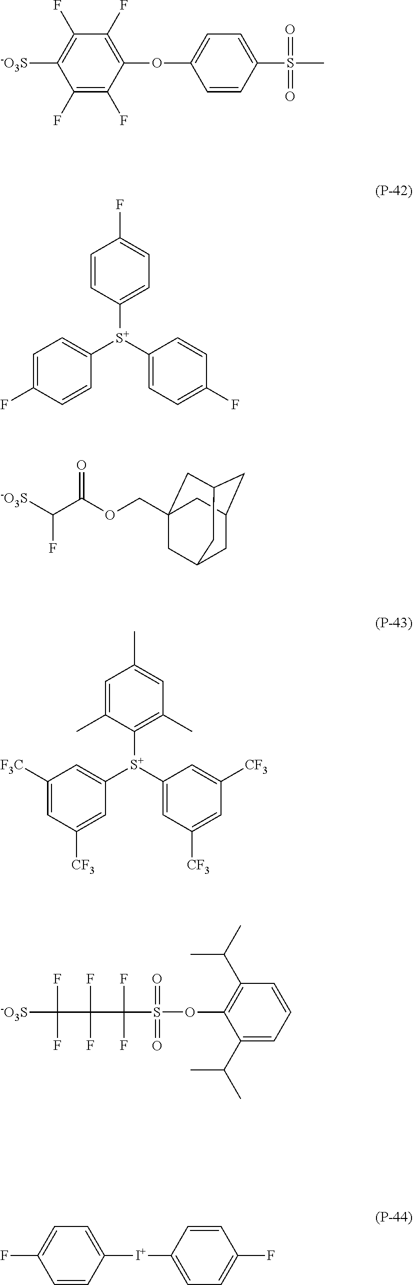

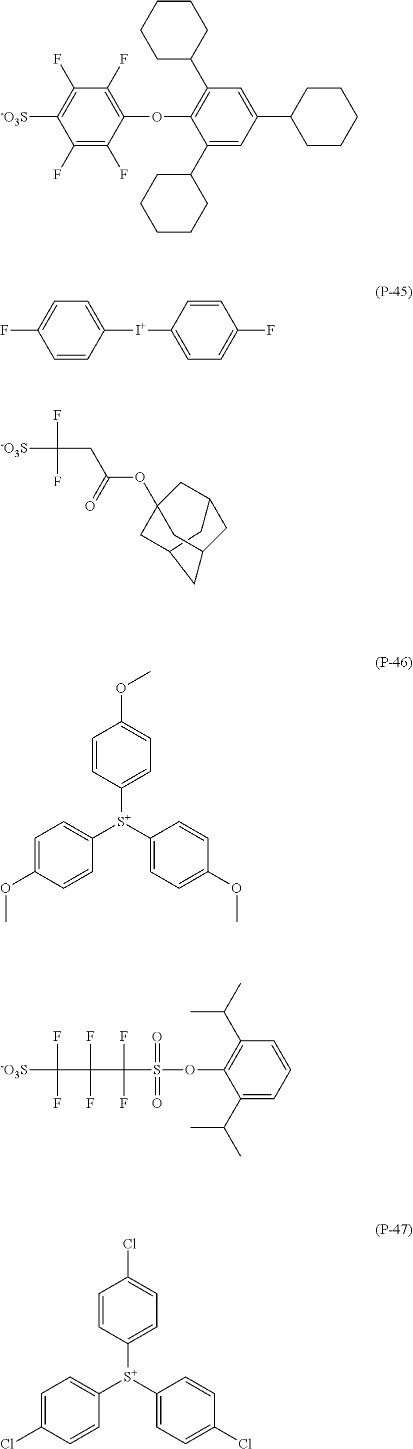

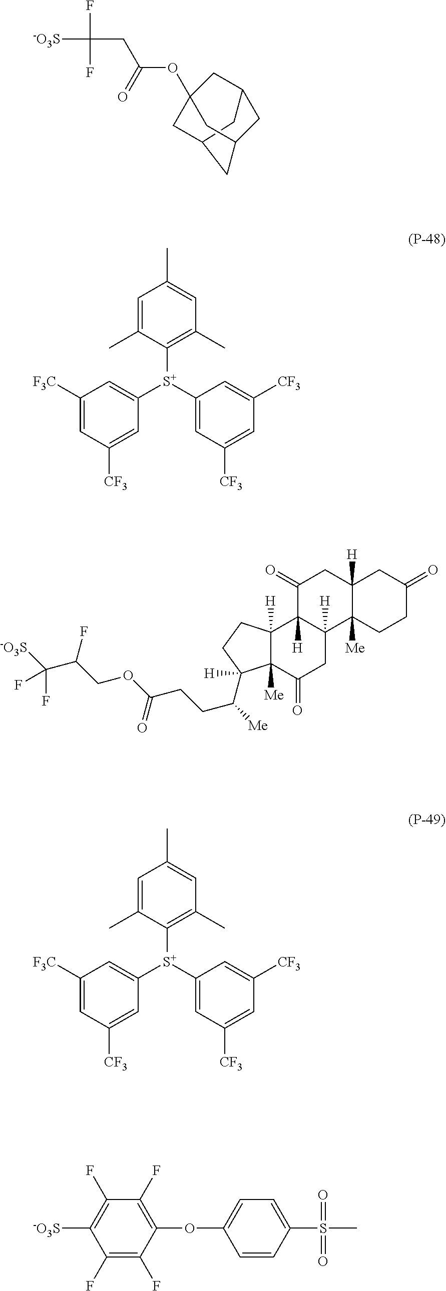

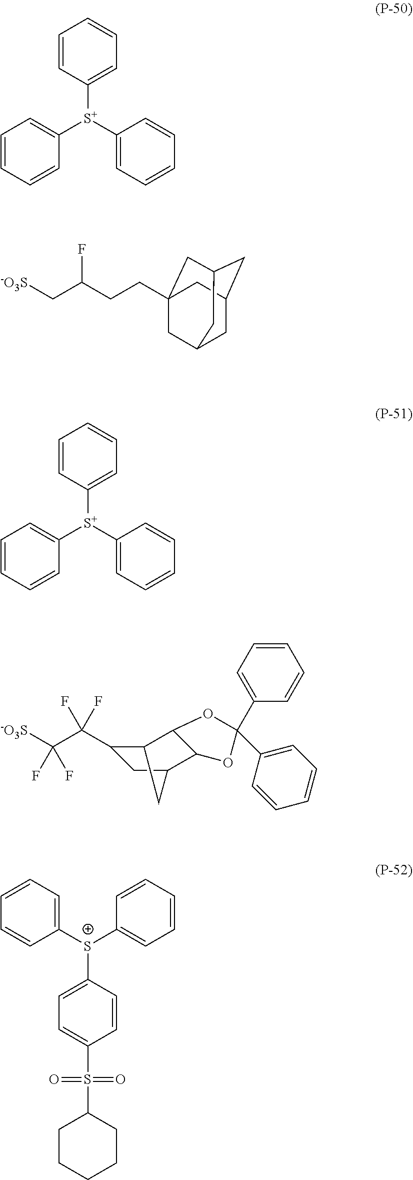

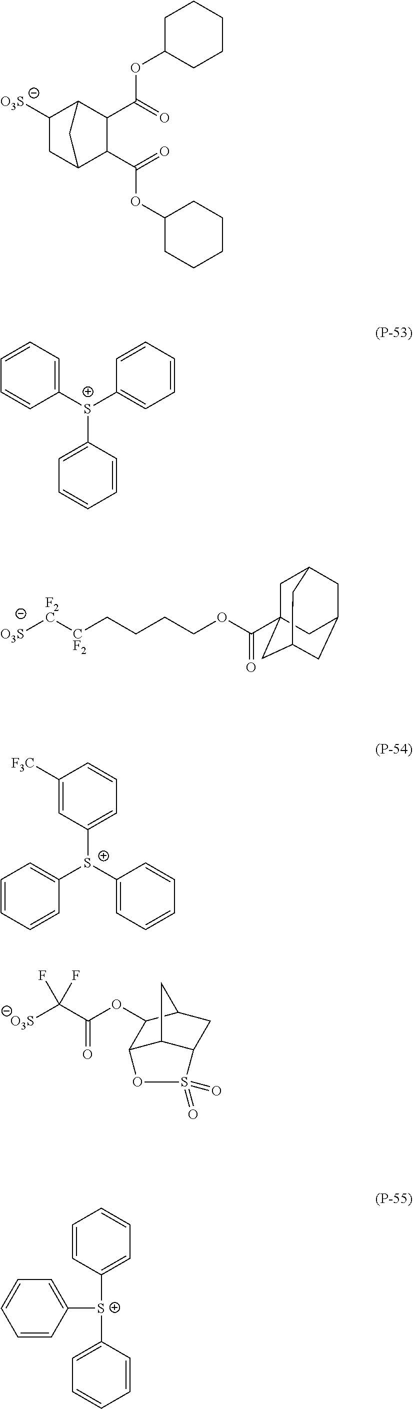

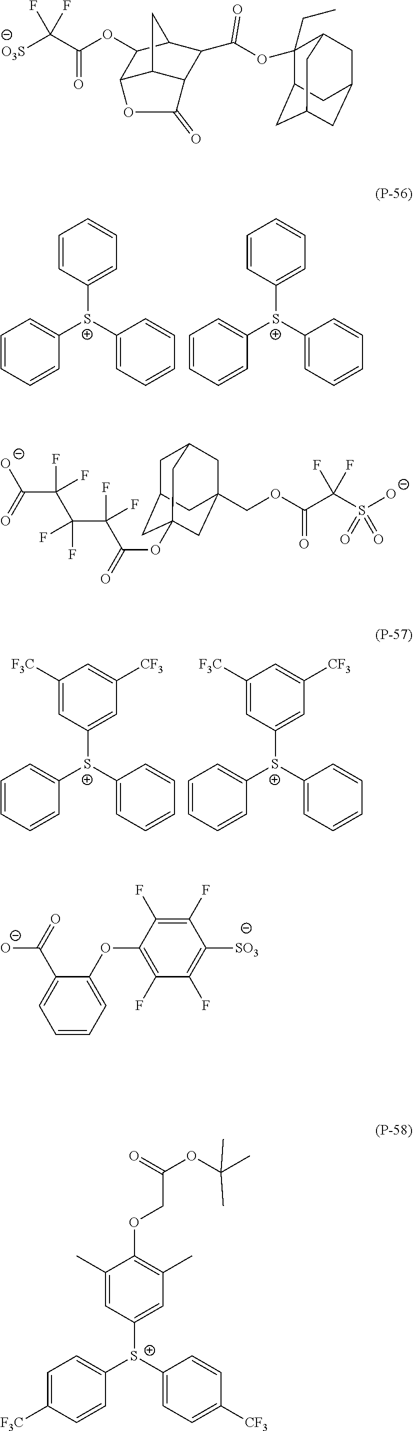

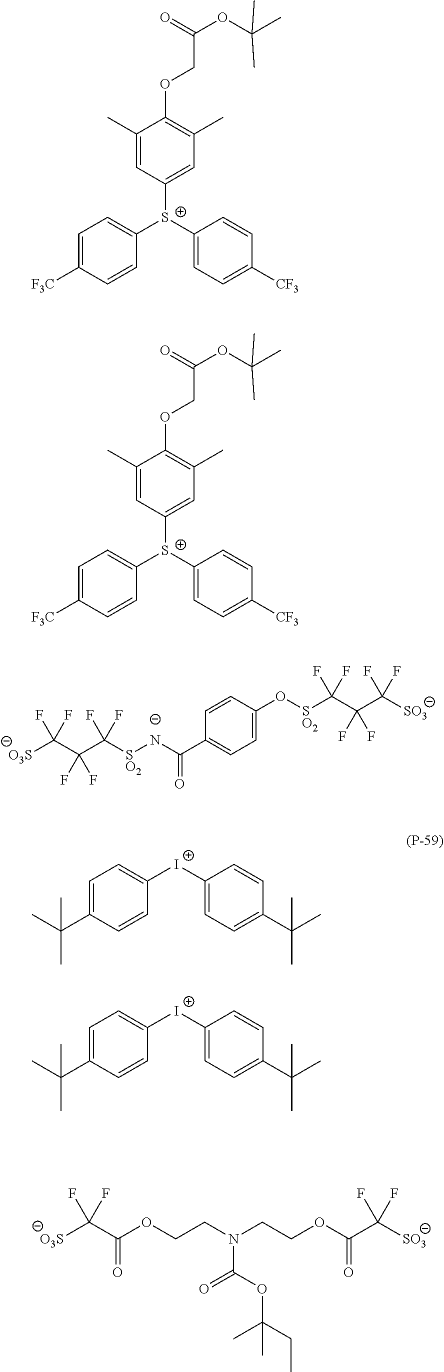

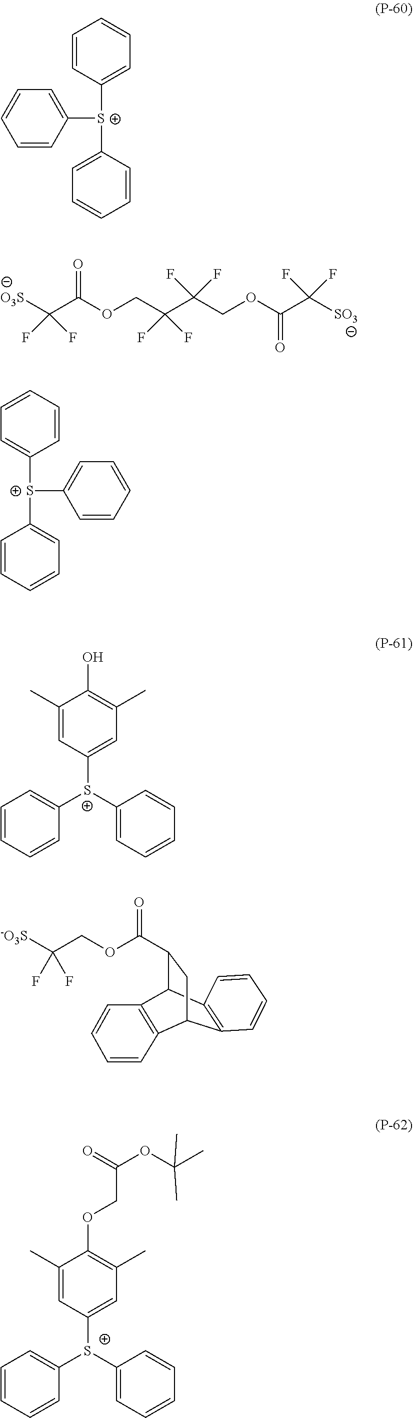

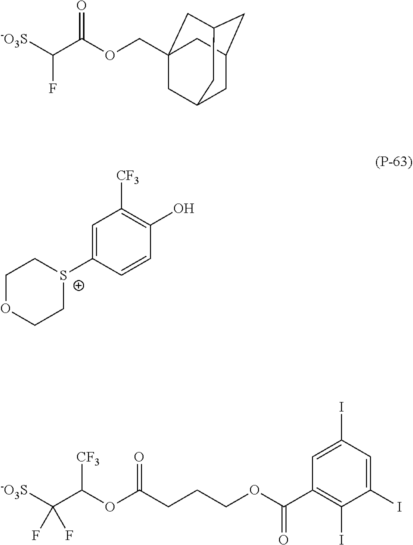

<Acid Diffusion Control Agent (Q)>

The structures of compounds Q-1 to Q-23 used as the acid diffusion control agent in Examples and Comparative Examples are shown below.

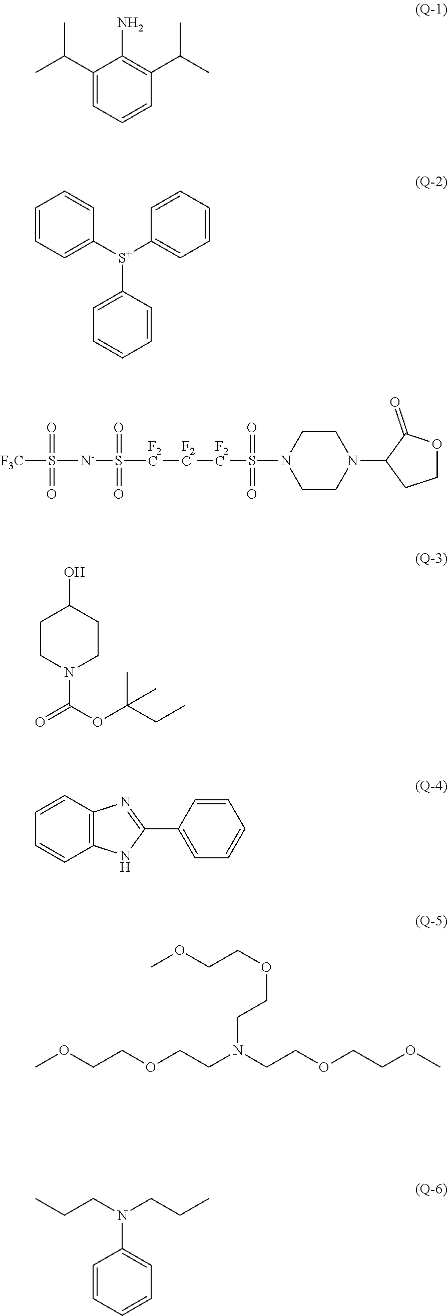

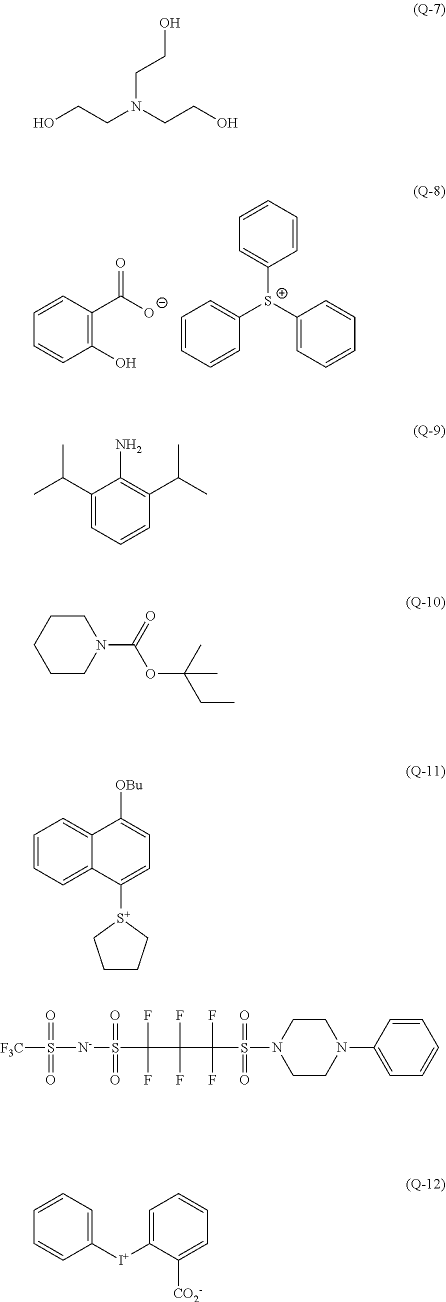

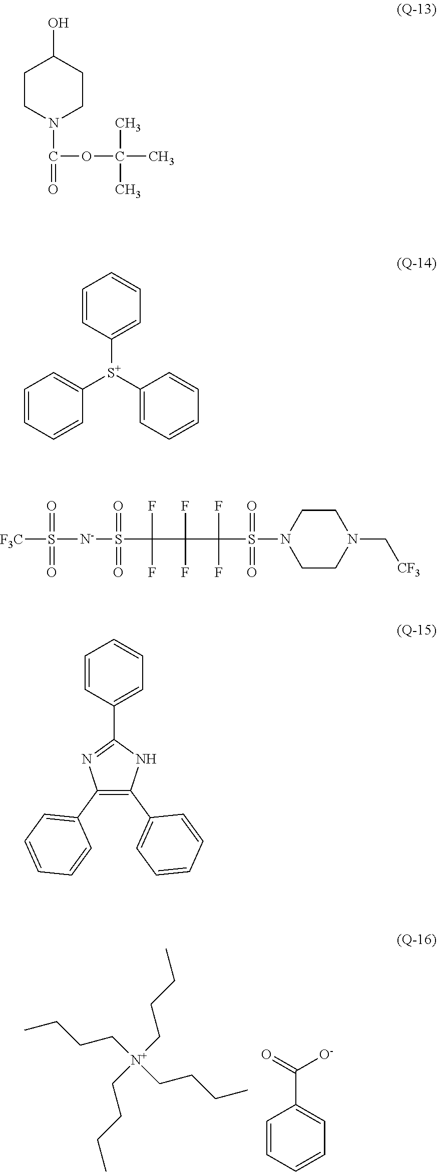 [SMILES: CC(C)(C)OC(=O)N1CCC(O)CC1 ; c1ccc([S+](c2ccccc2)c2ccccc2)cc1 ; O=S(=O)([N-]S(=O)(=O)C(F)(F)C(F)(F)C(F)(F)S(=O)(=O)N1CCN(CC(F)(F)F)CC1)C(F)(F)F ; c1ccc(-c2nc(-c3ccccc3)c(-c3ccccc3)[nH]2)cc1 ; CCCC[N+](CCCC)(CCCC)CCCC ; O=C([O-])c1ccccc1]

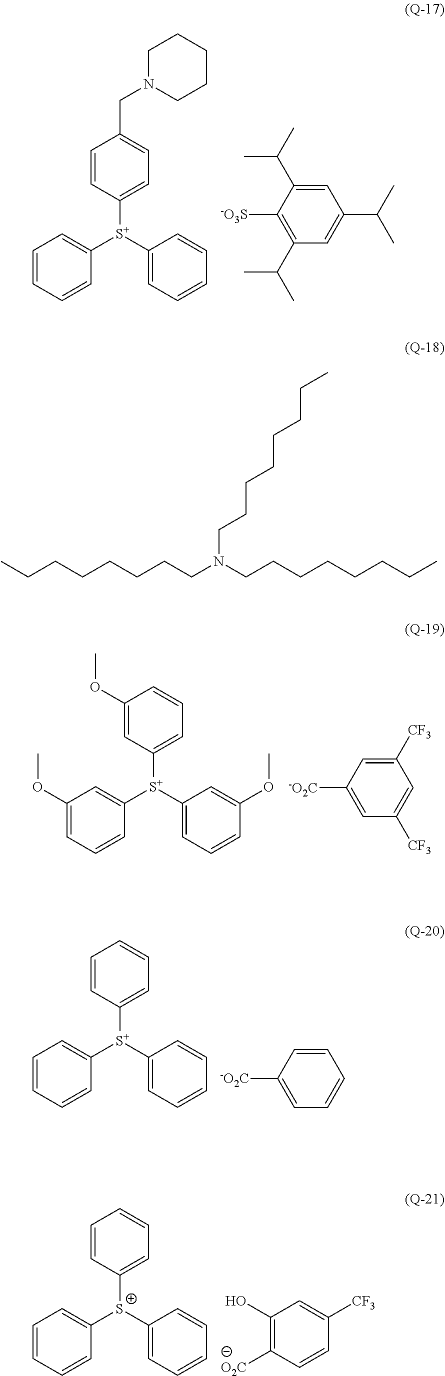

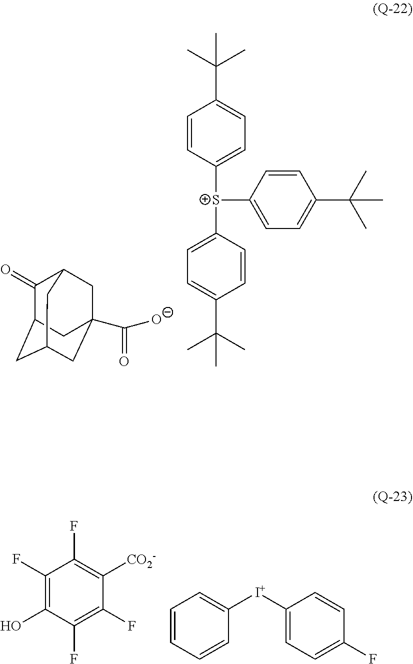

<Hydrophobic Resin (E)>

The structures of resins E-1 to E-17 used as the hydrophobic resin (E) in Examples and Comparative Examples are shown below. As the resins E-1 to E-17, those synthesized based on known techniques were used.

The compositional ratio (molar ratio; corresponding in order from the left), the weight-average molecular weight (Mw), and the dispersity (Mw/Mn) of each repeating unit in the hydrophobic resin (E) are shown in Table 8.

Furthermore, the weight-average molecular weight (Mw) and the dispersity (Mw/Mn) of the resins E-1 to E-17 were value expressed in terms of polystyrenes measured by the above-mentioned GPC method (carrier: tetrahydrofuran (THF)). In addition, the compositional ratio (ratio based on % by mole) of the repeating unit in the resin was measured by ¹³C-nuclear magnetic resonance (NMR).

TABLE 9

| Resin | Molar ratio of repeating unit | | | | Mw | Mw/Mn |
|---|---|---|---|---|---|---|
| E-1 | 60 | 40 | | | 10,000 | 1.4 |
| E-2 | 50 | 50 | | | 12,000 | 1.5 |
| E-3 | 50 | 50 | | | 9,000 | 1.5 |
| E-4 | 50 | 50 | | | 15,000 | 1.5 |
| E-5 | 50 | 50 | | | 10,000 | 1.5 |
| E-6 | 100 | | | | 23,000 | 1.7 |
| E-7 | 70 | 30 | | | 7,200 | 1.8 |
| E-8 | 50 | 50 | | | 15,000 | 1.7 |
| E-9 | 50 | 50 | | | 10,000 | 1.7 |
| E-10 | 50 | 50 | | | 7,700 | 1.8 |
| E-11 | 100 | | | | 13,000 | 1.4 |
| E-12 | 40 | 50 | 5 | 5 | 6,000 | 1.4 |
| E-13 | 50 | 50 | | | 10,000 | 1.7 |
| E-14 | 10 | 85 | 5 | | 11,000 | 1.4 |
| E-15 | 80 | 20 | | | 13,000 | 1.4 |
| E-16 | 40 | 30 | 30 | | 8,000 | 1.6 |
| E-17 | 80 | 20 | | | 14,000 | 1.7 |

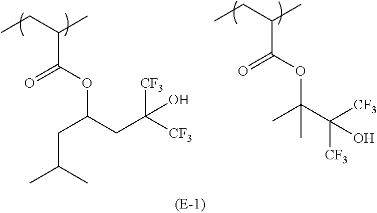

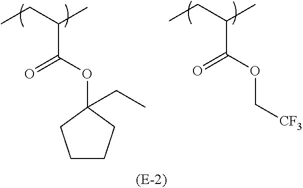

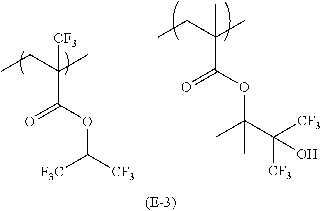

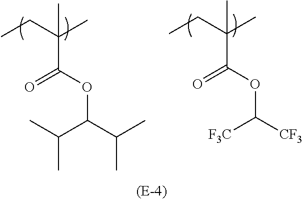

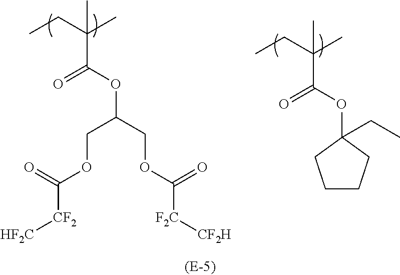

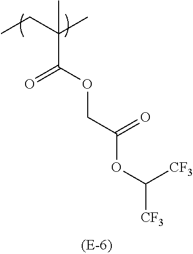

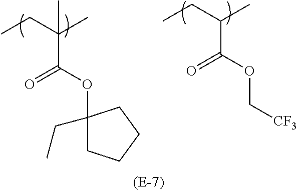

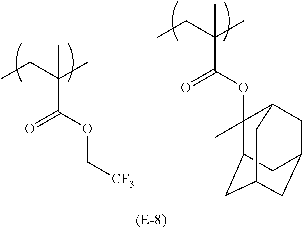

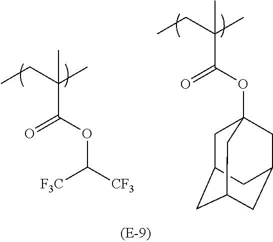

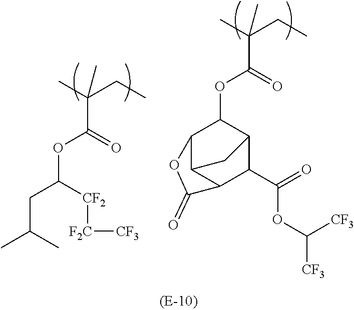

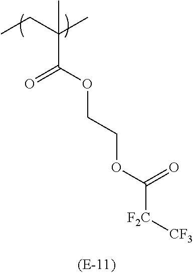

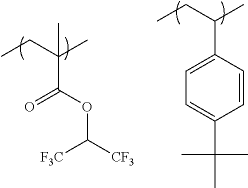

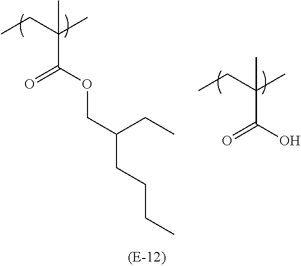

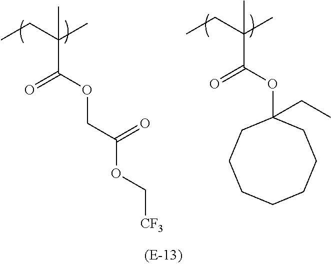

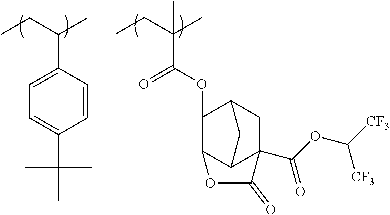

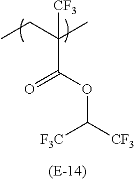

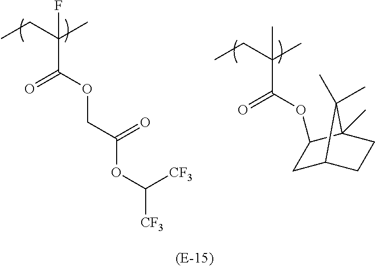

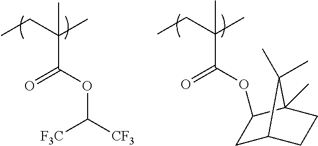

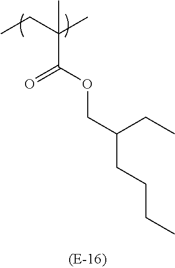

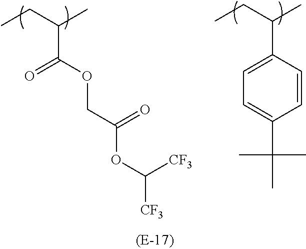

<Solvent>

Solvents used in Examples and Comparative Examples are shown below.

PGMEA: Propylene glycol monomethyl ether acetate

PGME: Propylene glycol monomethyl ether

EL: Ethyl lactate

BA: Butyl acetate

MAK: 2-Heptanone

MMP: Methyl 3-methoxypropionate

γ-BL: γ-Butyrolactone

CyHx: Cyclohexanone

<Surfactant (H)>

Surfactants used in Examples and Comparative Examples are shown below.

H-1: MEGAFACE R-41 (manufactured by DIC Corporation)

H-2: MEGAFACE F176 (manufactured by DIC Corporation)

H-3: MEGAFACE R08 (manufactured by DIC Corporation)

<Additive (X)>

Additives used in Examples and Comparative Examples are shown below.

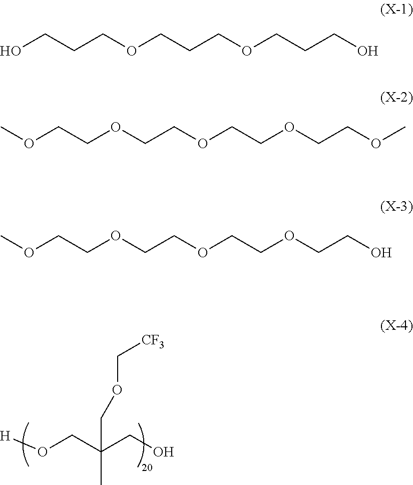

X-5: Polyvinyl Methyl Ether LUTONAL M40 (manufactured by BASF)

X-6: KF-53 (manufactured by Shin-Etsu Chemical Co., Ltd.)

X-7: Salicylic acid

### Examples and Comparative Examples

An operation which will be described later was carried out in a clean room of Class 6 (class notation of International Organization for Standardization ISO 14644-1) at a temperature of 22.1° C., a humidity of 60%, and an atmospheric pressure of 101.2 kPa.

First, a filter for filtering a raw material of a radiation-sensitive resin composition (hereinafter also referred to as a “resist composition”) was prepared according to the following procedure.

Specifically, a filter described in the “Second filter” column in Tables 12 and 13 was first prepared. Furthermore, the “Resin” column in Tables 12 and 13 shows second filters used for filtering the resins described in Tables 9 to 11, the “Low-molecular-weight component” column shows second filters used for filtering other components other than the resins and the solvents described in Tables 9 to 11, and the “Solvent” column shows second filters used for filtering the solvents described in Tables 9 to 11. For example, in the production method KJ-23, “0.5 um Nylon” and “0.3 um PE” were prepared as the filters for use in the filtration of the resins, “0.01 um Nylon” and “0.005 um PE” were prepared as the filters for use in the filtration of the low-molecular-weight components, and “0.01 um Nylon” and “0.005 um PE” were prepared as the filters for use in the filtration of the solvents.

Next, with regard to the production methods KJ-21 to KJ-28 and the production methods AJ-21 to AJ-28, the following operations were further carried out. First, a device similar to the device described in FIG. 1 was prepared, a 0.1 μm polytetrafluoroethylene (PTFE) filter was arranged in the position of the first filter 18A, and one kind of filter described in the “Second filter” column in Tables 12 and 13 was arranged in the position of the first filter 18B. Next, a valve arranged on the downstream side of the arranged second filter was closed, a second solution described in Tables 12 and 13 was supplied from a stirring tank to the second filter side using a pump, and the second filter was immersed in a predetermined solution. The conditions of the immersion time and the pressure are as shown in “Time” and “Pressure” in Tables 12 and 13, respectively. Furthermore, “1 h” in the “Time” column represents one hour. In addition, in a case where there is a description in the “Number of circulations” column in Tables 12 and 13, the second solution that had passed through the second filter was returned to the upstream side of the second filter as many times as the numerical value, and the treatment of passing the solution through the second filter was repeated. In addition, the linear velocity at which the second solution passed through the second filter was adjusted so as to be a value shown in the “Linear velocity” column described in Tables 12 and 13.

By the operations, the second filter for filtering the raw material was prepared. The treatment was carried out one by one for the second filter, and in a case of cleaning a plurality of second filters, the treatment was carried out for each second filter.

Moreover, the “Specific solvent” in the “Second solution” column in Tables 12 and 13 means the same solution as an organic solvent in a resist composition to which each production method is applied. For example, in Example K-21 of Table 14, the production method KJ-21 is adopted in a case where “Resist 1” (corresponding to a resist composition 1) is produced. Thus, as the second solution at that time, a mixed liquid (mass ratio: 50/50) of PGMEA and PGME used in the resist composition 1 was used.

Next, a filter for carrying out the filtration of the resist composition was prepared.

Specifically, filters described in the “First filter” column in Tables 12 and 13 were first prepared. For example, in the production method KJ-23, “0.2 um Nylon” and “0.15 um PE” were prepared as a filter for use in the filtration of the resins.

Next, the first filter was cleaned by any of the cleaning methods 1 to 3 which will be described later.

Furthermore, in the cleaning method 1, the first filter was cleaned in a production device for a radiation-sensitive resin composition, and a filtration treatment of the radiation-sensitive resin composition which will be described later was carried out as it is without taking out the first filter.

(Cleaning Method 1)

The first solution described in Tables 12 and 13 was put into the stirring tank 10 shown in FIG. 1.

Moreover, the “Specific solvent” in the “First solution” column in Tables 12 and 13 means the same solution as an organic solvent in a resist composition to which each production method is applied. For example, in Example K-4 of Table 14, the production method KJ-4 is adopted in a case where “Resist 1” (corresponding to a resist composition 1) is produced. Thus, as the first solution at that time, a mixed liquid (mass ratio: 50/50) of PGMEA and PGME used in the resist composition 1 was used.

In addition, “Resist produced” in the “First solution” column in Tables 12 and 13 means that the resist composition itself to which each production method is applied is used as the first solution. For example, in Example K-8 of Table 14, the production method KJ-8 is adopted in a case where “Resist 1” (corresponding to a resist composition 1) is produced. Thus, the resist composition 1 was used as the first solution at that time.

In a case where the first solution was other than the “Resist produced”, the first solution was put into the stirring tank 10 through a 0.1 μm PTFE filter.

In addition, in a case where the first solution was “Resist produced”, the resist composition was prepared in the stirring tank 10 according to the method for preparing the resist composition described in (Preparation of Resist Composition) which will be described later.

Next, a predetermined filter was arranged in the position of the first filter 18A in the first stage in the production device 100 of FIG. 1. For example, in the production method KJ-1, “0.2 um Nylon” and “0.15 um PE” were used, but “0.2 um Nylon” was arranged as the first filter in the first stage.

Thereafter, a valve on the secondary side of the first filter of the first stage was closed, the inside of a housing was filled with the first solution and held only for a time described in the “Time” column in Tables 12 and 13 (in which “h” represents a time), and the first filter was immersed in the first solution. At that time, in a case where there is a display of the “Pressure” column in Tables 12 and 13, the liquid feeding rate of a pump was adjusted so that the pressure inside a housing in which the first filter was arranged reached a pressure in Tables 12 and 13 while the feeding of liquid by the pump was continued.

In a case where the circulation filtration was not carried out, after the immersion treatment, all the valves in the production device 100 were opened, a pump was used to feed 15 kg of the first solution to the first filter of the first stage, and the first solution that had passed through the first filter was discharged (discarded) from the filling nozzle.

In addition, in a case of carrying out circulation filtration, after the immersion treatment, the first solution used for the immersion treatment was discharged, and using a new first solution, the first solution which had passed through the first filter arranged in the position of the first filter 18A was returned between the stirring tank and the first filter 18A, and circulation filtration for circulating the first solution was carried out. At that time, the first solution was circulated until the first solution in an amount of 15 kg×the number of times in the table flowed through the first filter. Thereafter, the first solution was discharged from the filling nozzle.

In addition, the linear velocity at which the first solution passed through the first filter was adjusted so as to be a value shown in the “Linear velocity” column described in Tables 12 and 13.

Furthermore, in a case where the first solution was other than the “Resist produced”, the residual liquid in the stirring tank was discarded after the treatment was completed.

In addition, in a case where the first solution was a “Resist produced”, the treatment was carried out using a part of the resist composition prepared in the stirring tank according to the procedure described in (Preparation of Resist Composition) which will be described later.

The procedure is described above only for the first filter of the first stage, but in a case where a plurality of first filters were used, the same cleaning treatment as above was carried out for the first filters of the second stage and subsequent stages. For example, in the production method KJ-1, “0.2 um Nylon” and “0.15 um PE” were used, but for “0.2 um Nylon”, an immersion treatment for an immersion time of one hours using PGMEA was carried out; and for “0.15 um PE”, “0.15 um PE” was arranged in the position of the first filter 18B in the second stage, an immersion treatment for an immersion time of one hours using PGMEA was carried out according to the same procedure as above.

(Cleaning Method 2)

The first solution described in Tables 12 and 13 was put into the stirring tank 10 described in the production device 100 of FIG. 1.

Furthermore, the first solution was put into the stirring tank 10 through a 0.1 μm PTFE filter.

Next, a 0.1 μm PTFE filter was arranged in the position of the first filter 18A in FIG. 1, and one predetermined filter described in the first filter column of Tables 12 and 13 was arranged in the position of the first filter 18B.

Thereafter, a valve on the secondary side of the first filter was closed, the inside of the housing was filled with the first solution and held only for the time described in the “Time” column in Tables 12 and 13 (in which “h” represents a time), and the first filter was immersed in the first solution. At that time, in a case where there is a display of the “Pressure” column in Tables 12 and 13, the liquid feeding rate of a pump was adjusted so that the pressure inside a housing in which the first filter was arranged reached a pressure in Tables 12 and 13 while the feeding of liquid by the pump was continued.

In a case where the circulation filtration was not carried out, after the immersion treatment, all the valves in the production device 100 were opened, a pump was used to feed 15 kg of the first solution to the first filter, and the first solution which had passed through the first filter was discharged (discarded) from the filling nozzle.

In addition, in a case of carrying out circulation filtration, after the immersion treatment, the first solution used for the immersion treatment was discharged, and using a new first solution, the first solution which had passed through the first filter was returned between the stirring tank and the PTFE filter, and circulation filtration for circulating the first solution was carried out. At that time, the first solution was circulated until the first solution in an amount of 15 kg×the number of times in the table flowed through the first filter. Thereafter, the first solution was discharged from the filling nozzle.

In addition, the linear velocity at which the first solution passed through the first filter was adjusted so as to be a value shown in the “Linear velocity” column described in Tables 12 and 13.

After cleaning, the first filter was taken out from the housing, transferred to a container coated with a fluororesin, and stored.

Furthermore, the treatment was carried out for each of the first filters used in each production method. For example, in the production method KJ-4, the treatment was carried out using each of “0.2 um Nylon” and “0.15 um PE” to obtain two cleaned first filters.

(Cleaning Method 3)

The first solution described in the “First solution” column of Tables 12 and 13 was put into a container whose inside was coated with a fluororesin through a 0.1 μm PTFE filter.

Next, a first filter described in the “First filter” column of Tables 12 and 13 was arranged so as to be immersed in the first solution, and immersed for a time described in the “Time” column in the tables (in which “h” represents a time.)

After the immersion, the first filter was transferred to a container prepared separately, whose inside was coated with a fluororesin, and stored.

Furthermore, the treatment was carried out for each of the first filters used in each production method. For example, in the production method KJ-6, the treatment was carried out using each of “0.2 um Nylon” and “0.15 um PE” to obtain two cleaned first filters.

(Preparation of Resist Composition)

Each component was put into a stirring tank (capacity of 200 L) in the same production device for a resist composition as in FIG. 1 and arranged in a clean room so as to have a composition of each of the resist compositions (resists 1 to 64) described in Tables 9 to 11.

Furthermore, in a case where the above (Cleaning Method 1) was carried out, a production device in which the first filter that had been subjected to a cleaning treatment was arranged was used. In addition, in a case where the “Resist produced” was used as the first solution in (Cleaning Method 1) as described above, the resist composition was already formed in the stirring tank by this method.

At that time, with regard to the addition of the resin, a solution obtained by dissolving the resin in a solvent used for the preparation of each resist composition was prepared, passed through a second filter described in the “Resin” column of the “Second filter” column in Tables 12 and 13, and put into a stirring tank. Furthermore, the concentration of solid contents of the resin in the solution was 50% by mass in a case of the resin of the resist compositions (resists 1 to 15) in Table 9, 10% by mass in a case of the resin of the resist compositions (resists 16 to 31) in Table 10, and 5% by mass in a case of the resin of the resist compositions (resists 32 to 64) in Table 11.

In addition, with regard to the addition of the solvent, the liquid was passed through the second filter described in the “Solvent” column of the “Second filter” column of Tables 12 and 13, and put into a stirring tank.

Furthermore, with regard to components (for example, a photoacid generator) other than the resin and the solvent, a solution obtained by dissolving such other components in a solvent used for the preparation of each resist composition was prepared, passed through a second filter described in the “Low-molecular-weight component” column of the “Second filter” column in Tables 12 and 13, and put into a stirring tank. Incidentally, the concentration of solid contents of such other components in the solution was 20% by mass in a case of the resist compositions (resists 1 to 15) in Table 9, 3% by mass in a case of the resist compositions (resists 16 to 31) in Table 10, and 3% by mass in a case of the resist compositions (resists 32 to 64) in Table 11.

A void ratio (proportion occupied by a space (void)) inside the stirring tank after putting each component was 15% by volume. In other words, an occupancy of the mixture in the stirring tank was 85% by volume.

Next, as shown in FIG. 1, the stirring shaft to which the stirring blade was attached, arranged in the stirring tank, was rotated to stir and mix each component.

Next, first filters described in the “First filter” column of Tables 12 and 13 were arranged in the positions of the first filter 18A, the first filter 18B, and the like (positions on the circulation pipe on the downstream side of the stirring tank) as shown in FIG. 1. At that time, the first filters were arranged from the upstream side, based on the order described from the left side to the right side in the “First filter” column of Tables 12 and 13, as described later. For example, in the production method KJ-19, the filters were arranged from the upstream side in the order of “0.3 um PE”, “0.2 um Nylon”, and “0.15 um PE”.

Furthermore, in a case where (Cleaning Method 1) was carried out as described above, the first filter which had been cleaned was already arranged at a predetermined position of the production device.

Next, a part of the resist composition prepared in the stirring tank was supplied to the first filter of the first stage, and the solution remaining in the first filter of the first stage was extruded and discharged from a discharge port arranged on the secondary side of the first filter in the first stage in the production device.

The same treatment as above was also applied to the first filters of the second stage and the subsequent stages arranged in the production device, and residues in each of the first filters were extruded and removed.

Thereafter, the resist composition in the stirring tank was sent to a circulation pipe connected to the stirring tank by a liquid feeding pump. Furthermore, at that time, filtration by a filter was carried out by circulating the resist composition through the circulation pipe. The circulation was carried out (the step 2 was carried out) until the liquid amount of upon the passage of the mixture through the filter reached four times the total amount of liquid in the pipe.

After the circulation filtration was completed, the filling valve was opened and the resist composition was filled in the container. At the time of filling, the resist composition was filled in five containers in small portions.

In Tables 9 to 11, “TMAH (2.38%)” represents an aqueous solution having a content of tetramethylammonium hydroxide of 2.38% by mass.

“TMAH (1.00%)” represents an aqueous solution having a tetramethylammonium hydroxide content of 1.00% by mass.

“TMAH (3.00%)” means an aqueous solution having a tetramethylammonium hydroxide content of 3.00% by mass.

“nBA” represents butyl acetate.

In Tables 9 to 11, the “Content” column of each component indicates a content (% by mass) of each component with respect to the total solid content in the resist composition.

In Tables 9 to 11, the numerical value in the “Solvent” column indicates a content mass ratio of each component.

In Tables 9 to 11, the “Solid content” column indicates a total concentration (% by mass) of solid contents in the resist composition.

In Tables 12 and 13, in the notation of “XumY”, X represents a pore size (μm) and Y represents a filter material. “Nylon” represents nylon 6 and “PE” represents polyethylene. For example, “0.02 um Nylon” means a filter made of nylon 6 having a pore size of 0.02 μm.

In Tables 12 and 13, in the “First filter” column and the “Second filter” column, the notation of “A+B” means that two filters, a filter described as A and a filter described as B, are used. In a case of using the filters, the solution is first passed through the filter of “A” described on the left side. That is, the filter of “A” is arranged on the upstream side. For example, in the “First filter” column of the production method KJ-1 in Table 12, a description of “0.2 um Nylon+0.15 um PE” means that a first filter made of nylon 6 having a pore size of 0.2 μm and a first filter made of polyethylene having a pore size of 0.15 μm are used. In addition, it means that in a case of the passage of a solution (for example, a first solution and a resist composition), the first filter made of nylon 6 having a pore size of 0.2 μm is passed first, and then first filter made of polyethylene having a pore size of 0.15 μm is passed.

In Tables 12 and 13, in the “First filter” column and the “Second filter” column, the notation of “A+B+C” means that three filters, a filter described as A, a filter described as B, and a filter described as C are used. In a case of using the filters, the solution is passed in the order of the filter described as “A”, the filter described as “B”, and the filter described as “C”.

In Tables 12 and 13, the “Direction” column indicates “Downward” in a case where the solution passing through the filter is passed from above to below in the vertical direction, and indicates “Upward” in a case where the solution is passed from below to above in the vertical direction.

TABLE 9

| | | | | | Acid | | | | | | | | | | | |
|---|---|---|---|---|---|---|---|---|---|---|---|---|---|---|---|---|
| Resist | | | Photoacid | | diffusion | | | | | | | | Condition for formation | | | |
| com- | | | generator | | control agent | | Additive 1 | | Additive 2 | | | Solid | Film | | | |
| posi- | Resin | | | Con- | | Con- | | Con- | | Con- | | con- | thick- | | | Devel- |
| tion | Type | Content | Type | tent | Type | tent | Type | tent | Type | tent | Solvent | tent | ness | PB | PEB | oper |
| Resist | A-1 | 83.71% | P-1 | 1.20% | Q-1 | 0.03% | X-1 | 15% | H-1 | 0.06% | PGMEA/ | 40% | 11.0 μm | 130° C./ | 120° C./ | TMAH |
| 1 | | | | | | | | | | | PGME | | | 60 sec | 60 sec | (2.38%) |
| | | | | | | | | | | | (50/50) | | | | | |
| Resist | A-2 | 90.40% | P-2 | 2.50% | Q-2 | 0.10% | X-2 | 6.95% | X-4 | 0.05% | PGMEA | 33% | 11.0 μm | 130° C./ | 120° C./ | TMAH |
| 2 | | | | | | | | | | | | | | 60 sec | 60 sec | (2.38%) |
| Resist | A-3 | 97.15% | P-3 | 2.70% | Q-3 | 0.10% | — | — | H-1 | 0.05% | PGMEA/ | 33% | 11.0 μm | 130° C./ | 120° C./ | TMAH |
| 3 | | | | | | | | | | | PGME | | | 60 sec | 60 sec | (2.38%) |
| | | | | | | | | | | | (70/30) | | | | | |
| Resist | A-4 | 87.65% | P-4 | 3.10% | Q-4 | 0.20% | X-3 | 9% | H-1 | 0.05% | PGMEA/ | 31% | 11.0 μm | 130° C./ | 120° C./ | TMAH |
| 4 | | | | | | | | | | | EL | | | 60 sec | 60 sec | (2.38%) |
| | | | | | | | | | | | (80/20) | | | | | |
| Resist | A-5 | 95.1% | P-5 | 4.5% | Q-4 | 0.3% | — | — | X-4 | 0.1% | PGMEA/ | 35% | 7.5 μm | 110° C./ | 110° C./ | TMAH |
| 5 | | | | | | | | | | | BA | | | 60 sec | 60 sec | (2.38%) |
| | | | | | | | | | | | (50/50) | | | | | |
| Resist | A-6 | 97% | P-1 | 2.90% | Q-2 | 0.10% | — | — | — | — | MAK/ | 28% | 9.0 μm | 130° C./ | 120° C./ | TMAH |
| 6 | | | | | | | | | | | MMP | | | 60 sec | 60 sec | (2.38%) |
| | | | | | | | | | | | (60/40) | | | | | |
| Resist | A-7 | 88.67% | P-6 | 1.20% | Q-3 | 0.04% | X-2 | 10% | X-4 | 0.09% | PGMEA/ | 39% | 11.0 μm | 130° C./ | 120° C./ | TMAH |
| 7 | | | | | | | | | | | PGME | | | 60 sec | 60 sec | (2.38%) |
| | | | | | | | | | | | (50/50) | | | | | |
| Resist | A-8 | 95.8% | P-7/ | 1.0%/ | Q-5 | 0.10% | X-5 | 2.00% | X-6 | 0.10% | PGME/ | 35% | 8.0 μm | 150° C./ | 110° C./ | TMAH |
| 8 | | | P-8 | 1.0% | | | | | | | EL | | | 60 sec | 60 sec | (2.38%) |
| | | | | | | | | | | | (70/30) | | | | | |
| Resist | A-9 | 98.55% | P-9 | 1.20% | Q-6 | 0.20% | — | — | X-4 | 0.05% | PGMEA/ | 28% | 5.0 μm | 130° C./ | 120° C./ | TMAH |
| 9 | | | | | | | | | | | PGME | | | 60 sec | 60 sec | (2.38%) |
| | | | | | | | | | | | (80/20) | | | | | |
| Resist | A-10 | 98.55% | P-11 | 0.6%/ | Q-6 | 0.20% | — | — | H-1 | 0.05% | PGMEA/ | 32% | 10.0 μm | 130° C./ | 120° C./ | TMAH |
| 10 | | | P-11 | 0.6% | | | | | | | PGME | | | 60 sec | 60 sec | (2.38%) |
| | | | | | | | | | | | (80/20) | | | | | |
| Resist | A-11 | 98.60% | P-12/ | 0.6%/ | Q-6 | 0.20% | — | — | — | — | PGMEA/ | 27% | 5.0 μm | 130° C./ | 120° C./ | TMAH |
| 11 | | | P-13 | 0.6% | | | | | | | PGME | | | 60 sec | 60 sec | (2.38%) |
| | | | | | | | | | | | (80/20) | | | | | |
| Resist | A-12 | 97.80% | P-14 | 1.95% | Q-7 | 0.07% | X-7 | 0.09% | H-1 | 0.09% | PGMEA/ | 28% | 5.0 μm | 140° C./ | 110° C./ | TMAH |
| 12 | | | | | | | | | | | PGME | | | 60 sec | 60 sec | (2.38%) |
| | | | | | | | | | | | (20/80) | | | | | |
| Resist | A-13/ | 49.275%/ | P-12/ | 0.6%/ | Q-2/ | 0.1%/ | — | — | X-4 | 0.05% | PGMEA/ | 32% | 10.0 μm | 130° C./ | 120° C./ | TMAH |
| 13 | A-14 | 49.275% | P-15 | 0.6% | Q-4 | 0.1% | | | | | PGME | | | 60 sec | 60 sec | (2.38%) |
| | | | | | | | | | | | (80/20) | | | | | |
| Resist | A-15/ | 49.275%/ | P-12/ | 0.6%/ | Q-4 | 0.20% | — | — | — | — | PGMEA/ | 32% | 10.0 μm | 130° C./ | 120° C./ | TMAH |
| 14 | A-16 | 49.275% | P-16 | 0.6% | | | | | | | PGME | | | 60 sec | 60 sec | (2.38%) |
| | | | | | | | | | | | (80/20) | | | | | |
| Resist | A-17/ | 49.275%/ | P-2 | 1.20% | Q-6/ | 0.1%/ | — | — | H-1 | 0.05% | PGMEA/ | 32% | 10.0 μm | 130° C./ | 110° C./ | TMAH |
| 15 | A-18 | 49.275% | | | Q-8 | 0.1% | | | | | PGME | | | 60 sec | 60 sec | (2.38%) |
| | | | | | | | | | | | (80/20) | | | | | |

TABLE 10

| | | | | | Acid | | | | | | | | | | | |
|---|---|---|---|---|---|---|---|---|---|---|---|---|---|---|---|---|
| Resist | | | Photoacid | | diffusion | | | | | | | | Condition for formation | | | |
| com- | | | generator | | control agent | | Additive 1 | | Additive 2 | | | Solid | Film | | | |
| posi- | Resin | | | Con- | | Con- | | Con- | | Con- | | con- | thick- | | | Devel- |
| tion | Type | Content | Type | tent | Type | tent | Type | tent | Type | tent | Solvent | tent | ness | PB | PEB | oper |
| Resist | A-19 | 89.20% | P-17/ | 3.6%/ | Q-9 | 0.30% | — | — | E-1 | 0.80% | PGMEA/ | 3% | 90 nm | 100° C./ | 100° C./ | TMAH |
| 16 | | | P-18 | 6.1% | | | | | | | PGME | | | 60 sec | 60 sec | (2.38%) |
| | | | | | | | | | | | (80/20) | | | | | |
| Resist | A-20 | 90.70% | P-19 | 7.90% | Q-10 | 0.40% | — | — | E-2 | 1.00% | PGMEA/ | 3% | 90 nm | 100° C./ | 95° C./ | TMAH |
| 17 | | | | | | | | | | | PGME | | | 60 sec | 60 sec | (2.38%) |
| | | | | | | | | | | | (90/10) | | | | | |
| Resist | A-21 | 88.20% | P-20/ | 5.2%/ | Q-10 | 0.50% | — | — | E-3 | 0.90% | PGMEA/ | 3% | 90 nm | 90° C./ | 90° C./ | TMAH |
| 18 | | | P-21 | 5.2% | | | | | | | PGME/ | | | 60 sec | 60 sec | (2.38%) |
| | | | | | | | | | | | γ-BL | | | | | |
| | | | | | | | | | | | (70/20/10) | | | | | |
| Resist | A-22 | 87.50% | P-22 | 8.20% | Q-4/ | 0.3%/ | — | — | E-4 | 1.50% | PGMEA/ | 3% | 90 nm | 110° C./ | 95° C./ | nBA |
| 19 | | | | | Q-2 | 2.5% | | | | | CyHx | | | 60 sec | 60 sec | |
| | | | | | | | | | | | (60/40) | | | | | |
| Resist | A-23 | 82.88% | P-23 | 11.30% | Q-11 | 5.10% | — | — | E-5 | 0.72% | PGMEA/ | | 90 nm | 100° C./ | 90° C./ | nBA |
| 20 | | | | | | | | | | | γ-BL | | | 60 sec | 60 sec | |
| | | | | | | | | | | | (80/20) | | | | | |
| Resist | A-24 | 86.90% | P-24 | 10.20% | Q-4/ | 0.3%/ | — | — | E-6 | 0.60% | PGMEA/ | 3% | 90 nm | 90° C./ | 100° C./ | nBA |
| 21 | | | | | Q-8 | 2.0% | | | | | PGME | | | 60 sec | 60 sec | |
| | | | | | | | | | | | (80/20) | | | | | |
| Resist | A-25 | 85% | P-25/ | 6%/6.7% | Q-8 | 2% | — | — | E-7 | 0.30% | PGMEA/ | 3% | 90 nm | 100° C./ | 95° C./ | TMAH |
| 22 | | | P-26 | | | | | | | | CyHx/ | | | 60 sec | 60 sec | (2.38%) |
| | | | | | | | | | | | γ-BL | | | | | |
| | | | | | | | | | | | (69/30/1) | | | | | |
| Resist | A-26 | 89% | P-27 | 8% | Q-8 | 2% | — | — | E-8 | 1.0% | PGMEA/ | 3% | 90 nm | 110° C./ | 90° C./ | TMAH |
| 23 | | | | | | | | | | | CyHx/ | | | 60 sec | 60 sec | (2.38%) |
| | | | | | | | | | | | γ-BL | | | | | |
| | | | | | | | | | | | (45/30/25) | | | | | |
| Resist | A-27 | 85.60% | P-28/ | 6.1%/ | Q-12 | 2.40% | — | — | E-9 | 1.70% | PGMEA/ | 3% | 90 nm | 110° C./ | 90° C./ | TMAH |
| 24 | | | P-29 | 4.2% | | | | | | | PGME/ | | | 60 sec | 60 sec | (2.38%) |
| | | | | | | | | | | | MAK/ | | | | | |
| | | | | | | | | | | | γ-BL | | | | | |
| | | | | | | | | | | | (85/6.5/ | | | | | |
| | | | | | | | | | | | 6.5/1) | | | | | |
| Resist | A-28 | 83.50% | P-30 | 12.50% | Q-13 | 1% | — | — | E-10 | 3% | PGMEA/ | 3% | 90 nm | 100° C./ | 90° C./ | TMAH |
| 25 | | | | | | | | | | | γ-BL | | | 60 sec | 60 sec | (2.38%) |
| | | | | | | | | | | | (80/20) | | | | | |
| Resist | A-29 | 82.40% | P-31/ | 5.2%/ | Q-3/ | 0.2%/ | — | — | E-11 | 0.50% | PGMEA/ | 4% | 120 nm | 90° C./ | 90° C./ | TMAH |
| 26 | | | P-24 | 7.7% | Q-2 | 4.0% | | | | | γ-BL | | | 60 sec | 60 sec | (2.38%) |
| | | | | | | | | | | | (95/5) | | | | | |
| Resist | A-30 | 87.40% | P-32 | 11.30% | Q-3 | 0.70% | — | — | E-12 | 0.60% | PGMEA/ | 4% | 120 nm | 110° C./ | 100° C./ | TMAH |
| 27 | | | | | | | | | | | CyHx/ | | | 60 sec | 60 sec | (2.38%) |
| | | | | | | | | | | | γ-BL | | | | | |
| | | | | | | | | | | | (69/30/1) | | | | | |
| Resist | A-31 | 87.40% | P-33/ | 2.8%/ | Q-14 | 3.20% | — | — | E-13 | 0.30% | PGMEA/ | 6% | 170 nm | 100° C./ | 90° C./ | TMAH |
| 28 | | | P-34 | 6.3% | | | | | | | PGME/ | | | 60 sec | 60 sec | (2.38%) |
| | | | | | | | | | | | γ-BL | | | | | |
| | | | | | | | | | | | (80/15/5) | | | | | |
| Resist | A-32 | 92.60% | P-1 | 6.50% | Q-4 | 0.40% | — | — | E-14 | 0.50% | PGMEA/ | 6% | 170 nm | 90° C./ | 90° C./ | TMAH |
| 29 | | | | | | | | | | | PGME | | | 60 sec | 60 sec | (2.38%) |
| | | | | | | | | | | | (80/20) | | | | | |
| Resist | A-33 | 87.85% | P-35 | 9.80% | Q-2 | 1.90% | — | — | E-15 | 0.45% | PGMEA/ | 4% | 130 nm | 100° C./ | 90° C./ | nBA |
| 30 | | | | | | | | | | | PGME | | | 60 sec | 60 sec | |
| | | | | | | | | | | | (90/10) | | | | | |
| Resist | A-34 | 89.30% | P-36 | 9.10% | Q-6 | 0.60% | — | — | E-16 | 1.00% | PGMEA/ | 6% | 170 nm | 100° C./ | 95° C./ | nBA |
| 31 | | | | | | | | | | | PGME | | | 60 sec | 60 sec | |
| | | | | | | | | | | | (90/10) | | | | | |

TABLE 11(1)

| | | | | | Acid | | | | | | | | | | | |
|---|---|---|---|---|---|---|---|---|---|---|---|---|---|---|---|---|
| Resist | | | Photoacid | | diffusion | | | | | | | | Condition for formation | | | |
| com- | | | generator | | control agent | | Additive 1 | | Additive 2 | | | Solid | Film | | | |
| posi- | Resin | | | Con- | | Con- | | Con- | | Con- | | con- | thick- | | | Devel- |
| tion | Type | Content | Type | tent | Type | tent | Type | tent | Type | tent | Solvent | tent | ness | PB | PEB | oper |
| Resist | A-35 | 74.00% | P-37/ | 7.5%/ | Q-4 | 1.00% | — | — | — | — | PGMEA/ | 1.4% | 50 nm | 100° C./ | I20° C./ | TMAH |
| 32 | | | P-38 | 7.5% | | | | | | | PGME/EL | | | 60 sec | 60 sec | (2.38%) |
| | | | | | | | | | | | (30/20/50) | | | | | |
| Resist | A-35 | 74.00% | P-37/ | 7.5%/ | Q-4 | 1.00% | — | — | — | — | PGMEA/ | 1.4% | 50 nm | 100° C./ | 120° C./ | nBA |
| 33 | | | P-38 | 7.5% | | | | | | | PGME/EL | | | 60 sec | 60 sec | |
| | | | | | | | | | | | (30/20/50) | | | | | |
| Resist | A-36 | 79.20% | P-39 | 20.0% | Q-15 | 0.80% | — | — | — | — | PGMEA/ | 1.6% | 55 nm | I20° C./ | 90° C./ | TMAH |
| 34 | | | | | | | | | | | EL | | | 60 sec | 60 sec | (2.38%) |
| | | | | | | | | | | | 60/40 | | | | | |
| Resist | A-37 | 71.92% | P-40 | 26.0% | Q-16 | 2.08% | — | — | — | — | PGMEA/ | 1.3% | 50 nm | 90° C./ | 105° C./ | TMAH |
| 35 | | | | | | | | | | | PGME | | | 60 sec | 60 sec | (1.00%) |
| | | | | | | | | | | | (90/10) | | | | | |
| Resist | A-38 | 80.00% | P-41/ | 8%/8% | Q-2 | 4.00% | — | — | — | — | PGMEA | 1.6% | 55 nm | 100° C./ | 100° C./ | TMAH |
| 36 | | | P-42 | | | | | | | | | | | 60 sec | 60 sec | (2.38%) |
| Resist | A-39 | 74.70% | P-43 | 20.0% | Q-17 | 5.00% | — | — | H-2 | 0.30% | EL | 1.4% | 50 nm | 100° C./ | 120° C./ | TMAH |
| 37 | | | | | | | | | | | | | | 60 sec | 60 sec | (3.00%) |
| Resist | A-40 | 80.70% | P-44/ | 13%/3% | Q-15 | 1.30% | — | — | E-17 | 2.00% | PGMEA | 1.4% | 55 nm | 120° C./ | 120° C./ | TMAH |
| 38 | | | P-45 | | | | | | | | | | | 60 sec | 60 sec | (2.38%) |
| Resist | A-41 | 78.40% | P-46 | 20.0% | Q-18 | 1.60% | — | — | — | — | PGMEA/ | 1.6% | 55 nm | 100° C./ | 90° C./ | TMAH |
| 39 | | | | | | | | | | | EL/γ-BL | | | 60 sec | 60 sec | (2.38%) |
| | | | | | | | | | | | (30/90/10) | | | | | |
| Resist | A-42 | 72.40% | P-47 | 20.0% | Q-17 | 6.0% | — | — | — | — | PGMEA/ | 2.1% | 65 nm | 100° C./ | 100° C./ | TMAH |
| 40 | | | | | | | | | | | PGME | | | 60 sec | 60 sec | (2.38%) |
| | | | | | | | | | | | (90/10) | | | | | |
| Resist | A-43 | 78.40% | P-48 | 20.0% | Q-15 | 1.60% | — | — | — | — | PGMEA/ | 2.1% | 60 nm | 100° C./ | 100° C./ | TMAH |
| 41 | | | | | | | | | | | PGME | | | 60 sec | 60 sec | (2.38%) |
| | | | | | | | | | | | (60/40) | | | | | |
| Resist | A-44 | 69.50% | P-37/ | 12%/9% | Q-2 | 9.00% | — | — | H-3 | 0.50% | PGMEA/ | 1.4% | 50 nm | 100° C./ | 110° C./ | TMAH |
| 42 | | | P-49 | | | | | | | | EL | | | 60 sec | 60 sec | (2.38%) |
| | | | | | | | | | | | (80/20) | | | | | |
| Resist | A-45 | 80.00% | P-37/ | 5%/8% | Q-19 | 7.00% | — | — | — | — | PGMEA/ | 1.6% | 55 nm | 90° C./ | 100° C./ | TMAH |
| 43 | | | P-23 | | | | | | | | EL | | | 60 sec | 60 sec | (2.38%) |
| | | | | | | | | | | | (80/20) | | | | | |
| Resist | A-46 | 83.00% | P-50/ | 5%/8% | Q-20 | 4.00% | — | — | — | — | PGMEA/ | 1.5% | 50 nm | 100° C./ | 100° C./ | TMAH |
| 44 | | | P-51 | | | | | | | | EL/CyHx | | | 60 sec | 60 sec | (2.38%) |
| | | | | | | | | | | | (30/40/30) | | | | | |
| Resist | A-47 | 57% | P-52/ | 12%/4% | Q-21 | 27% | — | — | — | — | PGMEA/ | 1.3% | 50 nm | 90° C./ | 100° C./ | TMAH |
| 45 | | | P-53 | | | | | | | | EL | | | 60 sec | 60 sec | (2.38%) |
| | | | | | | | | | | | (70/30) | | | | | |
| Resist | A-48/ | 41%/ | P-54 | 14% | Q-8 | 4% | — | — | — | — | PGMEA/ | 1.6% | 55 nm | 100° C./ | 100° C./ | TMAH |
| 46 | A-49 | 41% | | | | | | | | | PGME | | | 60 sec | 60 sec | (2.38%) |
| | | | | | | | | | | | (20/80) | | | | | |
| Resist | A-50 | 75.20% | P-55 | 22.60% | Q-22 | 2.20% | — | — | — | — | PGMEA/ | 1.4% | 50 nm | 100° C./ | 100° C./ | TMAH |
| 47 | | | | | | | | | | | PGME/ | | | 60 sec | 60 sec | (2.38%) |
| | | | | | | | | | | | γ-BL | | | | | |
| | | | | | | | | | | | (79.5/ | | | | | |
| | | | | | | | | | | | 19.5/1.0) | | | | | |
| Resist | A-51 | 97% | — | — | Q-23 | 3% | — | — | — | — | PGMEA/ | 1.4% | 55 nm | 120° C./ | 100° C./ | TMAH |
| 48 | | | | | | | | | | | CyHx/ | | | 60 sec | 60 sec | (2.38%) |
| | | | | | | | | | | | PGME | | | | | |
| | | | | | | | | | | | (16/80/4) | | | | | |

TABLE 11(2)

| | | | | | Acid | | | | | | | | | | | |
|---|---|---|---|---|---|---|---|---|---|---|---|---|---|---|---|---|
| Resist | | | Photoacid | | diffusion | | | | | | | | Condition for formation | | | |
| com- | | | generator | | control agent | | Additive 1 | | Additive 2 | | | Solid | Film | | | |
| posi- | Resin | | | Con- | | Con- | | Con- | | Con- | | con- | thick- | | | Devel- |
| tion | Type | Content | Type | tent | Type | tent | Type | tent | Type | tent | Solvent | tent | ness | PB | PEB | oper |
| Resist | A-52 | 75.0% | P-57 | 25.0% | — | — | — | — | — | — | PGMEA/ | 1.5% | 50 nm | 100° C./ | 100° C./ | TMAH |
| 49 | | | | | | | | | | | PGME/ | | | 60 sec | 60 sec | (2.38%) |
| | | | | | | | | | | | γ-BL | | | | | |
| | | | | | | | | | | | (85/10/5) | | | | | |
| Resist | A-52 | 73.0% | P-61 | 15.0% | Q-2 | 10.0% | — | — | E-10 | 2.00% | PGMEA/ | 1.5% | 40 nm | 80° C./ | 100° C./ | TMAH |
| 50 | | | | | | | | | | | PGME | | | 60 sec | 60 sec | (2.38%) |
| | | | | | | | | | | | (70/30) | | | | | |
| Resist | A-53 | 70.0% | P-61 | 20.0% | Q-12 | 10.0% | — | — | — | — | PGMEA/ | 1.3% | 30 nm | 120° C./ | 100° C./ | TMAH |
| 51 | | | | | | | | | | | CyHx | | | 60 sec | 60 sec | (2.38%) |
| | | | | | | | | | | | (70/30) | | | | | |
| Resist | A-53 | 83.0% | P-62 | 12.0% | Q-19 | 5.0% | — | — | — | — | PGMEA/ | 1.9% | 60 nm | 120° C./ | 90° C./ | nBA |
| 52 | | | | | | | | | | | PGME/EL | | | 60 sec | 60 sec | |
| | | | | | | | | | | | (30/20/50) | | | | | |
| Resist | A-54 | 72.0% | P-62 | 18.0% | Q-3 | 5.0% | — | — | E-14 | 5.00% | PGMEA/ | 1.2% | 25 nm | 120° C./ | 120° C./ | TMAH |
| 53 | | | | | | | | | | | PGME/ | | | 60 sec | 60 sec | (2.38%) |
| | | | | | | | | | | | γ-BL | | | | | |
| | | | | | | | | | | | (85/10/5) | | | | | |
| Resist | A-54 | 85.0% | P-60 | 10.0% | Q-5 | 5.0% | — | — | — | — | PGMEA/ | 2.6% | 70 nm | 120° C./ | 100° C./ | TMAH |
| 54 | | | | | | | | | | | PGME | | | 60 sec | 60 sec | (2.38%) |
| | | | | | | | | | | | (70/30) | | | | | |
| Resist | A-55 | 71.0% | P-60 | 20.0% | Q-19 | 7.0% | — | — | E-17 | 2.00% | PGMEA/ | 1.5% | 50 nm | 120° C./ | 90° C./ | TMAH |
| 55 | | | | | | | | | | | CyHx | | | 60 sec | 60 sec | (2.38%) |
| | | | | | | | | | | | (70/30) | | | | | |
| Resist | A-55 | 60.0% | P-63 | 25.0% | Q-21 | 15.0% | — | — | — | — | PGMEA/ | 1.4% | 40 nm | 120° C./ | 80° C./ | nBA |
| 66 | | | | | | | | | | | PGME/EL | | | 60 sec | 60 sec | |
| | | | | | | | | | | | (30/20/50) | | | | | |
| Resist | A-56 | 62.0% | P-58 | 35.0% | Q-5 | 3.0% | — | — | — | — | PGMEA/ | 1.2% | 30 nm | 120° C./ | 90° C./ | TMAH |
| 57 | | | | | | | | | | | PGME/ | | | 60 sec | 60 sec | (2.38%) |
| | | | | | | | | | | | γ-BL | | | | | |
| | | | | | | | | | | | (85/10/5) | | | | | |
| Resist | A-56 | 67.0% | P-59 | 30.0% | — | — | — | — | E-14 | 3.00% | PGMEA/ | 1.5% | 60 nm | 120° C./ | 120° C./ | TMAH |
| 58 | | | | | | | | | | | PGME | | | 60 sec | 60 sec | (2.38%) |
| | | | | | | | | | | | (70/30) | | | | | |
| Resist | A-57 | 75.0% | P-58 | 25.0% | — | — | — | — | — | — | PGMEA/ | 1.0% | 25 nm | 120° C./ | 90° C./ | TMAH |
| 59 | | | | | | | | | | | CyHx | | | 60 sec | 60 sec | (2.38%) |
| | | | | | | | | | | | (70/30) | | | | | |
| Resist | A-58 | 74.0% | P-63 | 18.0% | Q-5 | 8.0% | — | — | — | — | PGMEA/ | 2.7% | 70 nm | 90° C./ | 130° C./ | TMAH |
| 60 | | | | | | | | | | | PGME/EL | | | 60 sec | 60 sec | (2.38%) |
| | | | | | | | | | | | (30/20/50) | | | | | |
| Resist | A-59 | 55.0% | P-56 | 40.0% | Q-12 | 5.0% | — | — | — | — | PGMEA/ | 1.5% | 50 nm | 100° C./ | 100° C./ | TMAH |
| 61 | | | | | | | | | | | PGME/ | | | 60 sec | 60 sec | (2.38%) |
| | | | | | | | | | | | γ-BL | | | | | |
| | | | | | | | | | | | (85/10/5) | | | | | |
| Resist | A-59 | 70.0% | P-63 | 15.0% | Q-14 | 15.0% | — | — | — | — | PGMEA/ | 1.5% | 50 nm | 100° C./ | 90° C./ | nBA |
| 62 | | | | | | | | | | | PGME | | | 60 sec | 60 sec | |
| | | | | | | | | | | | (70/30) | | | | | |
| Resist | A-60 | 90.0% | — | — | Q-12 | 10.0% | — | — | — | — | PGMEA/ | 1.6% | 50 nm | 100° C./ | 130° C./ | TMAH |
| 63 | | | | | | | | | | | CyHx | | | 60 sec | 60 sec | (2.38%) |
| | | | | | | | | | | | (70/30) | | | | | |
| Resist | A-61 | 90.0% | P-56 | 10.0% | — | — | — | — | — | — | PGMEA/ | 1.5% | 50 nm | 100° C./ | 100° C./ | TMAH |
| 64 | | | | | | | | | | | PGME/EL | | | 60 sec | 60 sec | (2.38%) |
| | | | | | | | | | | | (30/20/50) | | | | | |

TABLE 14

| | Step 3 | | | | | | | |
|---|---|---|---|---|---|---|---|---|
| | Second filter | | | | | | | |
| | | Low- | | | | | | |
| | | molecular- | | Filter sedimentation | | | | |
| | | weight | | | | Second | | Number of |
| | Resin | component | Solvent | Time | Pressure | solution | Direction | circulations |
| Production method | 0.5 um Nylon | — | 0.01 um PE | — | — | — | — | — |
| KH-1 | | | | | | | | |
| Production method | 0.5 um Nylon | — | 0.01 um PE | — | — | — | — | — |
| KH-2 | | | | | | | | |
| Production method | 0.5 um Nylon | — | 0.01 um PE | — | — | — | — | — |
| KJ-1 | | | | | | | | |
| Production method | 0.5 um Nylon | — | 0.01 um PE | — | — | — | — | — |
| KJ-2 | | | | | | | | |
| Production method | 0.5 um Nylon | — | 0.01 um PE | — | — | — | — | — |
| KJ-3 | | | | | | | | |
| Production method | 0.5 um Nylon | — | 0.01 um PE | — | — | — | — | — |
| KJ-4 | | | | | | | | |
| Production method | 0.5 um Nylon | — | 0.01 um PE | — | — | — | — | — |
| KJ-5 | | | | | | | | |
| Production method | 0.5 um Nylon | — | 0.01 um PE | — | — | — | — | — |
| KJ-6 | | | | | | | | |
| Production method | 0.5 um Nylon | — | 0.01 um PE | — | — | — | — | — |
| KJ-7 | | | | | | | | |
| Production method | 0.5 um Nylon | — | 0.01 um PE | — | — | — | — | — |
| KJ-8 | | | | | | | | |
| Production method | 0.5 um Nylon | — | 0.01 um PE | — | — | — | — | — |
| KJ-9 | | | | | | | | |
| Production method | 0.5 um Nylon | — | 0.01 um PE | — | — | — | — | — |
| KJ-10 | | | | | | | | |
| Production method | 0.5 um Nylon | — | 0.01 um PE | — | — | — | — | — |
| KJ-11 | | | | | | | | |
| Production method | 0.5 um Nylon | — | 0.01 um PE | — | — | — | — | — |
| KJ-12 | | | | | | | | |
| Production method | 0.5 um Nylon | — | 0.01 um PE | — | — | — | — | — |
| KJ-13 | | | | | | | | |
| Production | 0.5 um Nylon | — | 0.01 um PE | — | — | — | — | — |
| method KJ-14 | | | | | | | | |
| Production | 0.5 um Nylon | — | 0.01 um PE | — | — | — | — | — |
| method KJ-15 | | | | | | | | |
| Production | 0.5 um Nylon | — | 0.01 um PE | — | — | — | — | — |
| method KJ-16 | | | | | | | | |
| Production | 0.5 um Nylon | — | 0.01 um PE | — | — | — | — | — |
| method KJ-17 | | | | | | | | |
| Production | 0.5 um Nylon | — | 0.01 um PE | — | — | — | — | — |
| method KJ-18 | | | | | | | | |
| Production | 0.5 um Nylon | — | 0.01 um PE | — | — | — | — | — |
| method KJ-19 | | | | | | | | |
| Production | 0.5 um Nylon | — | 0.01 um PE | — | — | — | — | — |
| method KJ-20 | | | | | | | | |
| Production | 0.5 um Nylon | — | 0.01 um PE | 1 h | 200 kPa | PGMEA | Upward | — |
| method KJ-21 | | | | | | | | |
| Production | 0.5 um Nylon | — | 0.01 um PE | 1 h | 200 kPa | Specific | Upward | — |
| method KJ-22 | | | | | | solvent | | |
| Production | 0.5 um Nylon + | 0.01 um Nylon + | 0.01 um Nylon + | 1 h | 200 kPa | Specific | Upward | — |
| method KJ-23 | 0.3 um PE | 0.005 um PE | 0.005 um PE | | | solvent | | |
| Production | 0.5 um Nylon + | 0.01 um Nylon + | 0.01 um Nylon + | 1 h | 200 kPa | Specific | Upward | 5 |
| method KJ-24 | 0.3 um PE | 0.005 um PE | 0.005 um PE | | | solvent | | |
| Production | 0.5 um Nylon | — | 0.01 um PE | 1 h | 200 kPa | PGMEA | Upward | — |
| method KJ-25 | | | | | | | | |
| Production | 0.5 um Nylon | — | 0.01 um PE | 1 h | 200 kPa | PGMEA | Upward | — |
| method KJ-26 | | | | | | | | |
| Production | 0.5 um Nylon + | 0.01 um Nylon + | 0.01 um Nylon + | 1 h | 200 kPa | Specific | Upward | 5 |
| method KJ-27 | 0.3 um PE | 0.005 um PE | 0.005 um PE | | | solvent | | |
| Production | 0.5 um Nylon + | 0.01 um Nylon + | 0.01 um Nylon + | 1 h | 200 kPa | Specific | Upward | 5 |
| method KJ-28 | 0.3 um PE | 0.005 um PE | 0.005 um PE | | | solvent | | |
| | Step 1 | | | | | | | Linear |
| | | | Filter sedimentation | | | | | velocity |
| | | Cleaning | | | Second | | Number of | (L/hr · |
| | First filter | method | Time | Pressure | solution | Direction | circulations | m²) |
| Production method | 0.2 um Nylon + | — | — | — | — | Downward | — | — |
| KH-1 | 0.15 um PE | | | | | | | |
| Production method | 0.2 um Nylon + | Cleaning | 1 h | — | Water | Downward | — | 30 |
| KH-2 | 0.15 um PE | method 1 | | | | | | |
| Production method | 0.2 um Nylon + | Cleaning | 1 h | — | PGMEA | Downward | — | 30 |
| KJ-1 | 0.15 um PE | method 1 | | | | | | |
| Production method | 0.2 um Nylon + | Cleaning | 1 h | — | n-Hexane | Downward | — | 30 |
| KJ-2 | 0.15 um PE | method 1 | | | | | | |
| Production method | 0.2 um Nylon + | Cleaning | 1 h | — | Specific | Downward | — | 30 |
| KJ-3 | 0.15 um PE | method 1 | | | solvent | | | |
| Production method | 0.2 um Nylon + | Cleaning | 1 h | — | Specific | Downward | — | 30 |
| KJ-4 | 0.15 um PE | method 2 | | | solvent | | | |
| Production method | 0.2 um Nylon + | Cleaning | 1 h | 200 kPa | Specific | Upward | 20 | 30 |
| KJ-5 | 0.15 um PE | method 2 | | | solvent | | | |
| Production method | 0.2 um Nylon + | Cleaning | 1 h | — | Specific | — | — | — |
| KJ-6 | 0.15 um PE | method 3 | | | solvent | | | |
| Production method | 0.2 um Nylon + | Cleaning | 24 h | — | Specific | — | — | — |
| KJ-7 | 0.15 um PE | method 3 | | | solvent | | | |
| Production method | 0.2 um Nylon + | Cleaning | 1 h | — | Resist | Downward | — | 30 |
| KJ-8 | 0.15 um PE | method 1 | | | produced | | | |
| Production method | 0.2 um Nylon + | Cleaning | 3 h | — | Resist | Downward | — | 30 |
| KJ-9 | 0.15 um PE | method 1 | | | produced | | | |
| Production method | 0.2 um Nylon + | Cleaning | 1 h | 50 kPa | Resist | Downward | — | 30 |
| KJ-10 | 0.15 um PE | method 1 | | | produced | | | |
| Production method | 0.2 um Nylon + | Cleaning | 1 h | 100 kPa | Resist | Downward | — | 30 |
| KJ-11 | 0.15 um PE | method 1 | | | produced | | | |
| Production method | 0.2 um Nylon + | Cleaning | 1 h | 200 kPa | Resist | Downward | — | 30 |
| KJ-12 | 0.15 um PE | method 1 | | | produced | | | |
| Production method | 0.2 um Nylon + | Cleaning | 1 h | 200 kPa | Resist | Upward | — | 30 |
| KJ-13 | 0.15 um PE | method 1 | | | produced | | | |
| Production | 0.2 um Nylon + | Cleaning | 1 h | 200 kPa | Resist | Upward | 10 | 30 |
| method KJ-14 | 0.15 um PE | method 1 | | | produced | | | |
| Production | 0.2 um Nylon + | Cleaning | 1 h | 200 kPa | Resist | Upward | 20 | 30 |
| method KJ-15 | 0.15 um PE | method 1 | | | produced | | | |
| Production | 0.3 um Nylon + | Cleaning | 1 h | 200 kPa | Resist | Upward | — | 30 |
| method KJ-16 | 0.2 um PE | method 1 | | | produced | | | |
| Production | 0.3 um PE + | Cleaning | 1 h | 200 kPa | Resist | Upward | — | 30 |
| method KJ-17 | 0.2 um Nylon | method 1 | | | produced | | | |
| Production | 0.3 um PE + | Cleaning | 1 h | 200 kPa | Resist | Upward | — | 30 |
| method KJ-18 | 0.2 um Nylon + | method 1 | | | produced | | | |
| | 0.15 um PE | | | | | | | |
| Production | 0.3 um Nylon + | Cleaning | 1 h | 200 kPa | Resist | Upward | — | 30 |
| method KJ-19 | 0.2 um PE + | method 1 | | | produced | | | |
| | 0.15 um PE | | | | | | | |
| Production | 0.5 um PTFE + | Cleaning | 1 h | 200 kPa | Resist | Upward | — | 30 |
| method KJ-20 | 0.2 um Nylon + | method 1 | | | produced | | | |
| | 0.15 um PE | | | | | | | |
| Production | 0.2 um Nylon + | Cleaning | 1 h | 200 kPa | Resist | Upward | 20 | 30 |
| method KJ-21 | 0.15 um PE | method 1 | | | produced | | | |
| Production | 0.2 um Nylon + | Cleaning | 1 h | 200 kPa | Resist | Upward | 20 | 30 |
| method KJ-22 | 0.15 um PE | method 1 | | | produced | | | |
| Production | 0.2 um Nylon + | Cleaning | 1 h | 200 kPa | Resist | Upward | 20 | 30 |
| method KJ-23 | 0.15 um PE | method 1 | | | produced | | | |
| Production | 0.2 um Nylon + | Cleaning | 1 h | 200 kPa | Resist | Upward | 20 | 30 |
| method KJ-24 | 0.15 um PE | method 1 | | | produced | | | |
| Production | 0.2 um Nylon + | Cleaning | 1 h | 200 kPa | Resist | Upward | 20 | 20 |
| method KJ-25 | 0.15 um PE | method 1 | | | produced | | | |
| Production | 0.2 um Nylon + | Cleaning | 1 h | 200 kPa | Resist | Upward | 20 | 10 |
| method KJ-26 | 0.15 um PE | method 1 | | | produced | | | |
| Production | 0.2 um Nylon + | Cleaning | 1 h | 200 kPa | Resist | Upward | 20 | 20 |
| method KJ-27 | 0.15 um PE | method 1 | | | produced | | | |
| Production | 0.2 um Nylon + | Cleaning | 1 h | 200 kPa | Resist | Upward | 20 | 10 |
| method KJ-28 | 0.15 um PE | method 1 | | | produced | | | |

TABLE 15

| | Step 3 | | | | | | | |
|---|---|---|---|---|---|---|---|---|
| | Second filter | | | | | | | |
| | | Low- | | | | | | |
| | | molecular- | | Filter sedimentation | | | | |
| | | weight | | | | Second | | Number of |
| | Resin | component | Solvent | Time | Pressure | solution | Direction | circulations |
| Production method | 0.02 um Nylon | — | 0.01 um PE | — | — | — | — | — |
| AH-1 | | | | | | | | |
| Production method | 0.02 um Nylon | — | 0.01 um PE | — | — | — | — | — |
| AH-2 | | | | | | | | |
| Production method | 0.02 um Nylon | — | 0.01 um PE | — | — | — | — | — |
| AJ-1 | | | | | | | | |
| Production method | 0.02 um Nylon | — | 0.01 um PE | — | — | — | — | — |
| AJ-2 | | | | | | | | |
| Production method | 0.02 um Nylon | — | 0.01 um PE | — | — | — | — | — |
| AJ-3 | | | | | | | | |
| Production method | 0.02 um Nylon | — | 0.01 um PE | — | — | — | — | — |
| AJ-4 | | | | | | | | |
| Production method | 0.02 um Nylon | — | 0.01 um PE | — | — | — | — | — |
| AJ-5 | | | | | | | | |
| Production method | 0.02 um Nylon | — | 0.01 um PE | — | — | — | — | — |
| AJ-6 | | | | | | | | |
| Production method | 0.02 um Nylon | — | 0.01 um PE | — | — | — | — | — |
| AJ-7 | | | | | | | | |
| Production method | 0.02 um Nylon | — | 0.01 um PE | — | — | — | — | — |
| AJ-8 | | | | | | | | |
| Production method | 0.02 um Nylon | — | 0.01 um PE | — | — | — | — | — |
| AJ-9 | | | | | | | | |
| Production method | 0.02 um Nylon | — | 0.01 um PE | — | — | — | — | — |
| AJ-10 | | | | | | | | |
| Production method | 0.02 um Nylon | — | 0.01 um PE | — | — | — | — | — |
| AJ-11 | | | | | | | | |
| Production method | 0.02 um Nylon | — | 0.01 um PE | — | — | — | — | — |
| AJ-12 | | | | | | | | |
| Production method | 0.02 um Nylon | — | 0.01 um PE | — | — | — | — | — |
| AJ-13 | | | | | | | | |
| Production | 0.02 um Nylon | — | 0.01 um PE | — | — | — | — | — |
| method AJ-14 | | | | | | | | |
| Production | 0.02 um Nylon | — | 0.01 um PE | — | — | — | — | — |
| method AJ-15 | | | | | | | | |
| Production | 0.02 um Nylon | — | 0.01 um PE | — | — | — | — | — |
| method AJ-16 | | | | | | | | |
| Production | 0.02 um Nylon | — | 0.01 um PE | — | — | — | — | — |
| method AJ-17 | | | | | | | | |
| Production | 0.02 um Nylon | — | 0.01 um PE | — | — | — | — | — |
| method AJ-18 | | | | | | | | |
| Production | 0.02 um Nylon | — | 0.01 um PE | — | — | — | — | — |
| method AJ-19 | | | | | | | | |
| Production | 0.02 um Nylon | — | 0.01 um PE | — | — | — | — | — |
| method AJ-20 | | | | | | | | |
| Production | 0.02 um Nylon | — | 0.01 um PE | 1 h | 200 kPa | PGMEA | Upward | — |
| method AJ-21 | | | | | | | | |
| Production | 0.02 um Nylon | — | 0.01 um PE | 1 h | 200 kPa | Specific | Upward | — |
| method AJ-22 | | | | | | solvent | | |
| Production | 0.02 um Nylon + | 0.01 um Nylon + | 0.01 um Nylon + | 1 h | 200 kPa | Specific | Upward | — |
| method AJ-23 | 0.01 um PE | 0.005 um PE | 0.005 um PE | | | solvent | | |
| Production | 0.02 um Nylon + | 0.01 um Nylon + | 0.01 um Nylon + | 1 h | 200 kPa | Specific | Upward | 5 |
| method AJ-24 | 0.1 um PE | 0.005 um PE | 0.005 um PE | | | solvent | | |
| Production | 0.02 um Nylon | — | 0.01 um PE | 1 h | 200 kPa | PGMEA | Upward | — |
| method AJ-25 | | | | | | | | |
| Production | 0.02 um Nylon | — | 0.01 um PE | 1 h | 200 kPa | PGMEA | Upward | — |
| method AJ-26 | | | | | | | | |
| Production | 0.02 um Nylon + | 0.01 um Nylon + | 0.01 um Nylon + | 1 h | 200 kPa | Specific | Upward | 5 |
| method AJ-27 | 0.01 um PE | 0.005 um PE | 0.005 um PE | | | solvent | | |
| Production | 0.02 um Nylon + | 0.01 um Nylon + | 0.01 um Nylon + | 1 h | 200 kPa | Specific | Upward | 5 |
| method AJ-28 | 0.1 um PE | 0.005 um PE | 0.005 um PE | | | solvent | | |
| | Step 1 | | | | | | | Linear |
| | | | Filter sedimentation | | | | | velocity |
| | | Cleaning | | | Second | | Number of | (L/hr · |
| | First filter | method | Time | Pressure | solution | Direction | circulations | m²) |
| Production method | 0.01 um Nylon + | — | — | — | | Downward | — | — |
| AH-1 | 0.005 um PE | | | | | | | |
| Production method | 0.01 um Nylon + | Cleaning | 1 h | — | Water | Downward | — | 30 |
| AH-2 | 0.005 um PE | method 1 | | | | | | |
| Production method | 0.01 um Nylon + | Cleaning | 1 h | — | PGMEA | Downward | — | 30 |
| AJ-1 | 0.005 um PE | method 1 | | | | | | |
| Production method | 0.01 um Nylon + | Cleaning | 1 h | — | n-Hexane | Downward | — | 30 |
| AJ-2 | 0.005 um PE | method 1 | | | | | | |
| Production method | 0.01 um Nylon + | Cleaning | 1 h | — | Specific | Downward | — | 30 |
| AJ-3 | 0.005 um PE | method 1 | | | solvent | | | |
| Production method | 0.01 um Nylon + | Cleaning | 1 h | — | Specific | Downward | — | 30 |
| AJ-4 | 0.005 um PE | method 2 | | | solvent | | | |
| Production method | 0.01 um Nylon + | Cleaning | 1 h | 200 kPa | Specific | Upward | 20 | 30 |
| AJ-5 | 0.005 um PE | method 2 | | | solvent | | | |
| Production method | 0.01 um Nylon + | Cleaning | 1 h | — | Specific | — | — | — |
| AJ-6 | 0.005 um PE | method 3 | | | solvent | | | |
| Production method | 0.01 um Nylon + | Cleaning | 24 h | — | Specific | — | — | — |
| AJ-7 | 0.005 um PE | method 3 | | | solvent | | | |
| Production method | 0.01 um Nylon + | Cleaning | 1 h | — | Resist | Downward | — | 30 |
| AJ-8 | 0.005 um PE | method 1 | | | produced | | | |
| Production method | 0.01 um Nylon + | Cleaning | 3 h | — | Resist | Downward | — | 30 |
| AJ-9 | 0.005 um PE | method 1 | | | produced | | | |
| Production method | 0.01 um Nylon + | Cleaning | 1 h | 50 kPa | Resist | Downward | — | 30 |
| AJ-10 | 0.005 um PE | method 1 | | | produced | | | |
| Production method | 0.01 um Nylon + | Cleaning | 1 h | 100 kPa | Resist | Downward | — | 30 |
| AJ-11 | 0.005 um PE | method 1 | | | produced | | | |
| Production method | 0.01 um Nylon + | Cleaning | 1 h | 200 kPa | Resist | Downward | — | 30 |
| AJ-12 | 0.005 um PE | method 1 | | | produced | | | |
| Production method | 0.01 um Nylon + | Cleaning | 1 h | 200 kPa | Resist | Upward | — | 30 |
| AJ-13 | 0.005 um PE | method 1 | | | produced | | | |
| Production | 0.01 um Nylon + | Cleaning | 1 h | 200 kPa | Resist | Upward | 10 | 30 |
| method AJ-14 | 0.005 um PE | method 1 | | | produced | | | |
| Production | 0.01 um Nylon + | Cleaning | 1 h | 200 kPa | Resist | Upward | 20 | 30 |
| method AJ-15 | 0.005 um PE | method 1 | | | produced | | | |
| Production | 0.005 um Nylon + | Cleaning | 1 h | 200 kPa | Resist | Upward | — | 30 |
| method AJ-16 | 0.003 um PE | method 1 | | | produced | | | |
| Production | 0.01 um PE + | Cleaning | 1 h | 200 kPa | Resist | Upward | — | 30 |
| method AJ-17 | 0.01 um Nylon | method 1 | | | produced | | | |
| Production | 0.01 um PE + | Cleaning | 1 h | 200 kPa | Resist | Upward | — | 30 |
| method AJ-18 | 0.005 um Nylon + | method 1 | | | produced | | | |
| | 0.001 um PE | | | | | | | |
| Production | 0.005 um Nylon + | Cleaning | 1 h | 200 kPa | Resist | Upward | — | 30 |
| method AJ-19 | 0.003 um PE + | method 1 | | | produced | | | |
| | 0.003 um PE | | | | | | | |
| Production | 0.02 um PTFE + | Cleaning | 1 h | 200 kPa | Resist | Upward | — | 30 |
| method AJ-20 | 0.01 um Nylon + | method 1 | | | produced | | | |
| | 0.003 um PE | | | | | | | |
| Production | 0.01 um Nylon + | Cleaning | 1 h | 200 kPa | Resist | Upward | 20 | 30 |
| method AJ-21 | 0.005 um PE | method 1 | | | produced | | | |
| Production | 0.01 um Nylon + | Cleaning | 1 h | 200 kPa | Resist | Upward | 20 | 30 |
| method AJ-22 | 0.005 um PE | method 1 | | | produced | | | |
| Production | 0.01 um Nylon + | Cleaning | 1 h | 200 kPa | Resist | Upward | 20 | 30 |
| method AJ-23 | 0.005 um PE | method 1 | | | produced | | | |
| Production | 0.01 um Nylon + | Cleaning | 1 h | 200 kPa | Resist | Upward | 20 | 30 |
| method AJ-24 | 0.005 um PE | method 1 | | | produced | | | |
| Production | 0.01 um Nylon + | Cleaning | 1 h | 200 kPa | Resist | Upward | 20 | 20 |
| method AJ-25 | 0.005 um PE | method 1 | | | produced | | | |
| Production | 0.01 um Nylon + | Cleaning | 1 h | 200 kPa | Resist | Upward | 20 | 10 |
| method AJ-26 | 0.005 um PE | method 1 | | | produced | | | |
| Production | 0.01 um Nylon + | Cleaning | 1 h | 200 kPa | Resist | Upward | 20 | 20 |
| method AJ-27 | 0.005 um PE | method 1 | | | produced | | | |
| Production | 0.01 um Nylon + | Cleaning | 1 h | 200 kPa | Resist | Upward | 20 | 10 |
| method AJ-28 | 0.005 um PE | method 1 | | | produced | | | |

### Examples K-1 to K-50, and Comparative Examples K-1 to K-16

### KrF Exposure Experiment

As mentioned above, the resist composition was filled in five subdivided containers. Thus, an isolated space pattern was formed using each of the resist compositions in the subdivided containers according to the following method (Pattern Formation 1).

Specifically, in a case where a method which will be described later (Pattern Formation 1) was carried out, the resist compositions filled in the five subdivided containers were each used on five silicon wafers for each resist composition to form an isolated space pattern. That is, using the five subdivided resist compositions, an isolated space pattern was formed on the five silicon wafers for each subdivided resist composition, and an isolated space pattern was formed on a total of 25 silicon wafers.

Next, an operation of measuring the space line width per isolated space pattern at 60 points and calculating an average value thereof was carried out on the isolated space patterns on 25 silicon wafers, and an average value for each isolated space pattern was calculated. Next, using the values of the obtained 25 average values, the standard deviations a were obtained and 3σ corresponding to three times the standard deviation was calculated. The smaller the value of 3σ, the better the effect. The results are shown in Tables 14 and 15.

Furthermore, a scanning electron microscope (9380II manufactured by Hitachi High-Technologies Corporation) was used for the measurement of a pattern size.

(Pattern Formation 1)

Using a spin coater “ACT-8” manufactured by Tokyo Electron Limited, an antireflection film was not provided on a silicon wafer (8-inch diameter) treated with HMDS (hexamethyldisilazane), and each of the resist compositions (resists 1 to 15) prepared by a predetermined production method described in the “Resist composition” column in Tables 14 and 15 was applied to the wafer and baked under a PB condition corresponding to each resist composition shown in Table 9, thereby forming a resist film having a film thickness corresponding to each resist composition shown in Table 9.

The obtained resist film was subjected to pattern exposure through a mask having a line-and-space pattern so that a space line width and a pitch width of the pattern were 5 μm and 20 μm, respectively, using a KrF excimer laser scanner (manufactured by ASML; PAS5500/850C, wavelength 248 nm, NA=0.60, σ=0.75).

The resist film after exposure was baked under a PEB condition corresponding to each resist composition shown in Table 9, then developed with a developer corresponding to each resist composition shown in Table 9 for 30 seconds, and spin-dried to obtain an isolated space pattern having a space line width of 5 μm and a pitch width of 20 μm.

TABLE 16

| | Resist | | Evaluation |
|---|---|---|---|
| Table 14 | composition | Production method | results (3σ) |
| Comparative | Resist 1 | Production method KH-1 | 9.08 |
| Example K-1 | | | |
| Comparative | Resist 1 | Production method KH-2 | 9.14 |
| Example K-2 | | | |
| Example K-1 | Resist 1 | Production method KJ-1 | 8.00 |
| Example K-2 | Resist 1 | Production method KJ-2 | 8.54 |
| Example K-3 | Resist 1 | Production method KJ-3 | 8.19 |
| Example K-4 | Resist 1 | Production method KJ-4 | 8.24 |
| Example K-5 | Resist 1 | Production method KJ-5 | 6.01 |
| Example K-6 | Resist 1 | Production method KJ-6 | 7.99 |
| Example K-7 | Resist 1 | Production method KJ-7 | 7.00 |
| Example K-8 | Resist 1 | Production method KJ-8 | 6.89 |
| Example K-9 | Resist 1 | Production method KJ-9 | 6.78 |
| Example K-10 | Resist 1 | Production method KJ-10 | 6.66 |
| Example K-11 | Resist 1 | Production method KJ-10 | 6.49 |
| Example K-12 | Resist 1 | Production method KJ-12 | 6.41 |
| Example K-13 | Resist 1 | Production method KJ-13 | 6.33 |
| Example K-14 | Resist 1 | Production method KJ-14 | 6.28 |
| Example K-15 | Resist 1 | Production method KJ-15 | 6.22 |
| Example K-16 | Resist 1 | Production method KJ-16 | 6.13 |
| Example K-17 | Resist 1 | Production method KJ-17 | 6.07 |
| Example K-18 | Resist 1 | Production method KJ-18 | 6.10 |
| Example K-19 | Resist 1 | Production method KJ-19 | 6.06 |
| Example K-20 | Resist 1 | Production method KJ-20 | 6.05 |
| Example K-21 | Resist 1 | Production method KJ-21 | 6.03 |
| Example K-22 | Resist 1 | Production method KJ-22 | 6.01 |
| Example K-23 | Resist 1 | Production method KJ-23 | 6.00 |
| Example K-24 | Resist 1 | Production method KJ-24 | 5.99 |
| Example K-25 | Resist 2 | Production method KJ-5 | 5.27 |
| Example K-26 | Resist 4 | Production method KJ-5 | 5.37 |
| Example K-27 | Resist 5 | Production method KJ-5 | 5.48 |
| Example K-28 | Resist 6 | Production method KJ-5 | 5.92 |

TABLE 17

| | Resist | | Evaluation |
|---|---|---|---|
| Table 15 | composition | Production method | results (3σ) |
| Comparative | Resist 2 | Production method KH-1 | 8.27 |
| Example K-3 | | | |
| Comparative | Resist 3 | Production method KH-1 | 8.33 |
| Example K-4 | | | |
| Comparative | Resist 4 | Production method KH-1 | 8.42 |
| Example K-5 | | | |
| Comparative | Resist 5 | Production method KH-1 | 8.62 |
| Example K-6 | | | |
| Comparative | Resist 6 | Production method KH-1 | 9.01 |
| Example K-7 | | | |
| Comparative | Resist 7 | Production method KH-I | 8.53 |
| Example K-8 | | | |
| Comparative | Resist 8 | Production method KH-1 | 8.03 |
| Example K-9 | | | |
| Comparative | Resist 9 | Production method KH-1 | 8.54 |
| Example K-10 | | | |
| Comparative | Resist 10 | Production method KH-1 | 8.52 |
| Example K-11 | | | |
| Comparative | Resist 11 | Production method KH-1 | 8.65 |
| Example K-12 | | | |
| Comparative | Resist 12 | Production method KH-1 | 8.55 |
| Example K-13 | | | |
| Comparative | Resist 13 | Production method KH-1 | 8.15 |
| Example K-14 | | | |
| Comparative | Resist 14 | Production method KH-1 | 8.66 |
| Example K-15 | | | |
| Comparative | Resist 15 | Production method KH-1 | 8.45 |
| Example K-16 | | | |
| Example K-29 | Resist 2 | Production method KJ-24 | 5.24 |
| Example K-30 | Resist 3 | Production method KJ-24 | 5.28 |
| Example K-31 | Resist 4 | Production method KJ-24 | 5.34 |
| Example K-32 | Resist 5 | Production method KJ-24 | 5.46 |
| Example K-33 | Resist 6 | Production method KJ-24 | 5.88 |
| Example K-34 | Resist 7 | Production method KJ-24 | 5.34 |
| Example K-35 | Resist 8 | Production method KJ-24 | 5.01 |
| Example K-36 | Resist 9 | Production method KJ-24 | 5.37 |
| Example K-37 | Resist 10 | Production method KJ-24 | 5.39 |
| Example K-38 | Resist 11 | Production method KJ-24 | 5.59 |
| Example K-39 | Resist 12 | Production method KJ-24 | 5.39 |
| Example K-40 | Resist 13 | Production method KJ-24 | 5.08 |
| Example K-41 | Resist 14 | Production method KJ-24 | 5.46 |
| Example K-42 | Resist 15 | Production method KJ-24 | 5.37 |
| Example K-43 | Resist 1 | Production method KJ-25 | 5.81 |
| Example K-44 | Resist 1 | Production method KJ-26 | 5.71 |
| Example K-45 | Resist 1 | Production method KJ-27 | 5.70 |
| Example K-46 | Resist 1 | Production method KJ-28 | 5.61 |
| Example K-47 | Resist 2 | Production method KJ-28 | 5.01 |
| Example K-48 | Resist 4 | Production method KJ-28 | 5.09 |
| Example K-49 | Resist 5 | Production method KJ-28 | 5.21 |
| Example K-50 | Resist 6 | Production method KJ-28 | 5.62 |

As shown in the table above, it was confirmed that a desired effect can be obtained by the production method of the embodiment of the present invention. For example, as seen from the comparison between Example K-29 using “Resist 2” as the resist composition and Comparative Example K-3, Example K-29 using the production method of the embodiment of the present invention exhibited a more excellent effect.

Above all, from the comparison of Examples K-1 and K-2, it was confirmed that the effect is more excellent in a case where the SP value of the first organic solvent is 17.0 MPa^{1/2} or more and less than 25.0 MPa^{1/2}.

In addition, from the comparison of Examples K-1, K-3, and K-8, it was confirmed that the effect was more excellent in a case where the resist composition was used as the first solution.

Furthermore, from the comparison of Examples K-8 and K-10 to 12, it was confirmed that the effect was more excellent in a case where the immersion treatment of the first filter was carried out under a predetermined pressure.

Moreover, from the comparison of Examples K-12 and K-13, it was confirmed that the effect was more excellent in a case where the liquid passing direction of the solution passing through the filter was from the lower side to the upper side in the vertical direction.

In addition, from the comparison between Examples K-21 to K-24 and the other Examples, it was confirmed that the effect was more excellent in a case where the steps 3 and 4 were carried out.

Furthermore, from the comparison of Examples K-22, K-43, and K-44, it was confirmed that the lower the linear velocity, the better the effect.

### Examples A-1 to A-51 and Comparative Examples A-1 to A-17

### ArF Exposure Experiment

As mentioned above, the resist composition was filled in five subdivided containers.

Thus, a hole pattern was formed using each of the resist compositions in the subdivided containers according to the following method (Pattern Formation 2).

Specifically, in a case where a method which will be described later (Pattern Formation 2) was carried out, the resist compositions filled in the five subdivided containers were each used on five silicon wafers for each resist composition to form a hole pattern. That is, using the five subdivided resist compositions, a hole pattern was formed on the five silicon wafers for each subdivided resist composition, and a hole pattern was formed on a total of 25 silicon wafers.

Next, an operation of measuring a hole part per hole pattern at 60 points and calculating an average value thereof was carried out on the hole patterns on 25 silicon wafers, and an average value for each hole pattern was calculated. Next, using the values of the obtained 25 average values, the standard deviations σ were obtained and 3σ corresponding to three times the standard deviation was calculated. The smaller the value of 3σ, the better the effect. The results are shown in Tables 16 and 17.

Furthermore, a scanning electron microscope (9380II manufactured by Hitachi High-Technologies Corporation) was used for the measurement of a pattern size.

(Pattern Formation 2)

A composition for forming an organic antireflection film, ARC29SR (manufactured by Brewer Science, Inc.), was applied onto a silicon wafer (12-inch diameter), using a spin coater “ACT-12” manufactured by Tokyo Electron Limited, and baked at 205° C. for 60 seconds to form an antireflection film having a film thickness of 98 nm.

The resist compositions (resists 16 to 31) prepared by a predetermined production method described in the “Resist composition” column of Tables 16 and 17 was applied onto the obtained antireflection film using the same device, and baked under a PB condition corresponding to each resist composition shown in Table 10 to obtain a resist film having a film thickness corresponding to each resist composition shown in Table 10.

The obtained resist film was subjected to pattern exposure through a square array of 6% halftone masks having a hole portion of 45 nm and a pitch between the holes of 90 nm, using an ArF excimer laser liquid immersion scanner (manufactured by ASML; XT1700i, NA1.20, C-Quad, outer sigma 0.900, inner sigma 0.812, XY deflection). Ultrapure water was used as the immersion liquid.

The resist film after the exposure was baked under a PEB condition corresponding to each resist composition shown in Table 10, developed with a developer corresponding to each resist composition shown in Table 10 for 30 seconds, and then rinsed with pure water for 30 seconds. Thereafter, the resist film was spin-dried to obtain a hole pattern having a pore diameter of 45 nm.

TABLE 18

| | Resist | | Evaluation |
|---|---|---|---|
| Table 16 | composition | Production method | results (3σ) |
| Comparative | Resist 16 | Production method AH-1 | 3.80 |
| Example A-1 | | | |
| Comparative | Resist 16 | Production method AH-2 | 3.74 |
| Example A-2 | | | |
| Example A-1 | Resist 16 | Production method AJ-1 | 2.96 |
| Example A-2 | Resist 16 | Production method AJ-2 | 3.17 |
| Example A-3 | Resist 16 | Production method AJ-3 | 2.90 |
| Example A-4 | Resist 16 | Production method AJ-4 | 2.92 |
| Example A-5 | Resist 16 | Production method AJ-5 | 1.57 |
| Example A-6 | Resist 16 | Production method AJ-6 | 2.98 |
| Example A-7 | Resist 16 | Production method AJ-7 | 2.22 |
| Example A-8 | Resist 16 | Production method AJ-8 | 2.02 |
| Example A-9 | Resist 16 | Production method AJ-9 | 1.98 |
| Example A-10 | Resist 16 | Production method AJ-10 | 1.91 |
| Example A-11 | Resist 16 | Production method AJ-11 | 1.88 |
| Example A-12 | Resist 16 | Production method AJ-12 | 1.82 |
| Example A-13 | Resist 16 | Production method AJ-13 | 1.78 |
| Example A-14 | Resist 16 | Production method AJ-14 | 1.74 |
| Example A-15 | Resist 16 | Production method AJ-15 | 1.70 |
| Example A-16 | Resist 16 | Production method AJ-16 | 1.68 |
| Example A-17 | Resist 16 | Production method AJ-17 | 1.69 |
| Example A-18 | Resist 16 | Production method AJ-18 | 1.68 |
| Example A-19 | Resist 16 | Production method AJ-19 | 1.71 |
| Example A-20 | Resist 16 | Production method AJ-20 | 1.68 |
| Example A-21 | Resist 16 | Production method AJ-21 | 1.67 |
| Example A-22 | Resist 16 | Production method AJ-22 | 1.63 |
| Example A-23 | Resist 16 | Production method AJ-23 | 1.58 |
| Example A-24 | Resist 16 | Production method AJ-24 | 1.56 |
| Example A-25 | Resist 18 | Production method AJ-5 | 1.60 |
| Example A-26 | Resist 19 | Production method AJ-5 | 1.44 |
| Example A-27 | Resist 20 | Production method AJ-5 | 1.41 |
| Example A-28 | Resist 22 | Production method AJ-5 | 1.44 |
| Example A-29 | Resist 24 | Production method AJ-5 | 1.35 |

TABLE 19

| | Resist | | Evaluation |
|---|---|---|---|
| Table 17 | composition | Production method | results (3σ) |
| Comparative | Resist 17 | Production method AH-1 | 3.50 |
| Example A-3 | | | |
| Comparative | Resist 18 | Production method AH-1 | 3.76 |
| Example A-4 | | | |
| Comparative | Resist 19 | Production method AH-1 | 3.59 |
| Example A-5 | | | |
| Comparative | Resist 20 | Production method AH-1 | 3.51 |
| Example A-6 | | | |
| Comparative | Resist 21 | Production method AH-1 | 3.67 |
| Example A-7 | | | |
| Comparative | Resist 22 | Production method AH-1 | 3.64 |
| Example A-8 | | | |
| Comparative | Resist 23 | Production method AH-1 | 3.48 |
| Example A-9 | | | |
| Comparative | Resist 24 | Production method AH-1 | 3.38 |
| Example A-10 | | | |
| Comparative | Resist 25 | Production method AH-1 | 3.42 |
| Example A-11 | | | |
| Comparative | Resist 26 | Production method AH-1 | 3.53 |
| Example A-12 | | | |
| Comparative | Resist 27 | Production method AH-1 | 3.51 |
| Example A-13 | | | |
| Comparative | Resist 28 | Production method AH-1 | 3.89 |
| Example A-14 | | | |
| Comparative | Resist 29 | Production method AH-1 | 3.84 |
| Example A-15 | | | |
| Comparative | Resist 30 | Production method AH-1 | 4.07 |
| Example A-16 | | | |
| Comparative | Resist 31 | Production method AH-1 | 3.70 |
| Example A-17 | | | |
| Example A-30 | Resist 17 | Production method AJ-24 | 1.40 |
| Example A-31 | Resist 18 | Production method AJ-24 | 1.59 |
| Example A-32 | Resist 19 | Production method AJ-24 | 1.42 |
| Example A-33 | Resist 20 | Production method AJ-24 | 1.38 |
| Example A-34 | Resist 21 | Production method AJ-24 | 1.53 |
| Example A-35 | Resist 22 | Production method AJ-24 | 1.43 |
| Example A-36 | Resist 23 | Production method AJ-24 | 1.40 |
| Example A-37 | Resist 24 | Production method AJ-24 | 1.35 |
| Example A-38 | Resist 25 | Production method AJ-24 | 1.35 |
| Example A-39 | Resist 26 | Production method AJ-24 | 1.38 |
| Example A-40 | Resist 27 | Production method AJ-24 | 1.40 |
| Example A-41 | Resist 28 | Production method AJ-24 | 1.63 |
| Example A-42 | Resist 29 | Production method AJ-24 | 1.63 |
| Example A-43 | Resist 30 | Production method AJ-24 | 1.75 |
| Example A-44 | Resist 31 | Production method AJ-24 | 1.49 |
| Example A-43 | Resist 16 | Production method AJ-25 | 1.55 |
| Example A-44 | Resist 16 | Production method AJ-26 | 1.54 |
| Example A-45 | Resist 16 | Production method AJ-27 | 1.53 |
| Example A-46 | Resist 16 | Production method AJ-28 | 1.49 |
| Example A-47 | Resist 18 | Production method AJ-28 | 1.51 |
| Example A-48 | Resist 19 | Production method AJ-28 | 1.37 |
| Example A-49 | Resist 20 | Production method AJ-28 | 1.34 |
| Example A-50 | Resist 22 | Production method AJ-28 | 1.39 |
| Example A-51 | Resist 24 | Production method AJ-28 | 1.29 |

As shown in the table above, it was confirmed that a desired effect can be obtained by the production method of the embodiment of the present invention. For example, as seen from the comparison between Example A-30 using “Resist 17” as the resist composition and Comparative Example A-3, Example A-30 using the production method of the embodiment of the present invention exhibited a more excellent effect.

Above all, from the comparison of Examples A-1 and A-2, it was confirmed that the effect is more excellent in a case where the SP value of the first organic solvent is 17.0 MPa^{1/2} or more and less than 25.0 MPa^{1/2}.

In addition, from the comparison of Examples A-1, A-3, and A-8, it was confirmed that the effect was more excellent in a case where the radiation-sensitive resin composition was used as the first solution.

Furthermore, from the comparison of Examples A-8 and A-10 to 12, it was confirmed that the effect was more excellent in a case where the immersion treatment of the first filter was carried out under a predetermined pressure.

Moreover, from the comparison of Examples A-12 and A-13, it was confirmed that the effect was more excellent in a case where the liquid passing direction of the solution passing through the filter was from the lower side to the upper side in the vertical direction.

In addition, from the comparison between Examples A-21 to A-24 and the other Examples, it was confirmed that the effect was more excellent in a case where the steps 3 and 4 were carried out.

Furthermore, from the comparison of Examples A-22, A-43, and A-44, it was confirmed that the lower the linear velocity, the better the effect.

### Examples E-1 to E-76 and Comparative Examples E-1 to E-34

### EUV Exposure Experiment

As mentioned above, the radiation-sensitive resin composition was filled in five subdivided containers.

Thus, a hole pattern was formed using each of the radiation-sensitive resin compositions in the subdivided containers according to the following method (Pattern Formation 3).

Specifically, in a case where a method which will be described later (Pattern Formation 3) was carried out, the resist compositions filled in the five subdivided containers were each used on five silicon wafers for each resist composition to form a hole pattern. That is, using the five subdivided resist compositions, a hole pattern was formed on the five silicon wafers for each subdivided resist composition, and a hole pattern was formed on a total of 25 silicon wafers.

Next, an operation of measuring a hole part per hole pattern at 60 points and calculating an average value thereof was carried out on the hole patterns on 25 silicon wafers, and an average value for each hole pattern was calculated. Next, using the values of the obtained 25 average values, the standard deviations u were obtained and 3σ corresponding to three times the standard deviation was calculated. The smaller the value of 3σ, the better the effect. The results are shown in Tables 18 and 19.

Furthermore, a scanning electron microscope (9380II manufactured by Hitachi High-Technologies Corporation) was used for the measurement of a pattern size.

(Pattern Formation 3)

A composition for forming an organic antireflection film, AL412 (manufactured by Brewer Science, Inc.), was applied onto a silicon wafer (12-inch diameter), using a spin coater “ACT-12” manufactured by Tokyo Electron Limited, and baked at 205° C. for 60 seconds to form an antireflection film having a film thickness of 200 nm.

The resist compositions (resists 32 to 48) prepared by a predetermined production method described in the “Resist composition” column of Tables 18 and 19 was applied onto the obtained antireflection film using the same device, and baked under a PB condition corresponding to each resist composition shown in Table 11 to obtain a resist film having a film thickness corresponding to each resist composition shown in Table 11.

The obtained resist film was subjected to pattern exposure through a square array with masks having a hole portion of 28 nm and a pitch between the holes of 55 nm, using an EUV exposure device (manufactured by Exitech Ltd., Micro Exposure Tool, NA 0.3, Quadrupol, outer sigma 0.68, inner sigma 0.36).

The resist film after the exposure was baked under a PEB condition corresponding to each resist composition shown in Table 11, developed with a developer corresponding to each resist composition shown in Table 11 for 30 seconds, and then rinsed with pure water for 30 seconds. Thereafter, the resist film was spin-dried to obtain a hole pattern having a pore diameter of 28 nm.

TABLE 20

| | Resist | | Evaluation |
|---|---|---|---|
| Table 18 | composition | Production method | results (3σ) |
| Comparative | Resist 32 | Production method AH-1 | 2.60 |
| Example E-1 | | | |
| Comparative | Resist 32 | Production method AH-2 | 2.54 |
| Example E-2 | | | |
| Example E-1 | Resist 32 | Production method AJ-1 | 2.04 |
| Example E-2 | Resist 32 | Production method AJ-2 | 2.15 |
| Example E-3 | Resist 32 | Production method AJ-3 | 2.08 |
| Example E-4 | Resist 32 | Production method AJ-4 | 2.10 |
| Example E-5 | Resist 32 | Production method AJ-5 | 1.12 |
| Example E-6 | Resist 32 | Production method AJ-6 | 2.04 |
| Example E-7 | Resist 32 | Production method AJ-7 | 1.55 |
| Example E-8 | Resist 32 | Production method AJ-8 | 1.34 |
| Example E-9 | Resist 32 | Production method AJ-9 | 1.32 |
| Example E-10 | Resist 32 | Production method AJ-10 | 1.31 |
| Example E-11 | Resist 32 | Production method AJ-11 | 1.26 |
| Example E-12 | Resist 32 | Production method AJ-12 | 1.24 |
| Example E-13 | Resist 32 | Production method AJ-13 | 1.23 |
| Example E-14 | Resist 32 | Production method AJ-14 | 1.22 |
| Example E-15 | Resist 32 | Production method AJ-15 | 1.18 |
| Example E-16 | Resist 32 | Production method AJ-16 | 1.18 |
| Example E-17 | Resist 32 | Production method AJ-17 | 1.16 |
| Example E-18 | Resist 32 | Production method AJ-18 | 1.16 |
| Example E-19 | Resist 32 | Production method AJ-19 | 1.18 |
| Example E-20 | Resist 32 | Production method AJ-20 | 1.17 |
| Example E-21 | Resist 32 | Production method AJ-21 | 1.15 |
| Example E-22 | Resist 32 | Production method AJ-22 | 1.13 |
| Example E-23 | Resist 32 | Production method AJ-23 | 1.12 |
| Example E-24 | Resist 32 | Production method AJ-24 | 1.12 |
| Example E-25 | Resist 34 | Production method AJ-5 | 0.91 |
| Example E-26 | Resist 35 | Production method AJ-5 | 0.83 |
| Example E-27 | Resist 36 | Production method AJ-5 | 1.04 |
| Example E-28 | Resist 37 | Production method AJ-5 | 0.96 |
| Example E-29 | Resist 39 | Production method AJ-5 | 1.11 |
| Example E-30 | Resist 44 | Production method AJ-5 | 0.88 |
| Example E-31 | Resist 47 | Production method AJ-5 | 1.05 |
| Example E-32 | Resist 48 | Production method AJ-5 | 1.05 |

TABLE 21

| | Resist | | Evaluation |
|---|---|---|---|
| Table 19(1) | composition | Production method | results (3σ) |
| Comparative | Resist 33 | Production method AH-1 | 2.50 |
| Example E-3 | | | |
| Comparative | Resist 34 | Production method AH-1 | 2.25 |
| Example E-4 | | | |
| Comparative | Resist 35 | Production method AH-1 | 2.11 |
| Example E-5 | | | |
| Comparative | Resist 36 | Production method AH-1 | 2.42 |
| Example E-6 | | | |
| Comparative | Resist 37 | Production method AH-1 | 2.30 |
| Example E-7 | | | |
| Comparative | Resist 38 | Production method AH-1 | 2.41 |
| Example E-8 | | | |
| Comparative | Resist 39 | Production method AH-1 | 2.49 |
| Example E-9 | | | |
| Comparative | Resist 40 | Production method AH-1 | 2.42 |
| Example E-10 | | | |
| Comparative | Resist 41 | Production method AH-1 | 2.02 |
| Example E-11 | | | |
| Comparative | Resist 42 | Production method AH-1 | 2.50 |
| Example E-12 | | | |
| Comparative | Resist 43 | Production method AH-1 | 2.49 |
| Example E-13 | | | |
| Comparative | Resist 44 | Production method AH-1 | 2.20 |
| Example E-14 | | | |
| Comparative | Resist 45 | Production method AH-1 | 2.15 |
| Example E-15 | | | |
| Comparative | Resist 46 | Production method AH-1 | 2.35 |
| Example E-16 | | | |
| Comparative | Resist 47 | Production method AH-1 | 2.45 |
| Example E-17 | | | |
| Comparative | Resist 48 | Production method AH-1 | 2.49 |
| Example E-18 | | | |
| Example E-33 | Resist 33 | Production method AJ-24 | 1.10 |
| Example E-34 | Resist 34 | Production method AJ-24 | 0.90 |
| Example E-35 | Resist 35 | Production method AJ-24 | 0.82 |
| Example E-36 | Resist 36 | Production method AJ-24 | 1.04 |
| Example E-37 | Resist 37 | Production method AJ-24 | 0.95 |
| Example E-38 | Resist 38 | Production method AJ-24 | 0.99 |
| Example E-39 | Resist 39 | Production method AJ-24 | 1.10 |
| Example E-40 | Resist 40 | Production method AJ-24 | 1.00 |
| Example E-41 | Resist 41 | Production method AJ-24 | 0.79 |
| Example E-42 | Resist 42 | Production method AJ-24 | 1.07 |
| Example E-43 | Resist 43 | Production method AJ-24 | 1.03 |
| Example E-44 | Resist 44 | Production method AJ-24 | 0.86 |
| Example E-45 | Resist 45 | Production method AJ-24 | 0.82 |
| Example E-46 | Resist 46 | Production method AJ-24 | 0.94 |
| Example E-47 | Resist 47 | Production method AJ-24 | 1.04 |
| Example E-48 | Resist 48 | Production method AJ-24 | 1.04 |
| Example E-49 | Resist 32 | Production method AJ-25 | 1.09 |
| Example E-50 | Resist 32 | Production method AJ-26 | 1.06 |
| Example E-51 | Resist 32 | Production method AJ-27 | 1.10 |
| Example E-52 | Resist 32 | Production method AJ-28 | 1.07 |
| Example E-53 | Resist 34 | Production method AJ-28 | 0.88 |
| Example E-54 | Resist 35 | Production method AJ-28 | 0.80 |
| Example E-55 | Resist 36 | Production method AJ-28 | 1.02 |
| Example E-56 | Resist 37 | Production method AJ-28 | 0.92 |
| Example E-57 | Resist 39 | Production method AJ-28 | 1.06 |
| Example E-58 | Resist 44 | Production method AJ-28 | 0.82 |
| Example E-59 | Resist 47 | Production method AJ-28 | 1.01 |
| Example E-60 | Resist 48 | Production method AJ-28 | 1.00 |

TABLE 22

| | Resist | | Evaluation |
|---|---|---|---|
| Table 19(2) | composition | Production method | results (3σ) |
| Comparative | Resist 49 | Production method AH-1 | 2.42 |
| Example E-19 | | | |
| Comparative | Resist 50 | Production method AH-1 | 2.45 |
| Example E-20 | | | |
| Comparative | Resist 51 | Production method AH-1 | 2.02 |
| Example E-21 | | | |
| Comparative | Resist 52 | Production method AH-1 | 2.14 |
| Example E-22 | | | |
| Comparative | Resist 53 | Production method AH-1 | 2.14 |
| Example E-23 | | | |
| Comparative | Resist 54 | Production method AH-1 | 2.14 |
| Example E-24 | | | |
| Comparative | Resist 55 | Production method AH-1 | 2.50 |
| Example E-25 | | | |
| Comparative | Resist 56 | Production method AH-1 | 2.32 |
| Example E-26 | | | |
| Comparative | Resist 57 | Production method AH-1 | 2.22 |
| Example E-27 | | | |
| Comparative | Resist 58 | Production method AH-1 | 2.21 |
| Example E-28 | | | |
| Comparative | Resist 59 | Production method AH-1 | 2.44 |
| Example E-29 | | | |
| Comparative | Resist 60 | Production method AH-1 | 2.04 |
| Example E-30 | | | |
| Comparative | Resist 61 | Production method AH-1 | 2.49 |
| Example E-31 | | | |
| Comparative | Resist 62 | Production method AH-1 | 2.33 |
| Example E-32 | | | |
| Comparative | Resist 63 | Production method AH-1 | 2.42 |
| Example E-33 | | | |
| Comparative | Resist 64 | Production method AH-1 | 2.47 |
| Example E-34 | | | |
| Example E-61 | Resist 49 | Production method AJ-24 | 1.00 |
| Example E-62 | Resist 50 | Production method AJ-24 | 1.06 |
| Example E-63 | Resist 51 | Production method AJ-24 | 0.85 |
| Example E-64 | Resist 52 | Production method AJ-24 | 1.04 |
| Example E-65 | Resist 53 | Production method AJ-24 | 0.90 |
| Example E-66 | Resist 54 | Production method AJ-24 | 0.99 |
| Example E-67 | Resist 55 | Production method AJ-24 | 0.95 |
| Example E-68 | Resist 56 | Production method AJ-24 | 1.01 |
| Example E-69 | Resist 57 | Production method AJ-24 | 1.05 |
| Example E-70 | Resist 58 | Production method AJ-24 | 1.10 |
| Example E-71 | Resist 59 | Production method AJ-24 | 0.79 |
| Example E-72 | Resist 60 | Production method AJ-24 | 0.88 |
| Example E-73 | Resist 61 | Production method AJ-24 | 1.05 |
| Example E-74 | Resist 62 | Production method AJ-24 | 1.04 |
| Example E-75 | Resist 63 | Production method AJ-24 | 1.02 |
| Example E-76 | Resist 64 | Production method AJ-24 | 1.00 |

As shown in the table above, it was confirmed that a desired effect can be obtained by the production method of the embodiment of the present invention. For example, as shown from the comparison between Example E-33 using “Resist 33” as the resist composition and Comparative Example E-3, Example E-33 using the production method of the embodiment of the present invention exhibited a more excellent effect.

Above all, from the comparison of Examples E-1 and E-2, it was confirmed that the effect is more excellent in a case where the SP value of the first organic solvent is 17.0 MPa^{1/2} or more and less than 25.0 MPa^{1/2}.

In addition, from the comparison of Examples E-1, E-3, and E-8, it was confirmed that the effect was more excellent in a case where the radiation-sensitive resin composition was used as the first solution.

Furthermore, from the comparison of Examples E-8 and E-10 to 12, it was confirmed that the effect was more excellent in a case where the immersion treatment of the first filter was carried out under a predetermined pressure.

Moreover, from the comparison of Examples E-12 and E-13, it was confirmed that the effect was more excellent in a case where the liquid passing direction of the solution passing through the filter was from the lower side to the upper side in the vertical direction.

In addition, from the comparison between Examples E-21 to E-24 and the other Examples, it was confirmed that the effect was more excellent in a case where the steps 3 and 4 were carried out.

Furthermore, from the comparison of Examples E-22, E-49, and E-50, it was confirmed that the lower the linear velocity, the better the effect.

### EXPLANATION OF REFERENCES

10: stirring tank

12 stirring shaft

14 stirring blade

16 circulation pipe

18A, 18B first filter

20 discharge pipe

22 discharge nozzle

100 production device

What is claimed is:

1. A method for producing a radiation-sensitive resin composition, comprising:
a step 1 of bringing a first solution including a first organic solvent into contact with a first filter to clean the first filter; and
a step 2 of filtering a radiation-sensitive resin composition using the first filter cleaned in the step 1.

2. The method for producing a radiation-sensitive resin composition according to claim 1,
wherein the radiation-sensitive resin composition includes a resin having a polarity that increases by an action of an acid, a photoacid generator, and an organic solvent, and
the radiation-sensitive resin composition is used as the first solution.

3. The method for producing a radiation-sensitive resin composition according to claim 1,
wherein a contact time between the first filter and the first solution in the step 1 is 1 hour or more.

4. The method for producing a radiation-sensitive resin composition according to claim 1, wherein an SP value of the first organic solvent is 17.0 MPa^{1/2} or more and less than 25.0 MPa^{1/2}.

5. The method for producing a radiation-sensitive resin composition according to claim 1,
wherein the contact between the first filter and the first solution in the step 1 is performed under a pressure of 50 kPa or more.

6. The method for producing a radiation-sensitive resin composition according to claim 1,
wherein the first filter is arranged so that a liquid passing direction is from a lower side to an upper side in a vertical direction.

7. The method for producing a radiation-sensitive resin composition according to claim 1,
wherein at least one first filter is a polyamide-based filter.

8. The method for producing a radiation-sensitive resin composition according to claim 1,
wherein a linear velocity in a case where the first solution including the first organic solvent passes through the first filter is 40 L/(hr·m²) or less.

9. The method for producing a radiation-sensitive resin composition according to claim 1,
wherein the step 2 is a step of circulating and filtering the radiation-sensitive resin composition using the first filter.

10. The method for producing a radiation-sensitive resin composition according to claim 1, further comprising:
a step 3 of bringing a second solution including a second organic solvent into contact with a second filter to clean the second filter before the step 2;
a step 4 of filtering at least one compound of constituents included in the radiation-sensitive resin composition using the second filter cleaned in the step 3; and
a step 5 of preparing the radiation-sensitive resin composition using the compound obtained in the step 4.

11. The method for producing a radiation-sensitive resin composition according to claim 10,
wherein a contact time between the second filter and the second solution in the step 3 is 1 hour or more.

12. The method for producing a radiation-sensitive resin composition according to claim 10,
wherein an SP value of the second organic solvent is 17.0 MPa^{1/2} or more and less than 25.0 MPa^{1/2}.

13. The method for producing a radiation-sensitive resin composition according to claim 10,
wherein the contact between the second filter and the second solution in the step 3 is performed under a pressure of 50 kPa or more.

14. The method for producing a radiation-sensitive resin composition according to claim 10,
wherein the second filter is arranged so that a liquid passing direction is from a lower side to an upper side in a vertical direction.

15. The method for producing a radiation-sensitive resin composition according to claim 10,
wherein at least one second filter is a polyamide-based filter.

16. The method for producing a radiation-sensitive resin composition according to claim 10,
wherein a linear velocity in a case where the second solution including the second organic solvent passes through the second filter is 40 L/(hr·m²) or less.

17. The method for producing a radiation-sensitive resin composition according to claim 10,
wherein the step 4 is a step of circulating and filtering at least one compound of constituents included in the radiation-sensitive resin composition using the second filter.

18. The method for producing a radiation-sensitive resin composition according to claim 1,
wherein a concentration of solid contents of the radiation-sensitive resin composition is 10% by mass or more.

19. A pattern forming method comprising:
a step of forming a resist film on a substrate using a radiation-sensitive resin composition produced by the production method according to claim 1;
a step of exposing the resist film; and
a step of developing the exposed resist film using a developer to form a pattern.

20. A method for manufacturing an electronic device, comprising the pattern forming method according to claim 19.
